(19) United States
(12) Patent Application Publication
(10) Pub. No.: US 2010/0143707 A1
(43) Pub. Date: Jun. 10, 2010

(54) SURFACE-TREATED METAL SUBSTRATE AND MANUFACTURING METHOD OF THE SAME

(75) Inventors: Takaaki Sasaoka, Tsuchiura-shi (JP); Mineo Washima, Tsuchiura-shi (JP)

Correspondence Address: Fleit Gibbons Gutman Bongini & Bianco PL, 21355 EAST DIXIE HIGHWAY, SUITE 115, MIAMI, FL, 33180, US

(73) Assignee: HITACHI CABLE, LTD., Tokyo (JP)

(21) Appl. No.: 12/628,332

(22) Filed: Dec. 1, 2009

(30) Foreign Application Priority Data
Dec. 1, 2008 (JP) 2008-306398
Dec. 1, 2008 (JP) 2008-306399
Dec. 1, 2008 (JP) 2008-306400

(51) Int. Cl. B32B 33/00; B32B 15/04; C23C 14/34

(52) U.S. Cl. 428/332; 428/354; 204/192.15

(57) ABSTRACT

A surface-treated metal substrate of the present invention comprises: an adhesive layer formed of a sputtering film directly adhered to a passivation film of a metal substrate, with this adhesive layer having an internal residual stress of a compression stress or a zero stress; and a bonding layer formed of a sputtering film mainly composed of any one of copper (Cu), a mixture state of copper and nickel (Cu—Ni), a mixture state of copper and zinc (Cu—Zn), and a mixture state of copper, nickel, and zinc (Cu—Ni—Zn), on the surface of the metal substrate having the passivation film on an outermost, in an order from a surface side of the metal substrate.

### BACKGROUND

1. Technical Field

The present invention relates to a surface-treated metal substrate with surface treatment applied thereon, for improving wettability to solder and a manufacturing method of the same, in a metal substrate such as aluminum (Al) or an aluminum alloy, or stainless steel, titanium, and Invar (Trademark) material.

2. Description of Related Art

Generally, a metal plate such as aluminum (Al) and stainless steel, with a passivation film applied on an outermost surface, is one of the typical materials extremely hard to be soldered, or a material hard to be coated. This is because the passivation film such as an oxide film formed by combining with oxygen in atmospheric air (called a natural oxide film or a natural oxide aluminum layer, etc.), is formed on the outermost surface of, for example, an aluminum thin plate.

As a method for providing excellent solderability (solder wettability) on the surface of an aluminum plate having such characteristics, there is a technique of forming a tin (Sn) layer or a nickel (Ni) layer, etc, on the surface by a plating method, etc, after acid pickling treatment is applied to the surface.

Specifically, the surface of the metal substrate made of aluminum (Al) is degreased and pickled with a solution of acid, and thereafter a first ground layer mainly made of zinc (Zn) is formed by a zinc immersion plating process (5 to 500 mg/m²). A second ground layer 202 mainly made of nickel is formed thereon by plating after water washing is applied thereto (0.2 to 50 mg/m²). Then, a solder wet layer 203 mainly made of tin (Sn) is further formed thereon by plating (0.2 to 20 mg/m²) (Patent documents 1 and 2).

Also, as one of the techniques proposed for the purpose of improving solderability on the surface of an electrode in an electronic component, there is a technique of forming a layer made of titanium (Ti), aluminum (AL), zinc (Zn), or an alloy of them, then forming a layer thereon made of nickel (Ni), copper (Cu), or an alloy of them, and further coating the surface of this layer with a solder layer. In this technique, a layer having a thickness of 0.2 μm made of titanium is formed as the electrode of a ceramic component, then a layer having a thickness of 1 μm made of nickel is further formed thereon, and a coating layer is further formed thereon by immersion into a molten solder expressed by tin:zinc (Sn:Pb)=60:40 (Patent document 3).

Further, the following technique is proposed. Namely, as a wiring material of a semiconductor chip, a layer made of titanium (Ti) and an alloy of titanium/tungsten (Ti/W) is formed on an electrode made of aluminum (Al) as an adhesive layer, and an adhesive layer having a thickness of about 1 to 5 μm and made of nickel (Ni), copper (Cu), an alloy of nickel/vanadium (Ni/V), and nickel/phosphorus (Ni/P) is formed thereon, and Cu or a copper alloy is formed thereon as a solder alloy layer. Sputtering and plating can be used as a forming method of each layer constituting the aforementioned lamination structure. An object of this technique is to make it possible to bond a lead-free solder ball to the surface of the semiconductor chip (Patent document 4).

Further, there is a technique in which an adhesive layer made of an aluminum (Al) alloy and titanium nitride (TiN) are formed by sputtering, and in order to lessen a residual compression stress in these films, a film formation atmosphere in a sputtering film forming process is set to a pressure 3 mTorr or less (about 0.4 Pa or less) (Patent document 5).

There is also a technique in which a titanium (Ti) film having the compression stress is formed by vapor deposition in a film formation atmosphere having an oxygen partial pressure of 5×10⁻⁵ to 5×10⁻⁶ or in a moisture vapor atmosphere. According to this technique, by performing a film forming process in an environment of containing oxygen (O), oxygen (O) invades into a titanium (Ti) layer, and the compression stress remains in this layer (Patent document 6).

(Patent Document 1)

### Japanese Patent Laid Open Publication No. 2006-206945

(Patent Document 2)

### Japanese Patent Laid Open Publication No. 2006-110769

(Patent Document 3)

### Japanese Patent No. 3031024

(Patent Document 4)

### Japanese Patent Laid Open Publication No. 2002-280417

(Patent Document 5)

### Japanese Patent Laid Open Publication No. 11-162873

(Patent Document 6)

### Japanese Patent Laid Open Publication No. 59-121955

However, in any one of the techniques proposed in the aforementioned patent documents 1 to 6, acid pickling treatment is applied to the surface of the metal substrate having the passivation film such as the aluminum substrate, to make a state in which film formation by plating and sputtering is easily applied to the surface, and thereafter a surface treatment structure is formed. For example, as being proposed in patent document 1 and patent document 2, first, the acid pickling treatment is applied to the surface of the aluminum substrate, and the natural oxide film on the outermost surface is removed, and thereafter a tin (Sn) plating film and a zinc (Zn) plating film are formed on the surface. Thus, in a conventional technique, it is indispensable to apply the acid pickling treatment, etc, to the surface of the metal substrate.

Therefore, in the above-described conventional technique, it is necessary to perform a complicated process of applying acid pickling treatment to the surface of the metal substrate, to remove the passivation film, and also it is necessary to use a medical agent such as various plating solutions. Therefore, there is a problem that the process of the acid pickling treatment itself is complicated, and also there is a problem that considerable labor and time and cost are required in quality management of each kind of medical agents and in treating waste liquid.

Further, each kind of plating liquid including the medical agent for acid pickling in particular, is turned into a so-called industrial waste as the waste liquid after use, due to performing acid pickling treatment. Therefore, use of such plating liquid is not desirable from the viewpoint of environmental engineering.

Further, in order to realize excellent soldering, it would be possible to use a technique of using a flux strong enough to dissolve the passivation film such as the oxide film on the surface of the metal substrate. However, actually it is highly probable that the vicinity of a joint part after soldering is remarkably damaged and deteriorated by such a strong flux. Therefore, use of the strong flux is not desirable from the viewpoint of durability and reliability of the joint part.

Moreover, particularly the technique proposed by patent document 3 can be a technique of realizing a joint by lead (Pb) containing solder, but cannot be a technique of realizing a joint by lead free solder.

Further, particularly in the technique proposed by patent document 4, the joint by lead-free soldering can be realized, but it is not known exactly whether or not it can be applied to the metal substrate made of a material with the passivation film applied on the outermost surface, such as the aluminum (Al) substrate having the natural oxide film. Also, in this case, about 1 to 5 μm is required for the thickness of a surface coating film. However, actually when a manufacturing technique on a commercial base is taken into consideration, it is highly probable that too much time is required for forming such a thick surface coating film and productivity is remarkably lowered, resulting in increase of a manufacturing cost.

Further, particularly patent document 5 and patent document 6 disclose a technique of making the compression stress remain in the titanium film. However, even if such a compression stress is remained in the titanium film, as a result of conducting various experiments, it is confirmed that the bonding strength is highly possibly insufficient actually.

### SUMMARY OF THE INVENTION

An object of the present invention is to provide a surface-treated metal substrate capable of providing solder wettability and bonding strength to solder, to the surface of a metal substrate having a passivation film on the outermost surface.

The surface-treated metal substrate includes:

an adhesive layer formed of a sputtering film directly adhered to a passivation film of a metal substrate, with this adhesive layer having an internal residual stress of a compression stress or a zero stress; and

a bonding layer formed of a sputtering film mainly composed of any one of copper (Cu), a mixture state of copper and nickel (Cu—Ni), a mixture state of copper and zinc (Cu—Zn), and a mixture state of copper, nickel, and zinc (Cu—Ni—Zn), on the surface of the metal substrate having the passivation film on an outermost, in an order from a surface side of the metal substrate.

Further, the manufacturing method of the surface-treated metal substrate of the present invention includes the steps of:

forming by sputtering an adhesive layer directly adhered to a passivation film of the metal substrate, with an internal residual stress of this adhesive layer set as a compression stress or a zero stress, and

forming on the adhesive layer by sputtering a bonding layer mainly composed of any one of copper (Cu), a mixture state of copper and nickel (Cu—Ni), a mixture state of copper and zinc (Cu—Zn), and a mixture state of copper, nickel, and zinc (Cu—Ni—Zn), wherein in the step of forming the adhesive layer and the step of forming the bonding layer, film formation by sputtering is performed sequentially in the same chamber maintaining a film formation atmosphere of inactive gas from which oxygen is intentionally removed even when materials of the formed layers are switched.

### BRIEF DESCRIPTION OF THE DRAWINGS

FIG. 1 is a view schematically showing a main essential lamination structure of a surface-treated metal substrate according to an embodiment of the present invention.

FIG. 2 is a view schematically showing a lamination structure in which a protective layer is provided, which is formed by sputtering on a bonding layer of the surface-treated metal substrate shown in FIG. 1.

FIG. 3 is a view schematically showing a lamination structure in which a protective layer is provided, which is formed by plating on the bonding layer of the surface-treated metal substrate shown in FIG. 1.

FIGS. 4-90 correspond to Tables 1-87 as discussed in the specification.

### DESCRIPTION OF PREFERRED EMBODIMENTS OF THE INVENTION

A surface-treated metal substrate and a manufacturing method of the same according to preferred embodiments of the present invention will be described, with reference to the drawings.

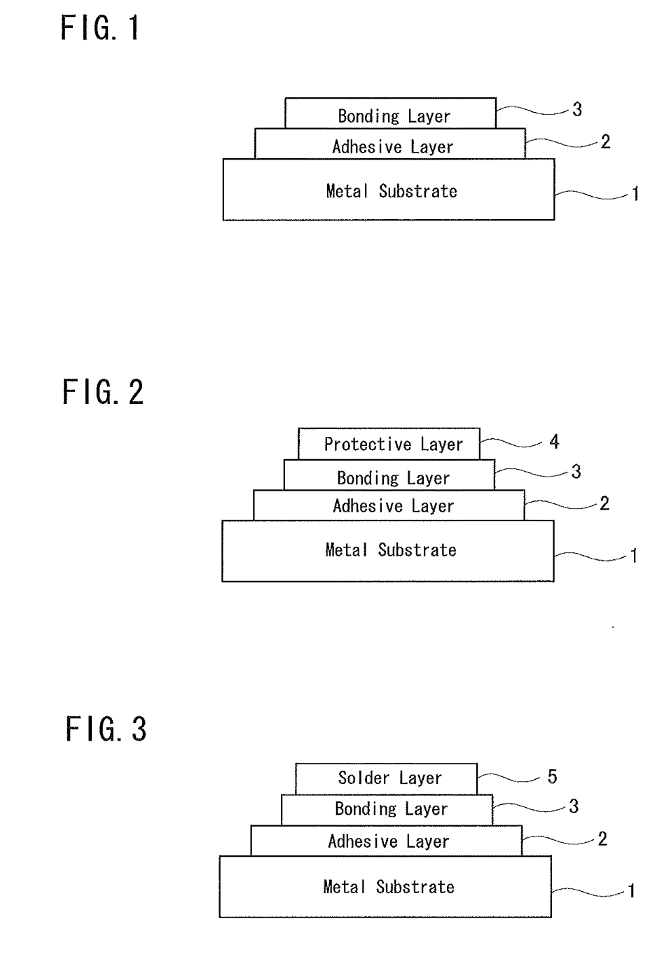

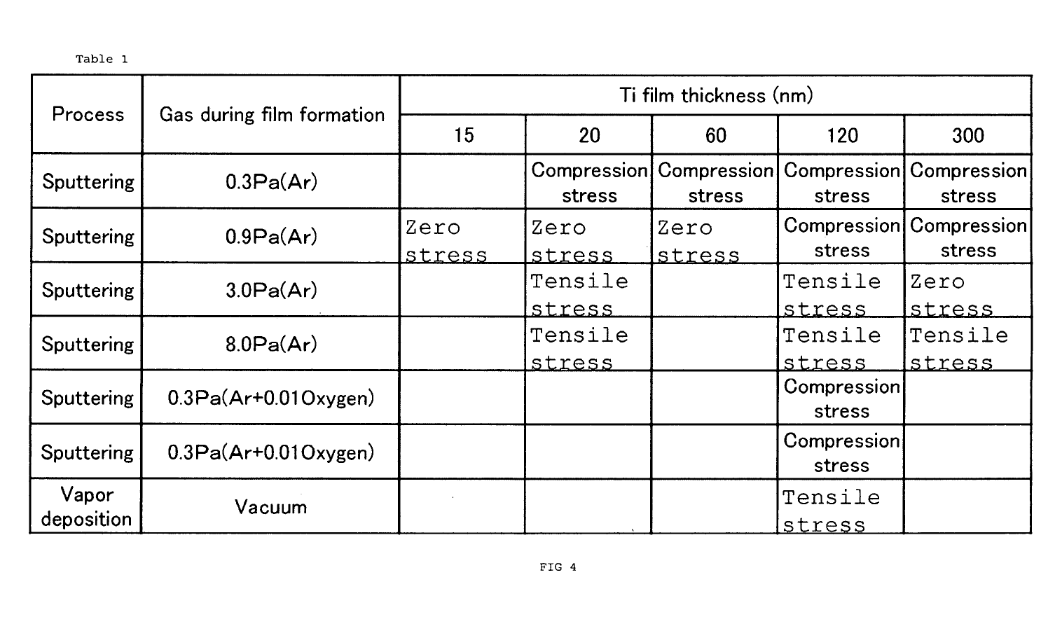

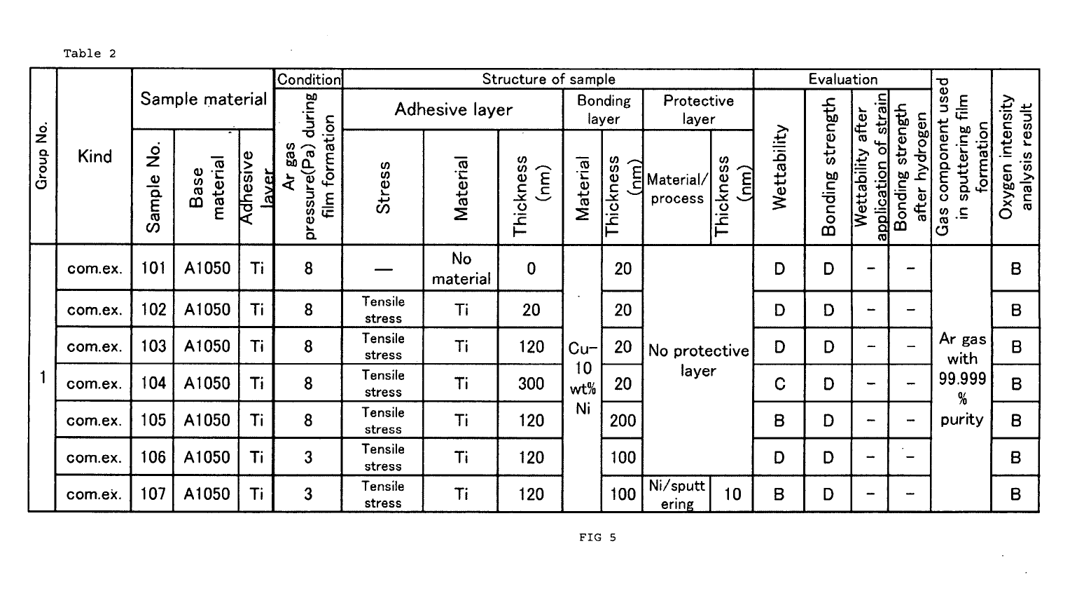

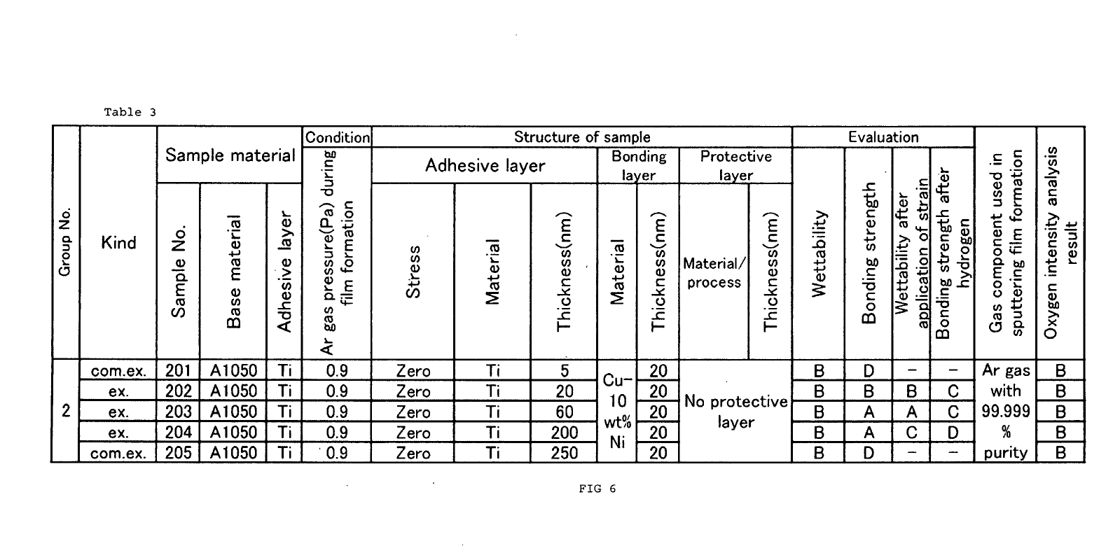

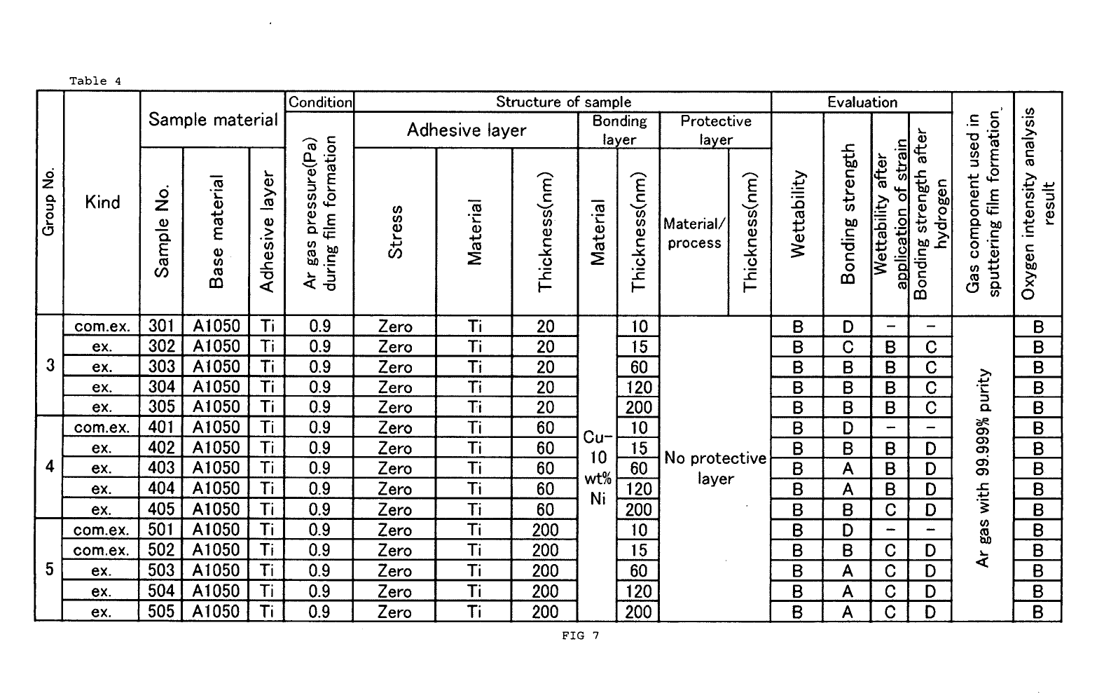

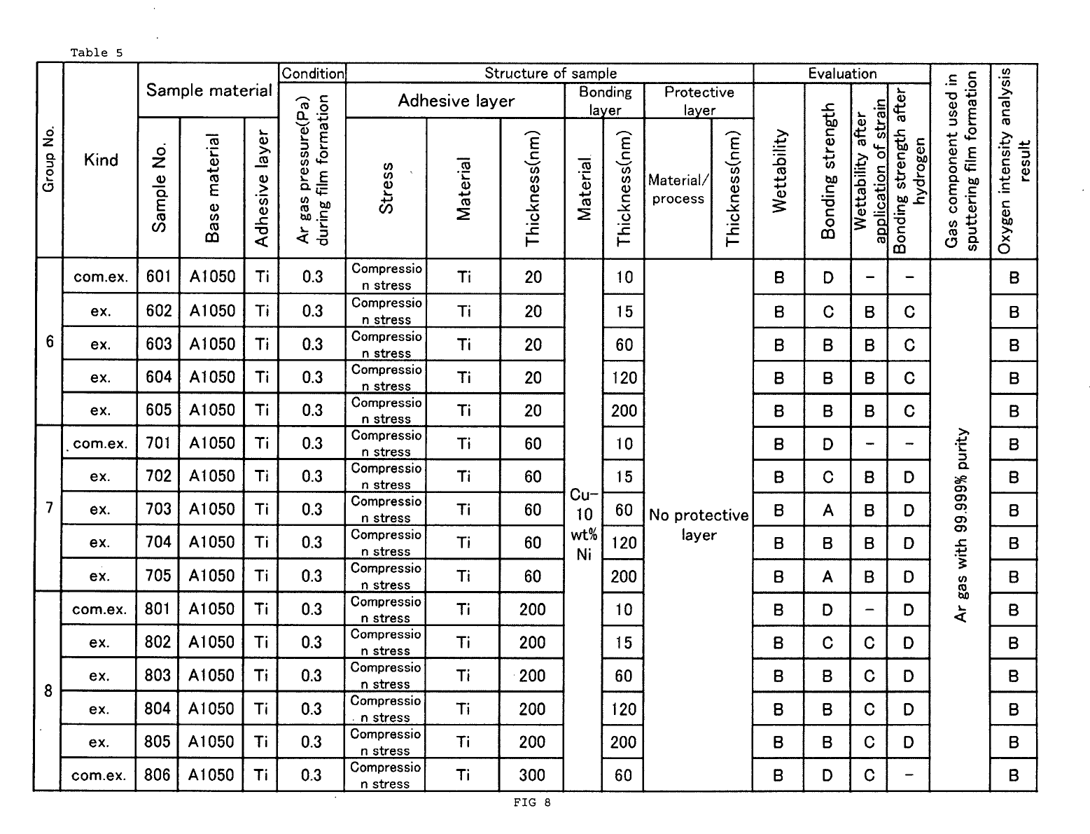

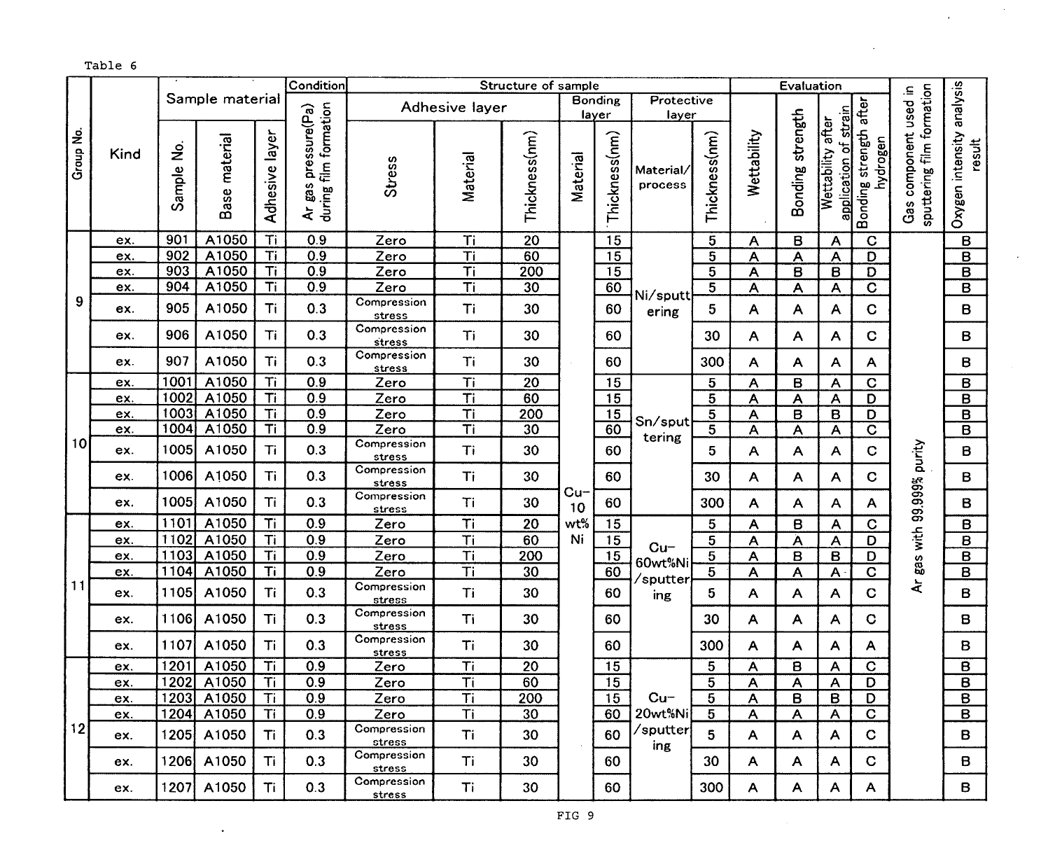

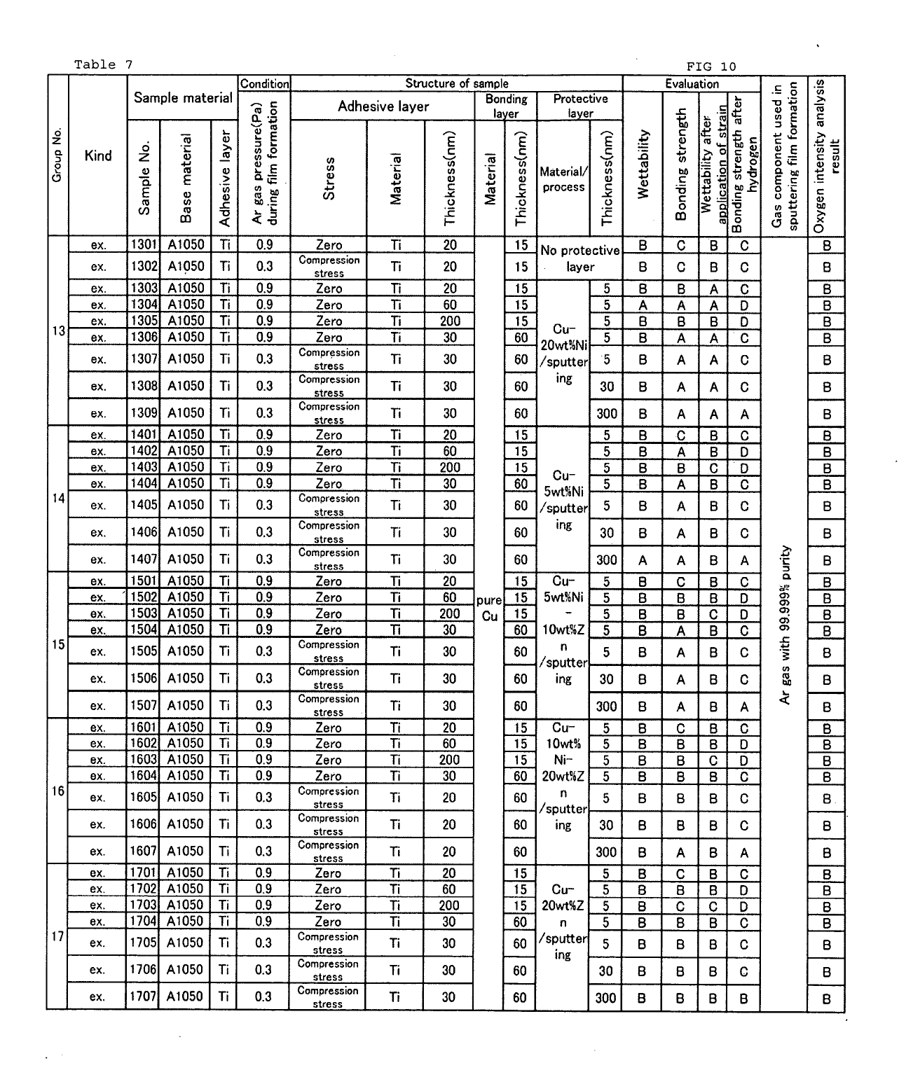

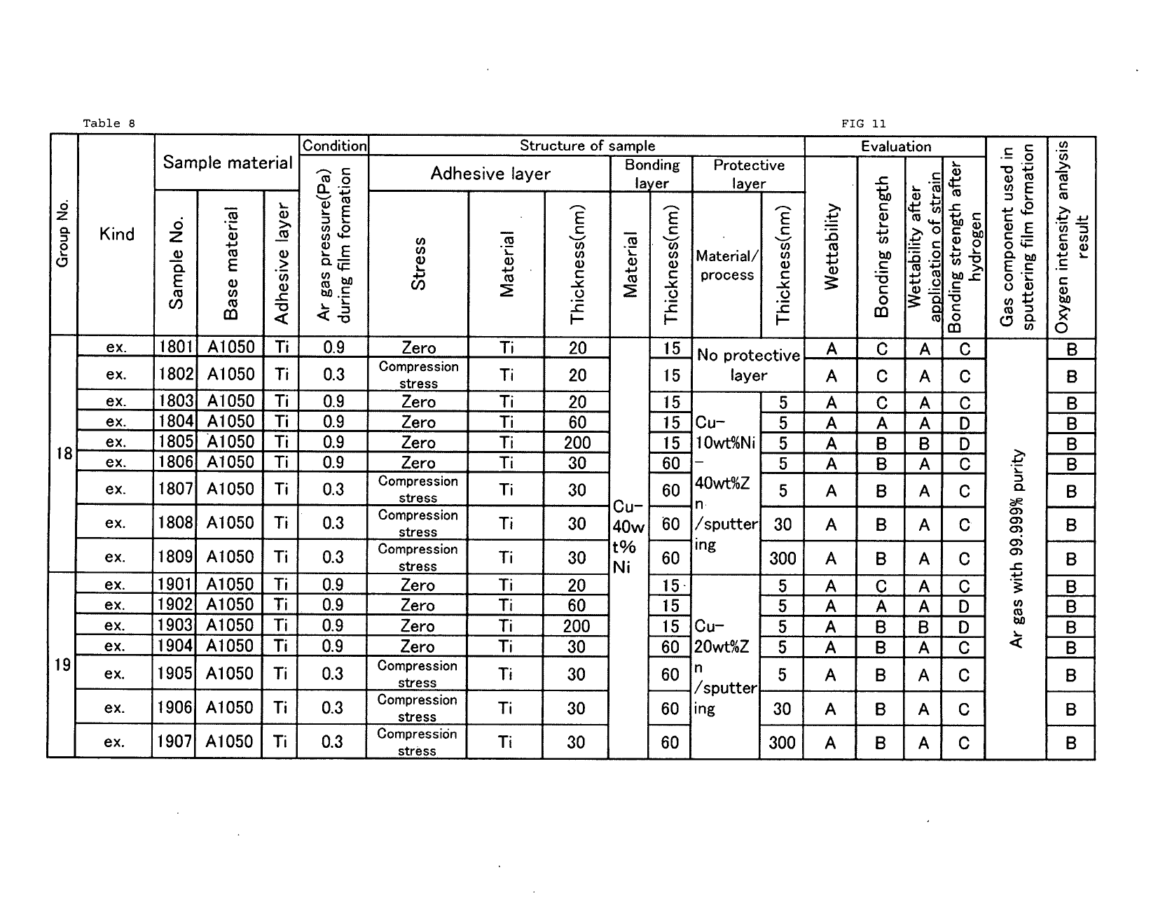

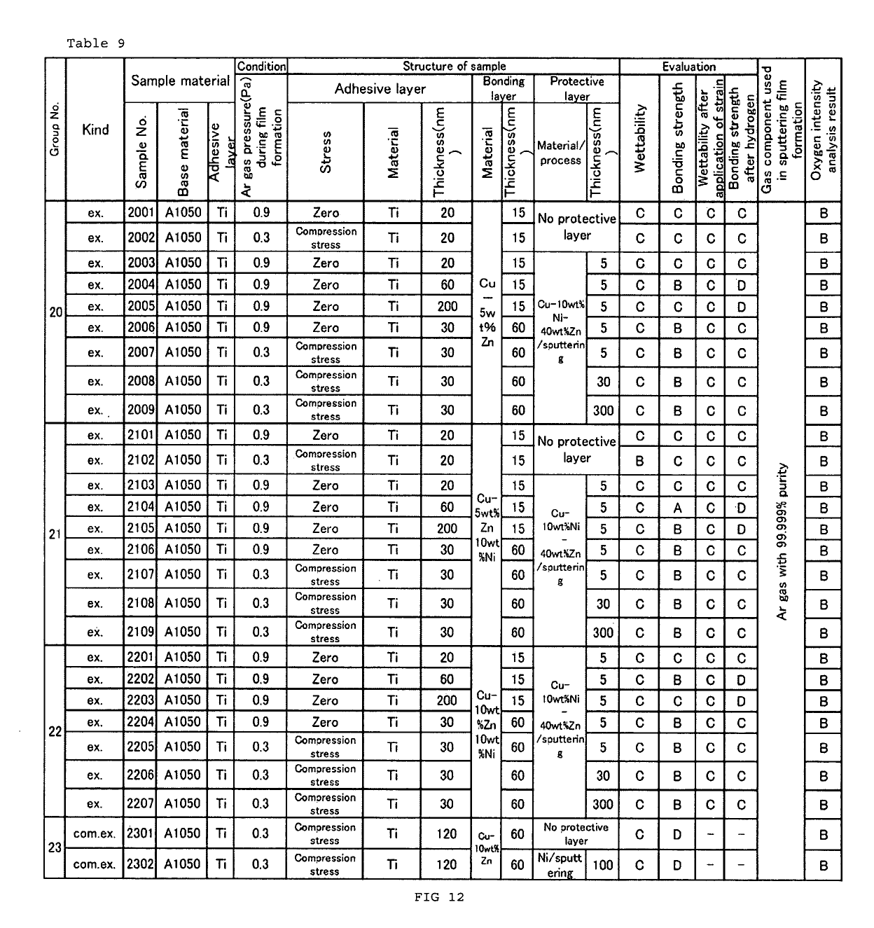

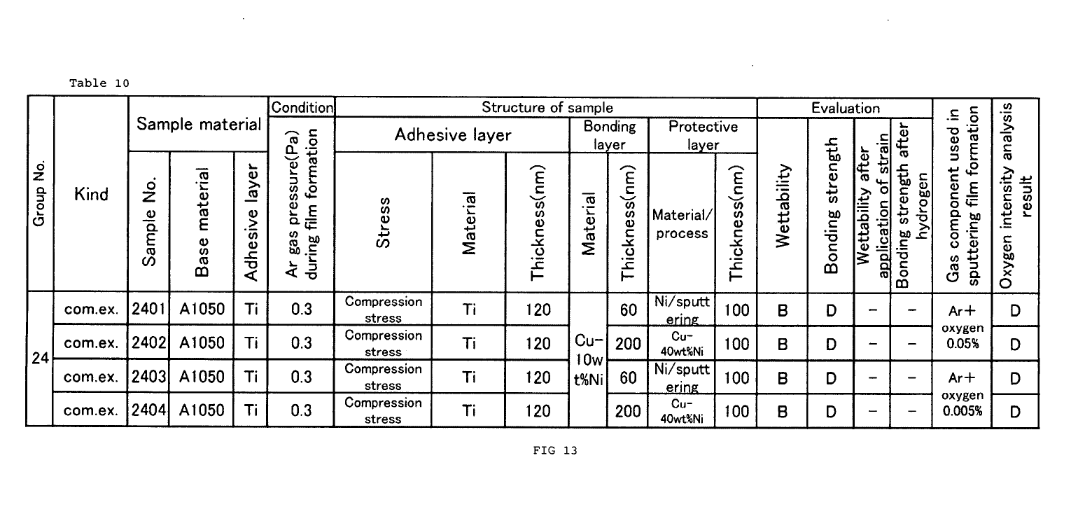

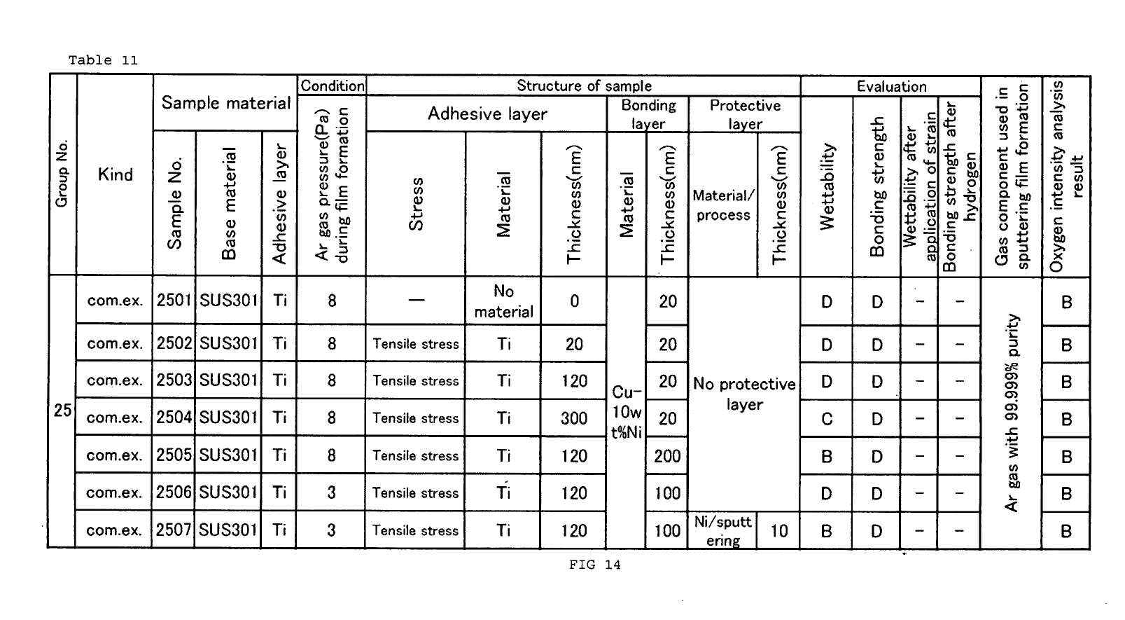

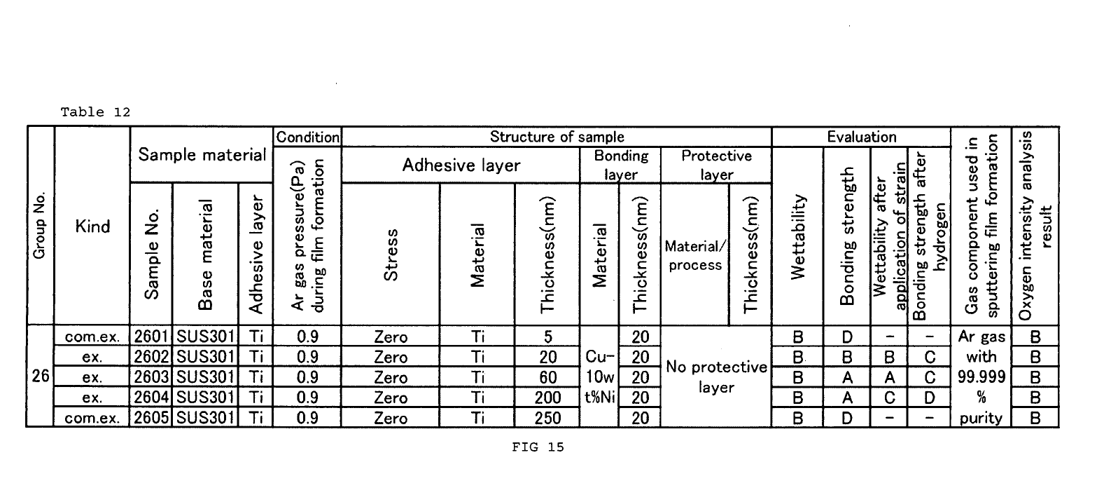

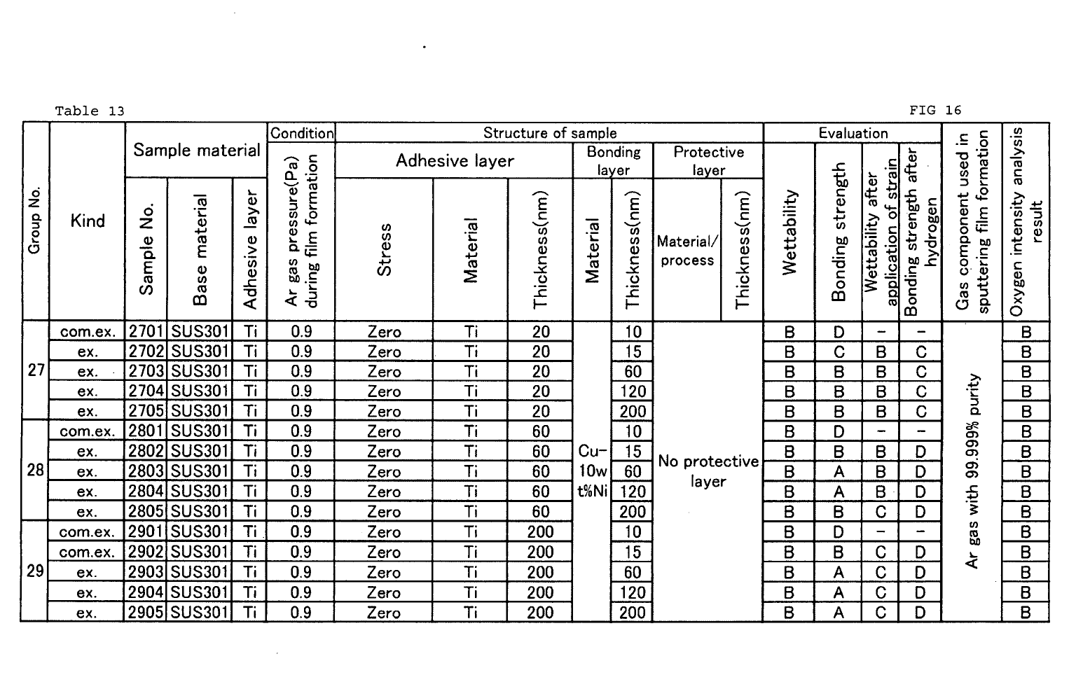

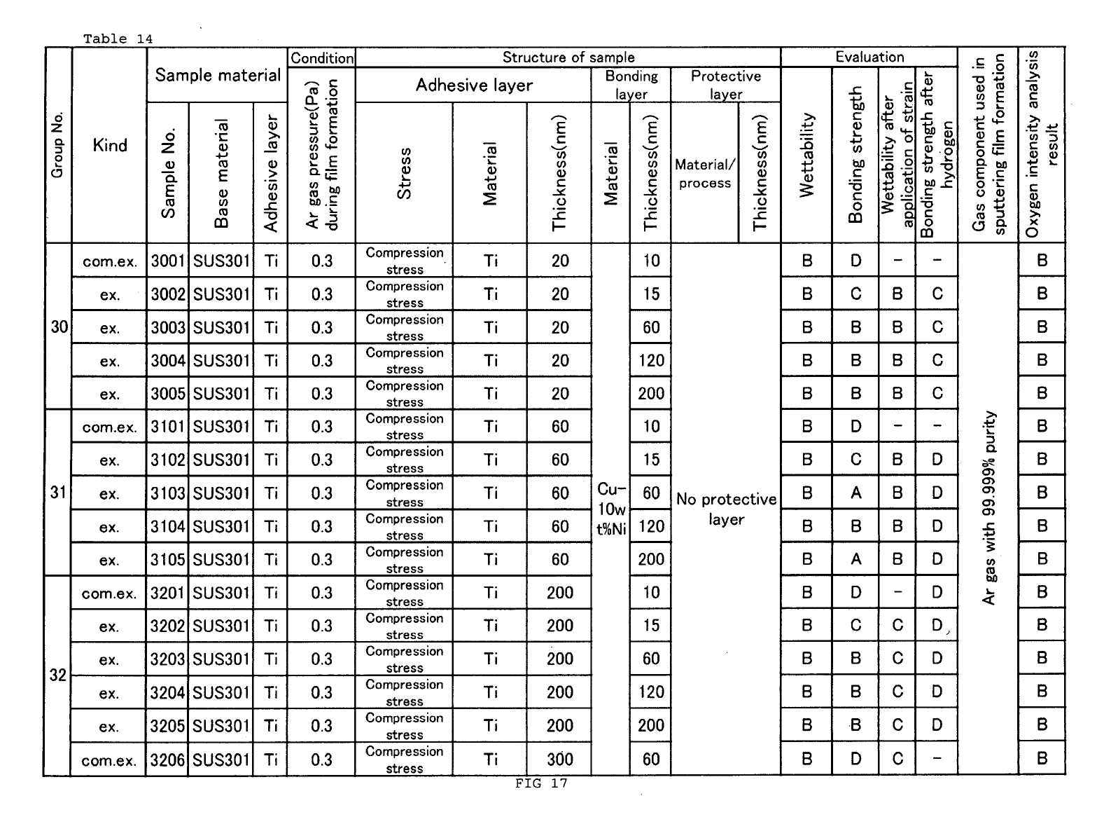

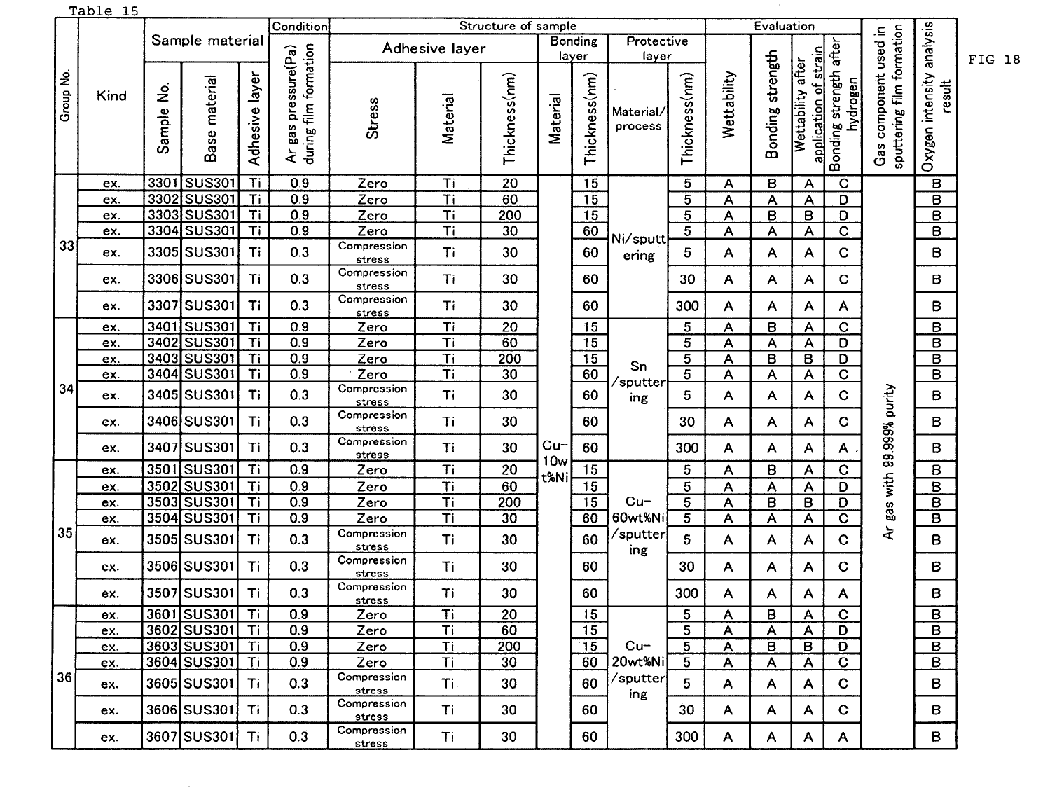

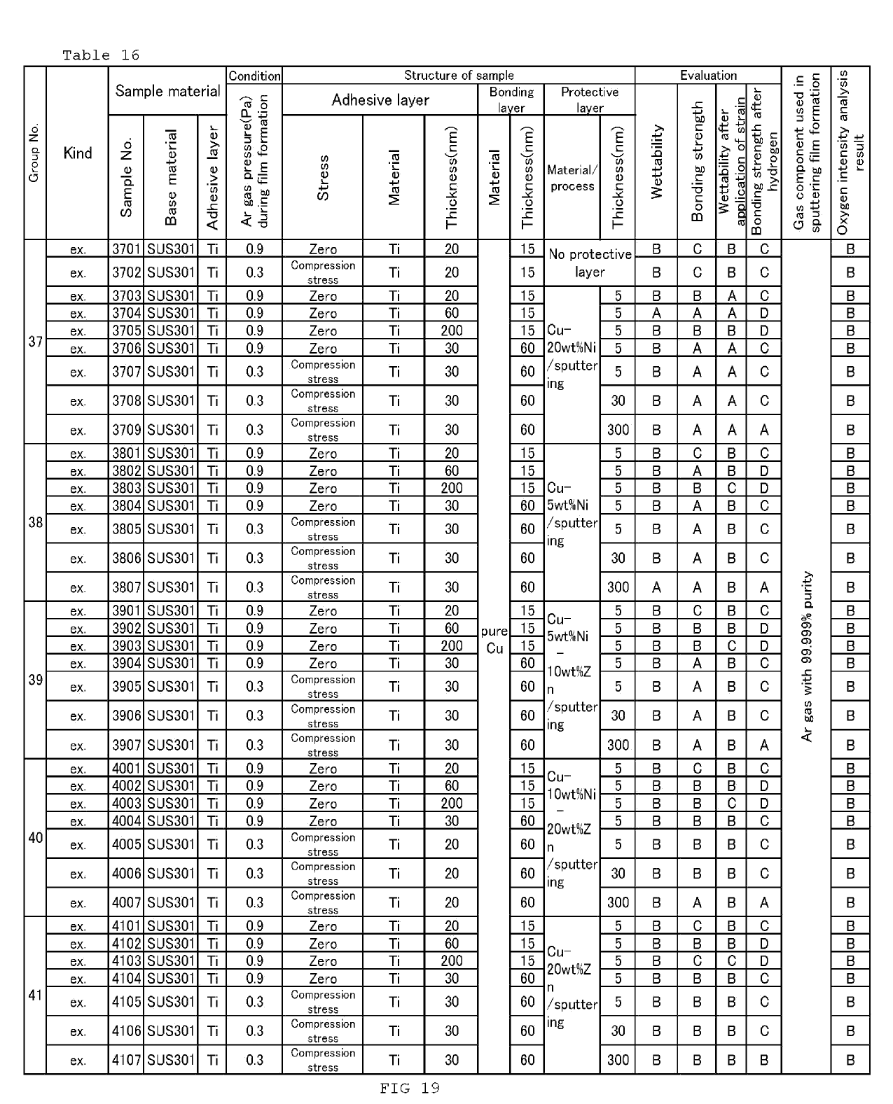

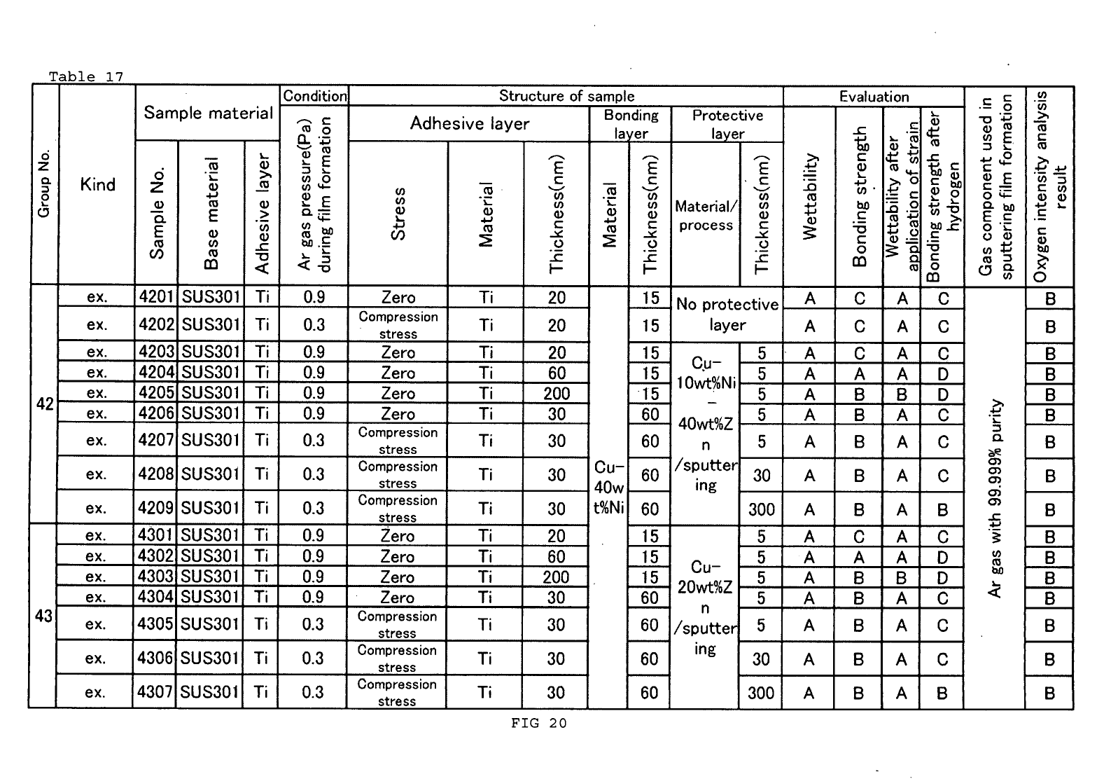

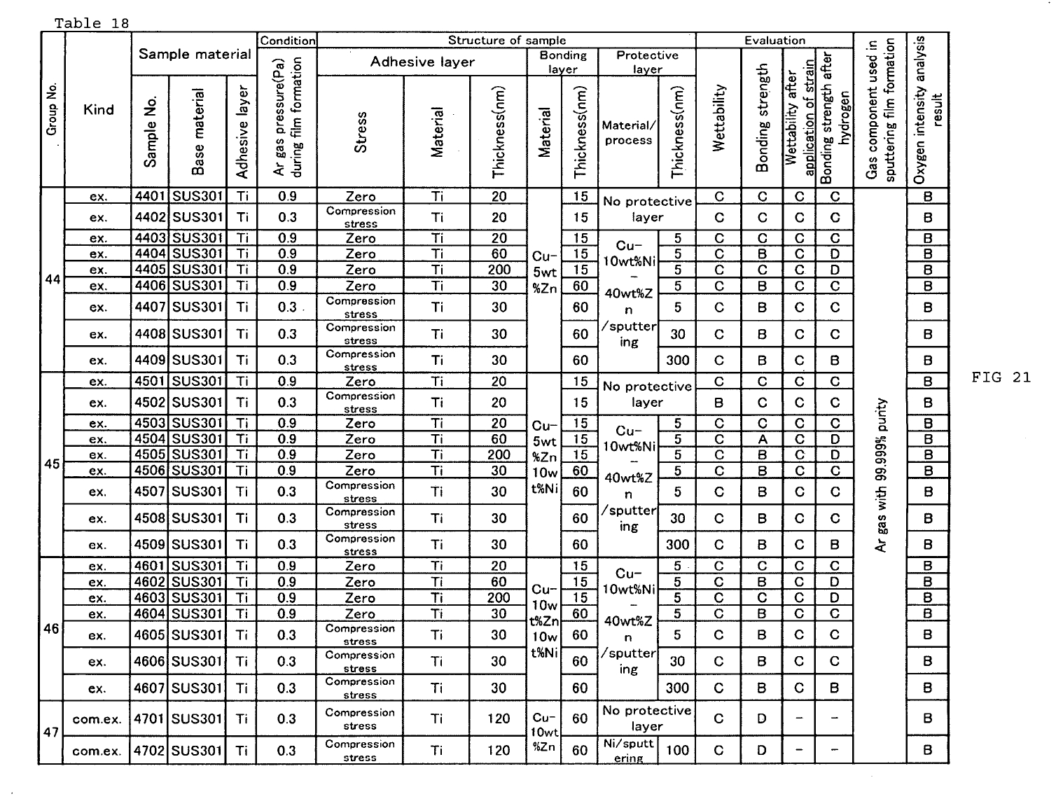

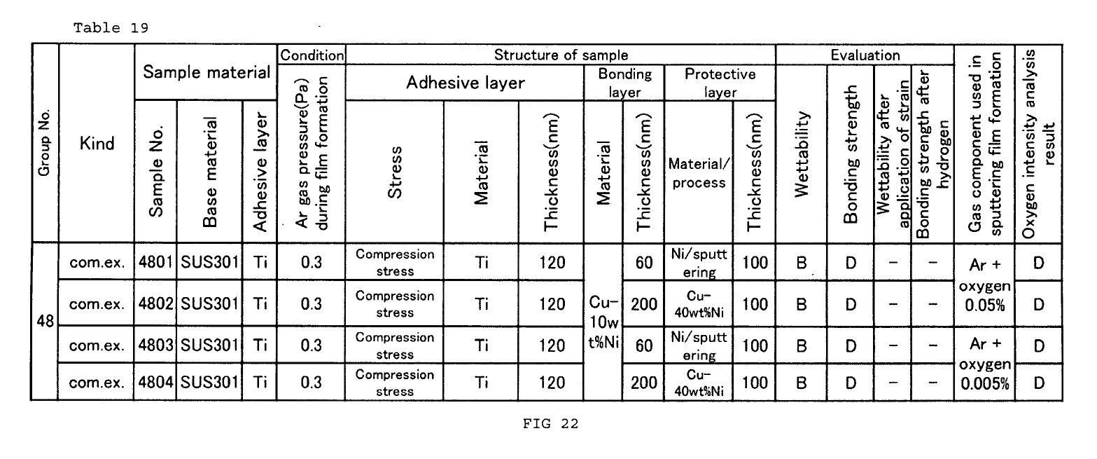

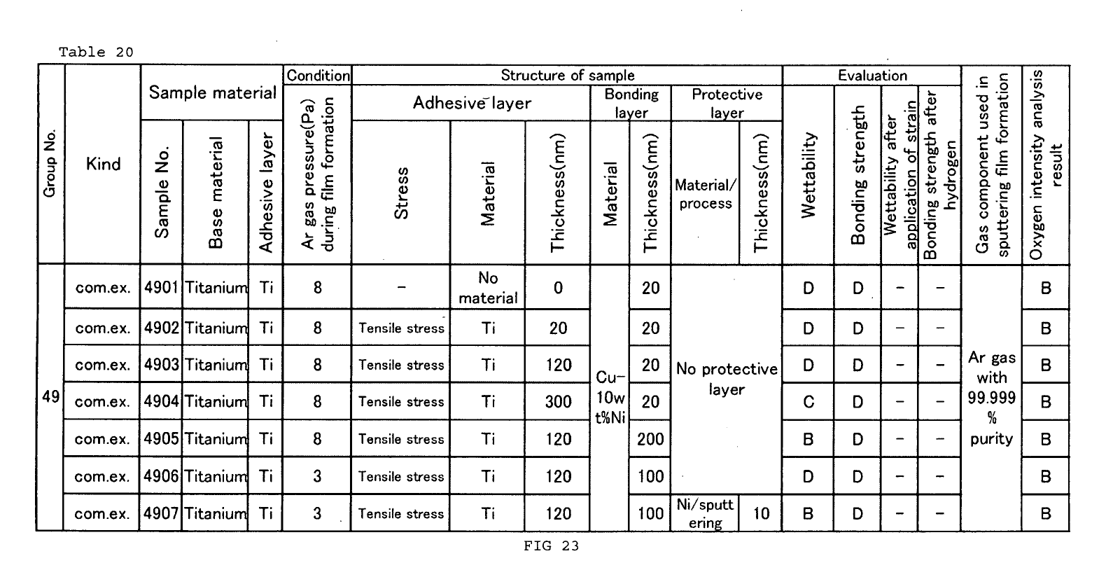

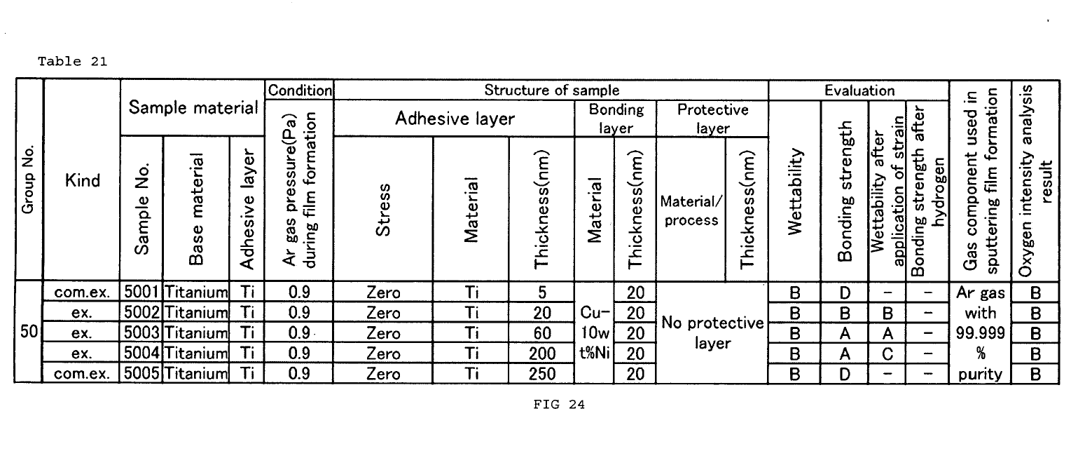

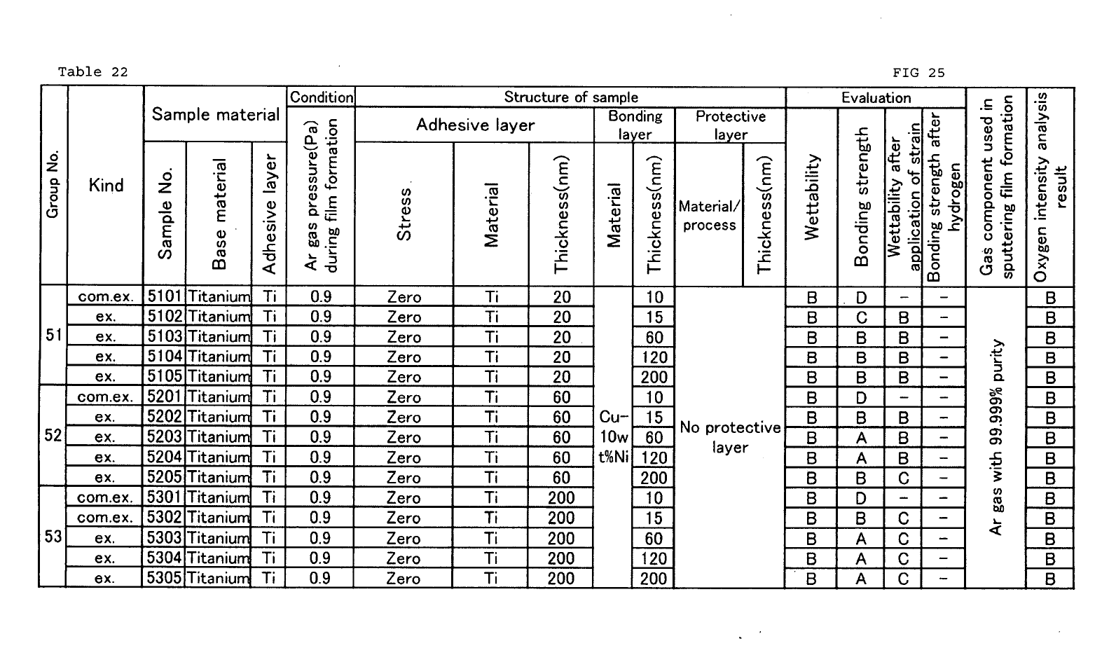

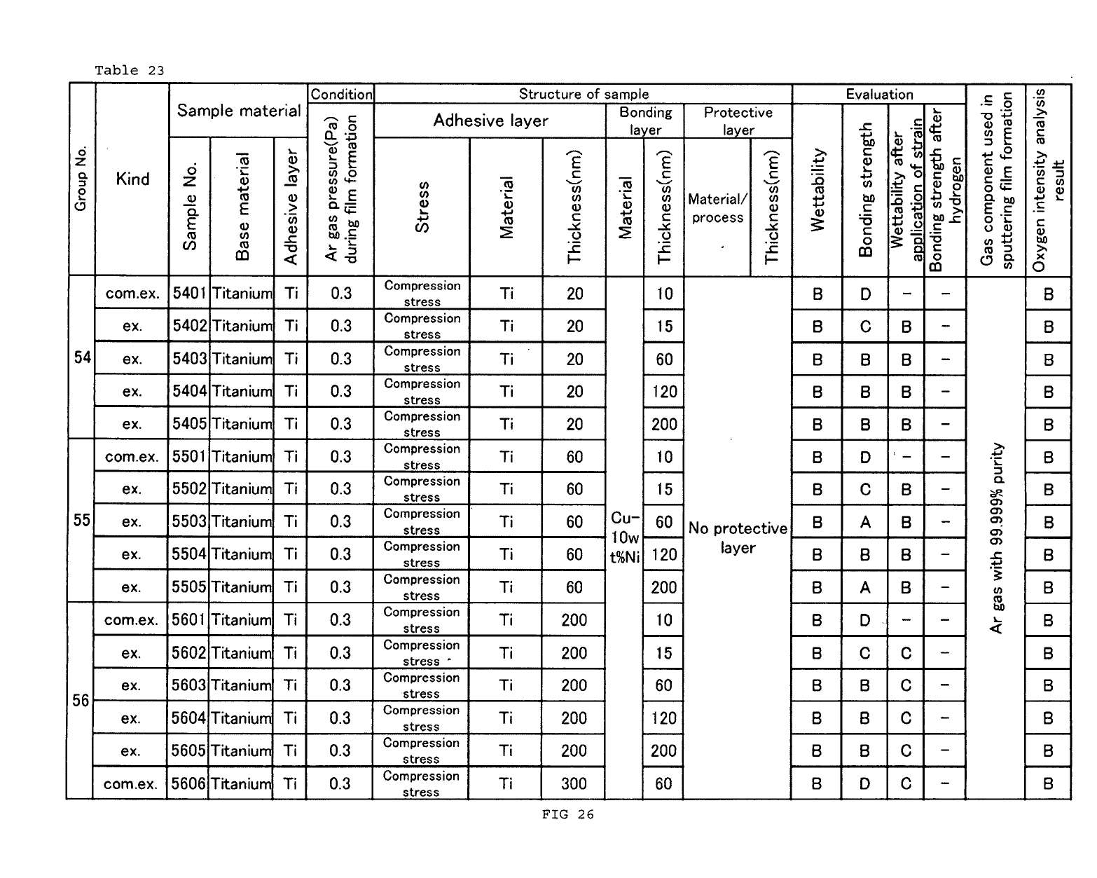

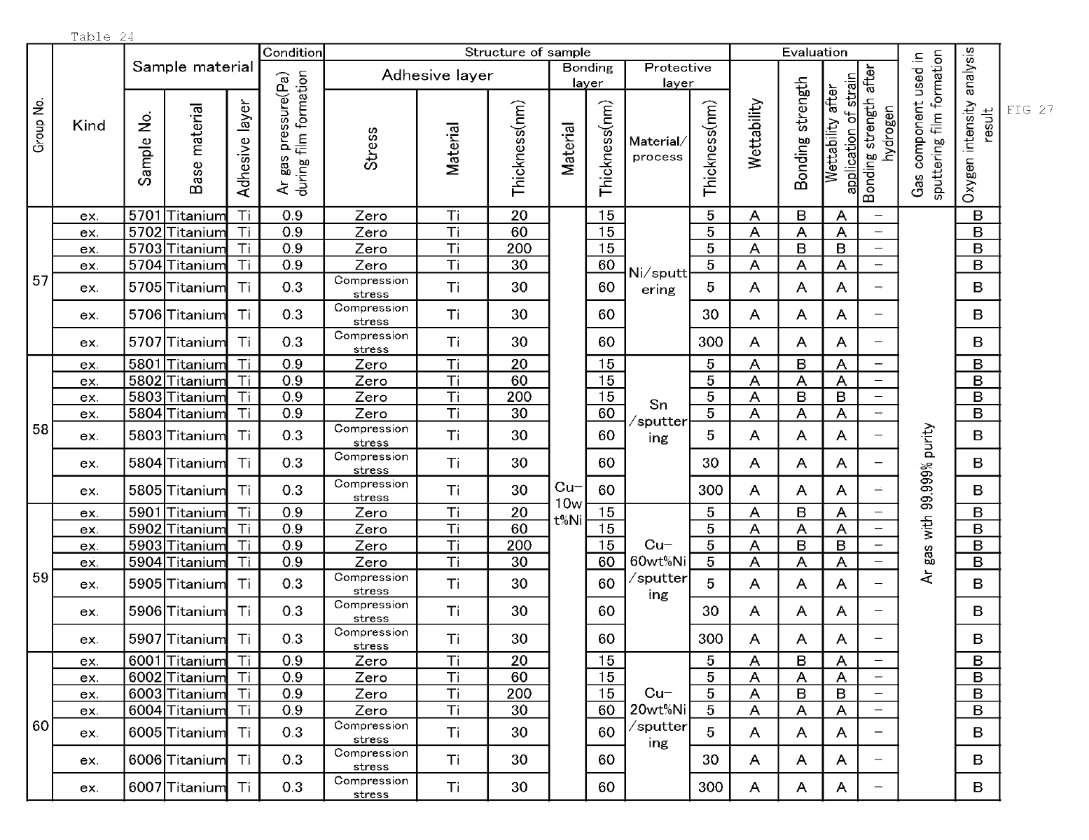

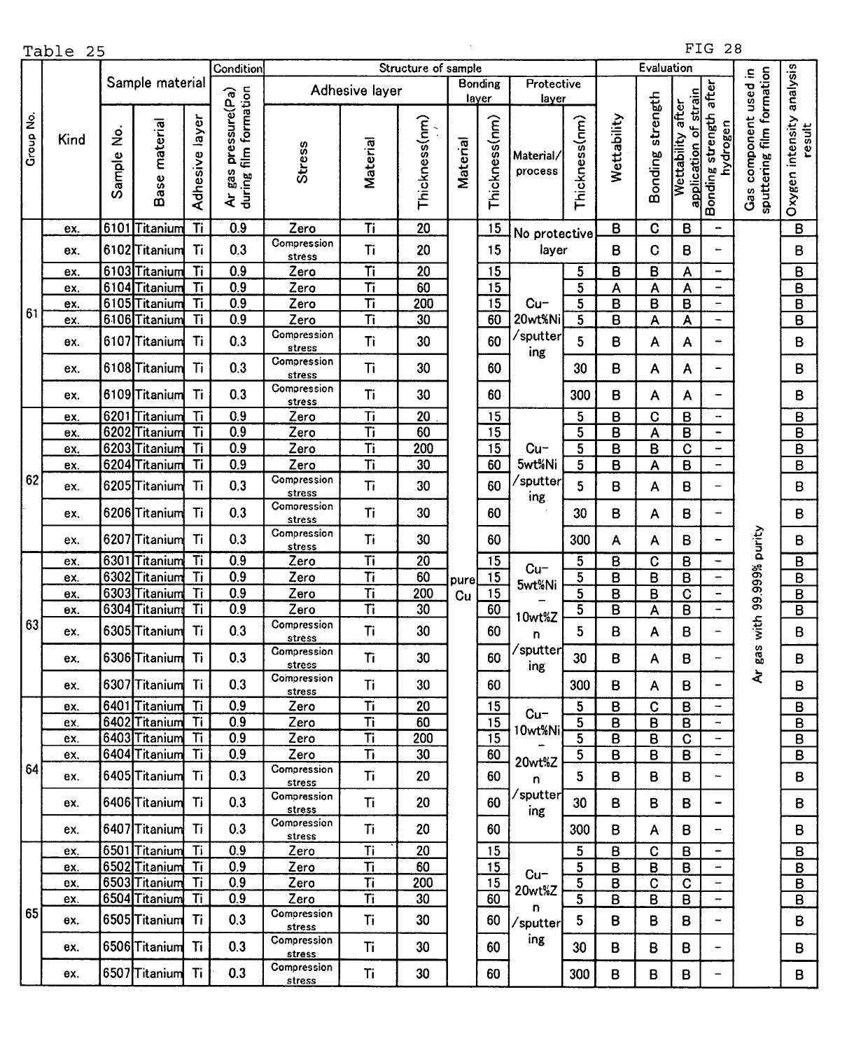

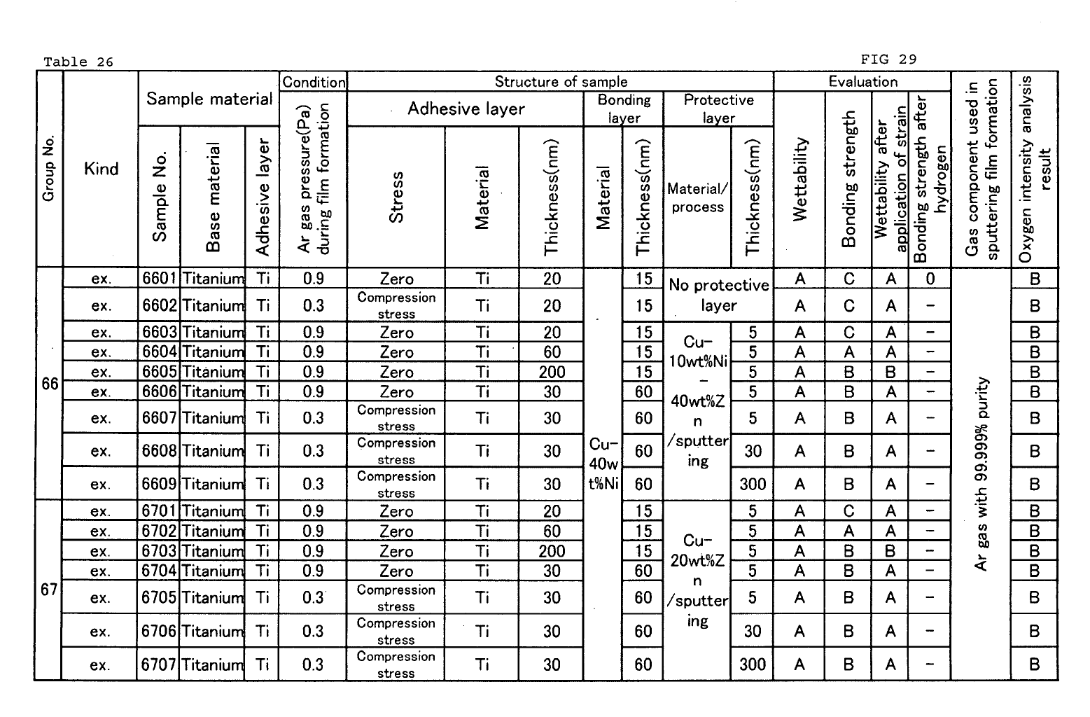

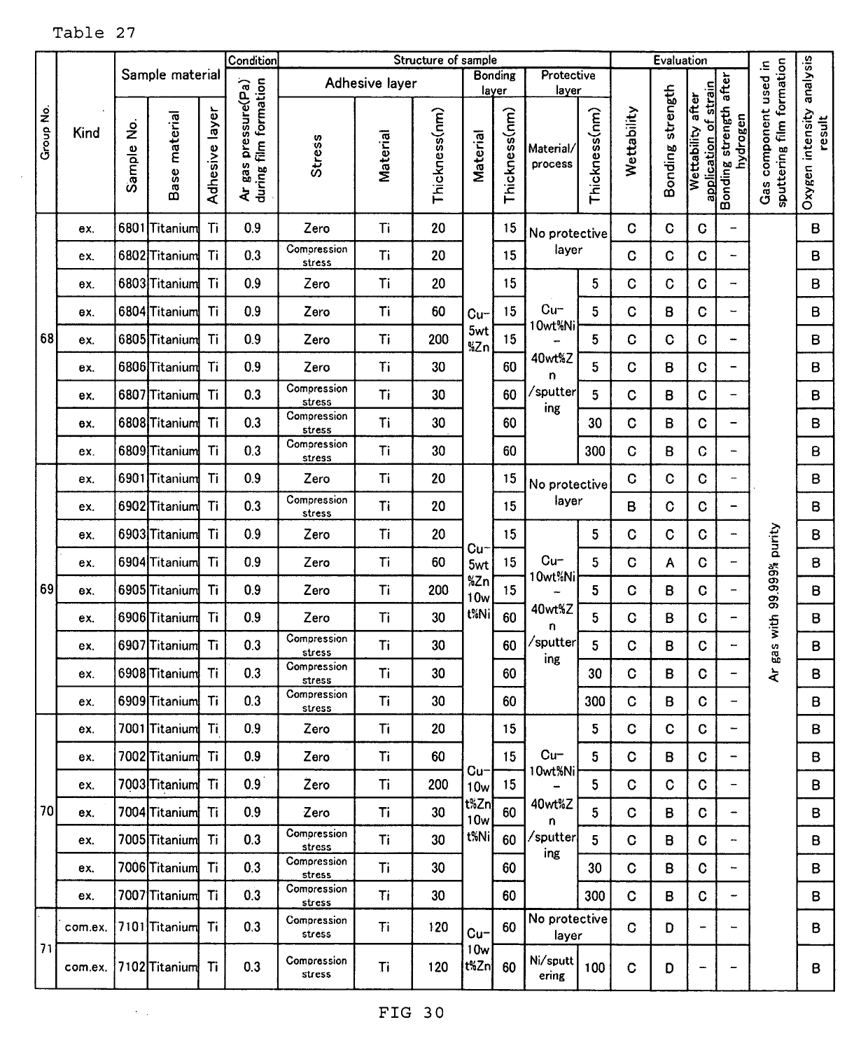

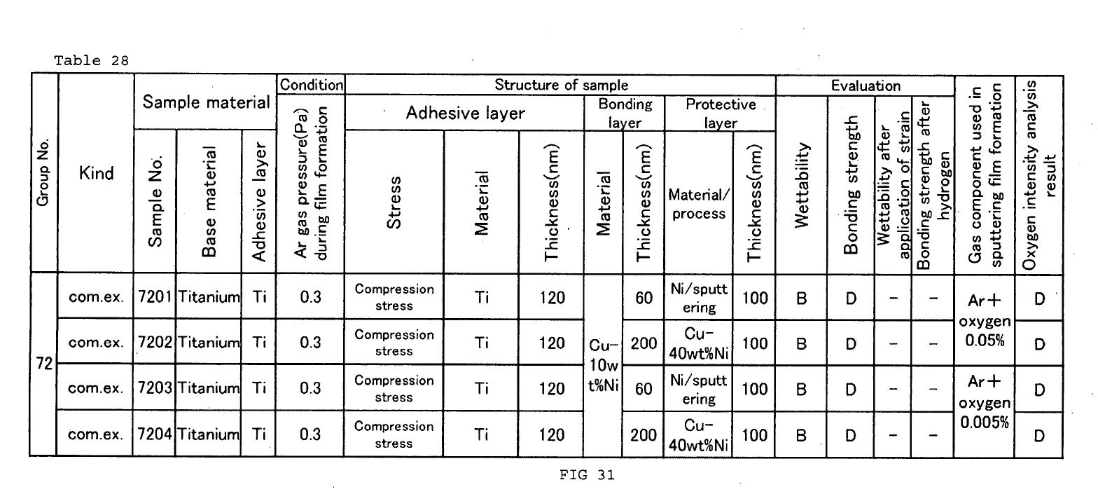

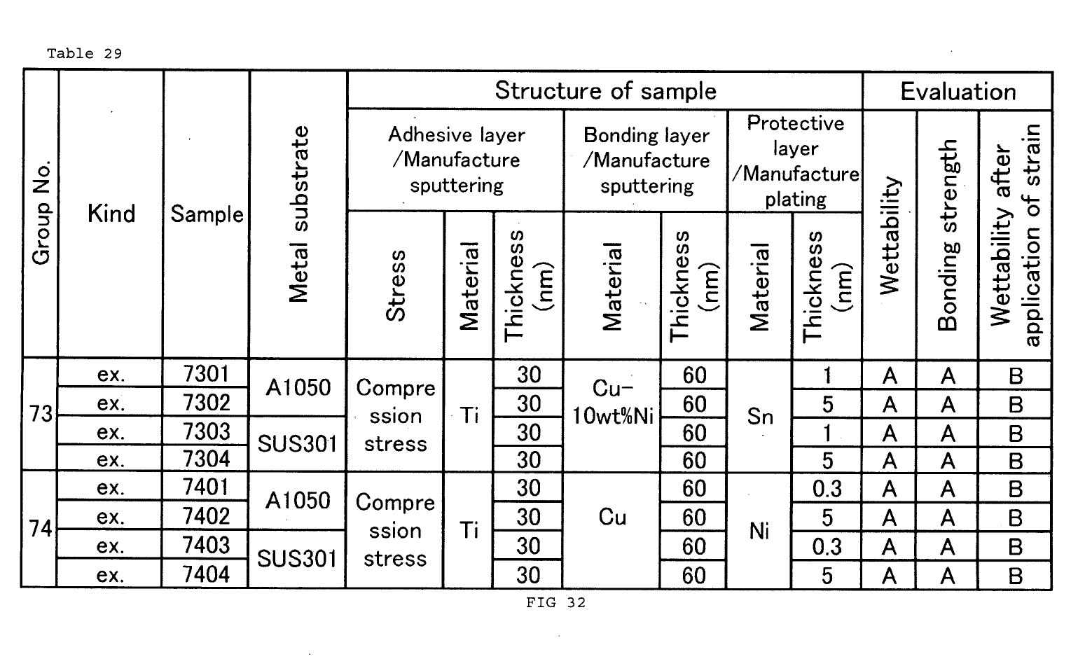

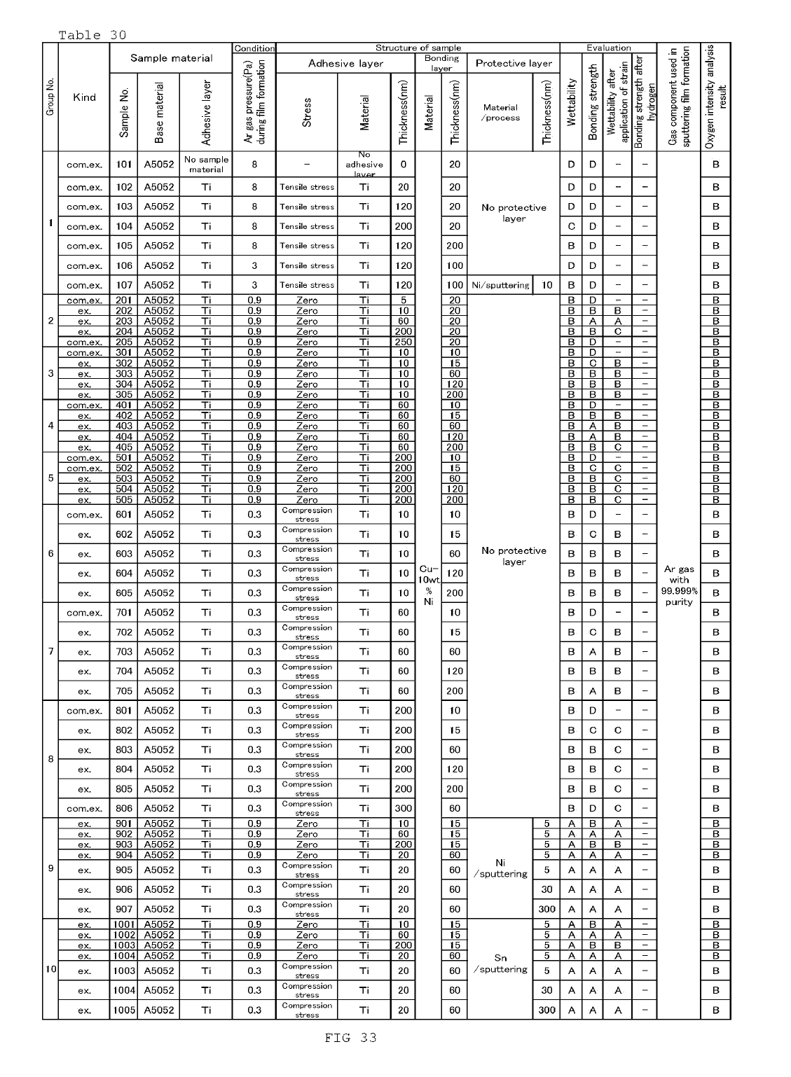

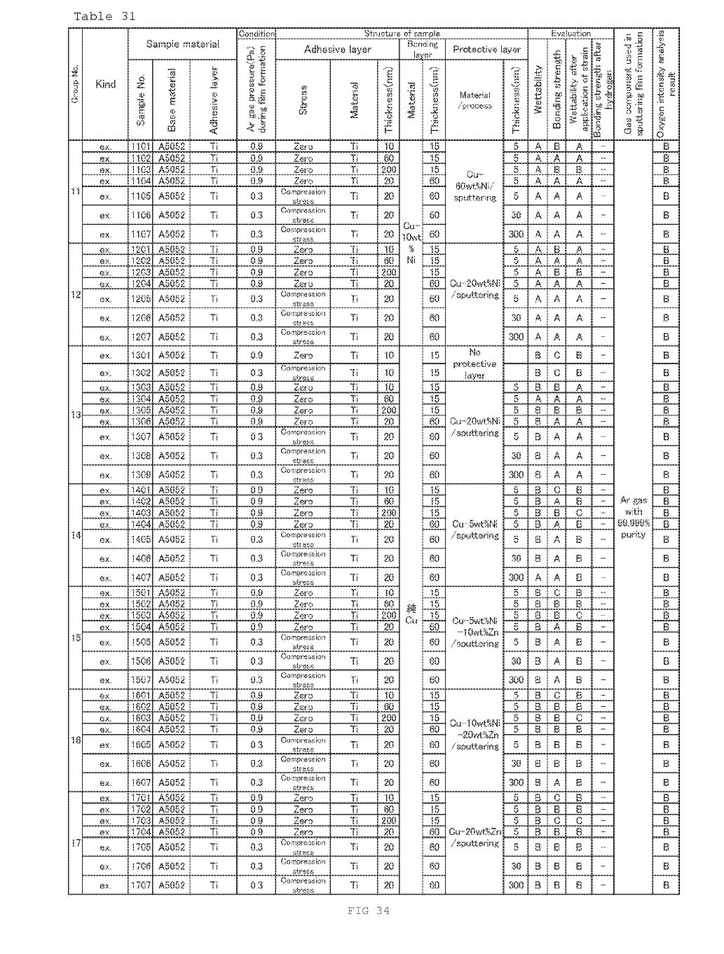

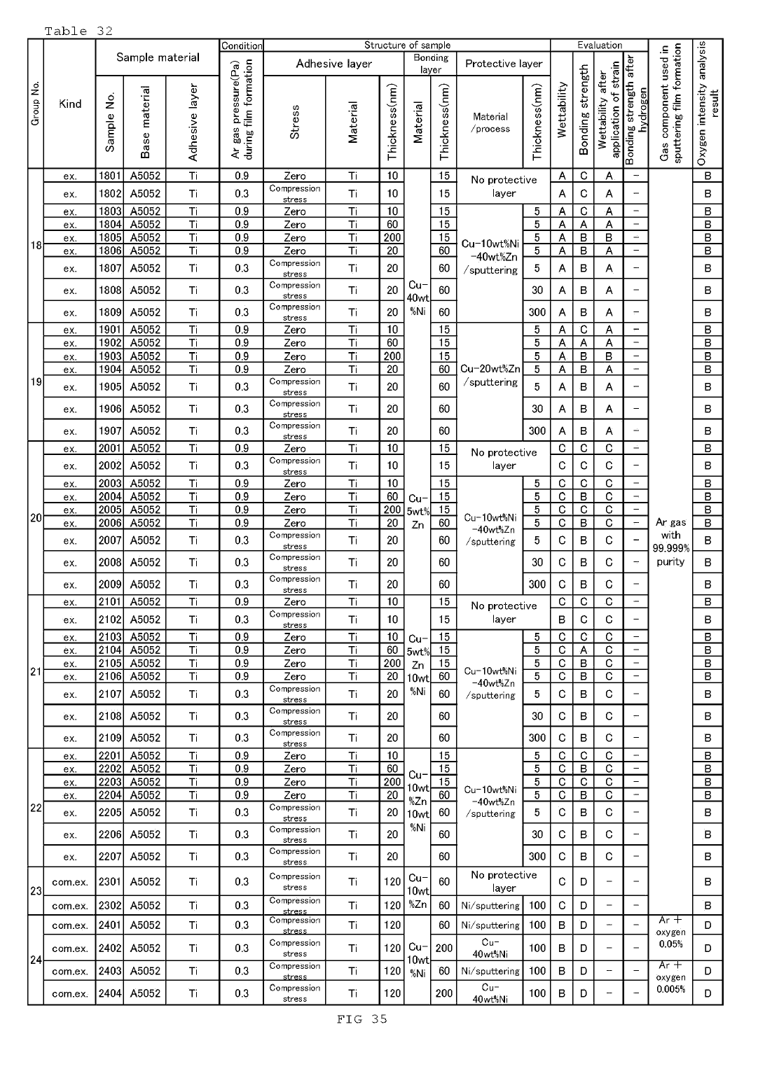

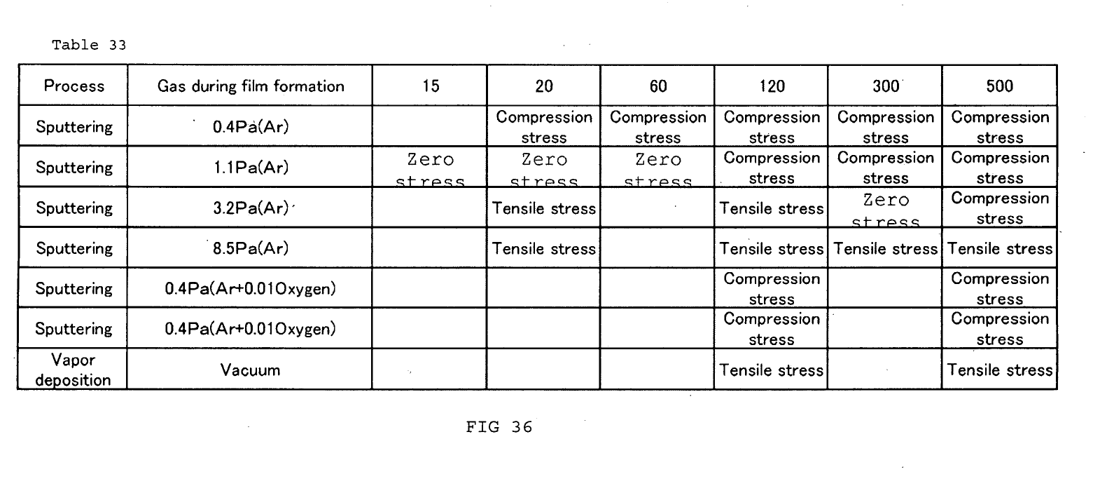

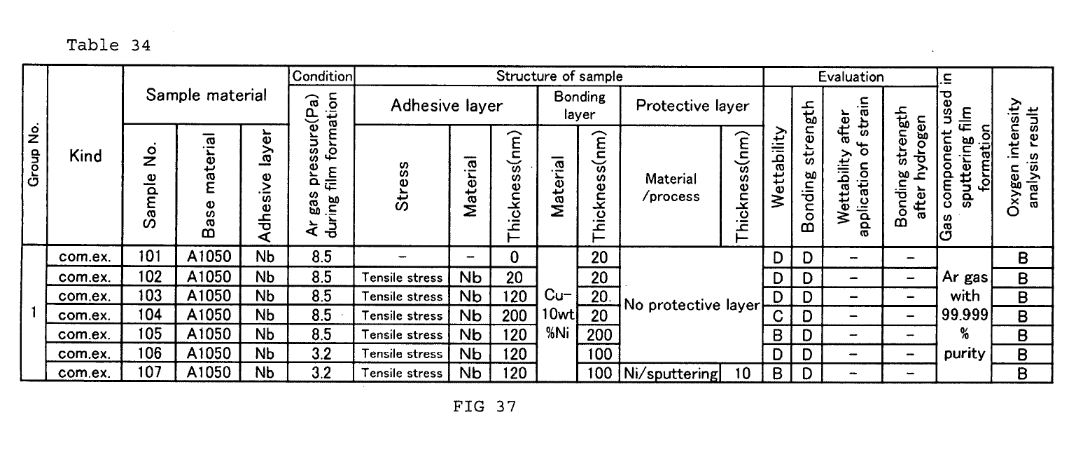

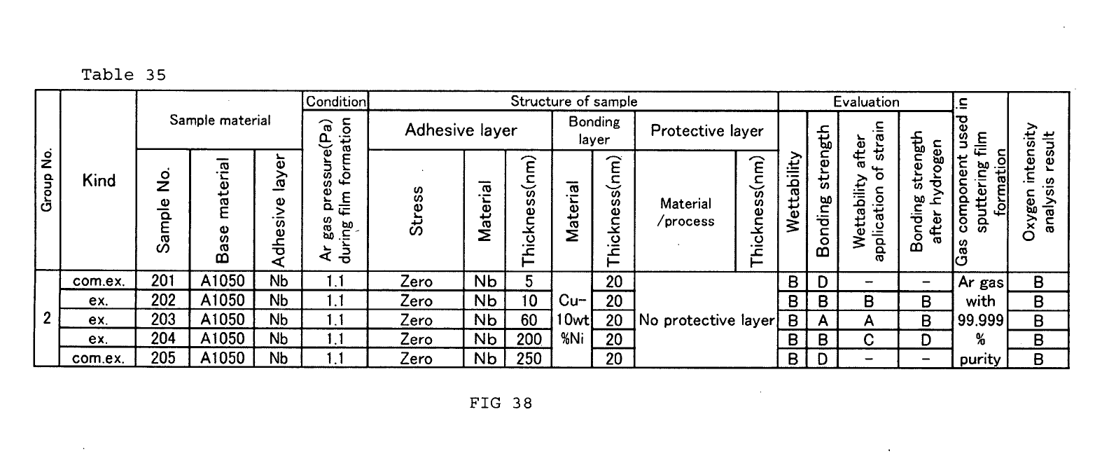

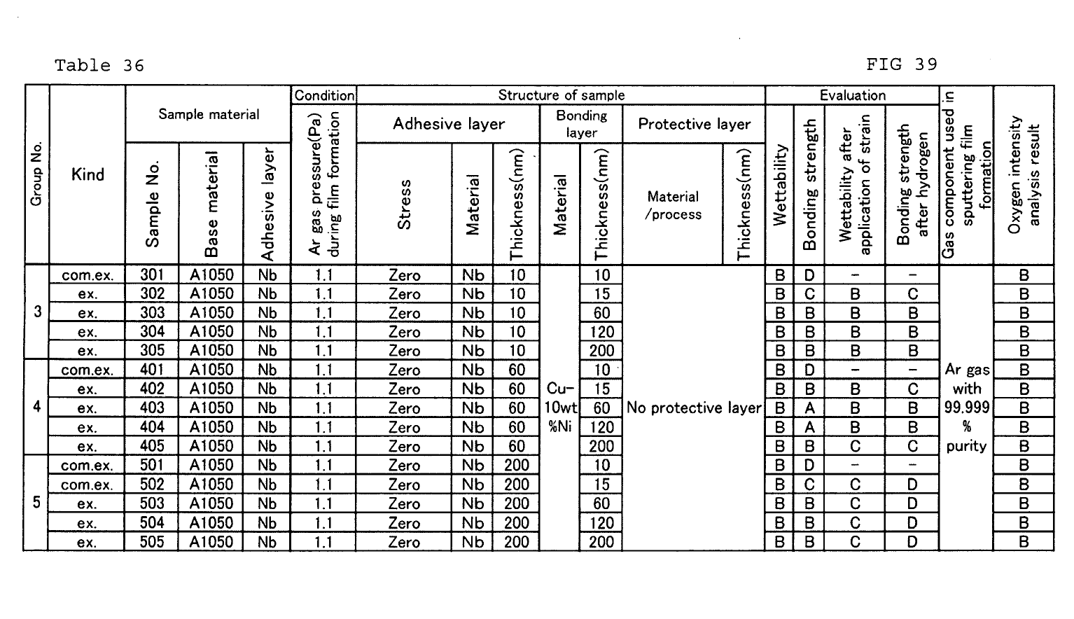

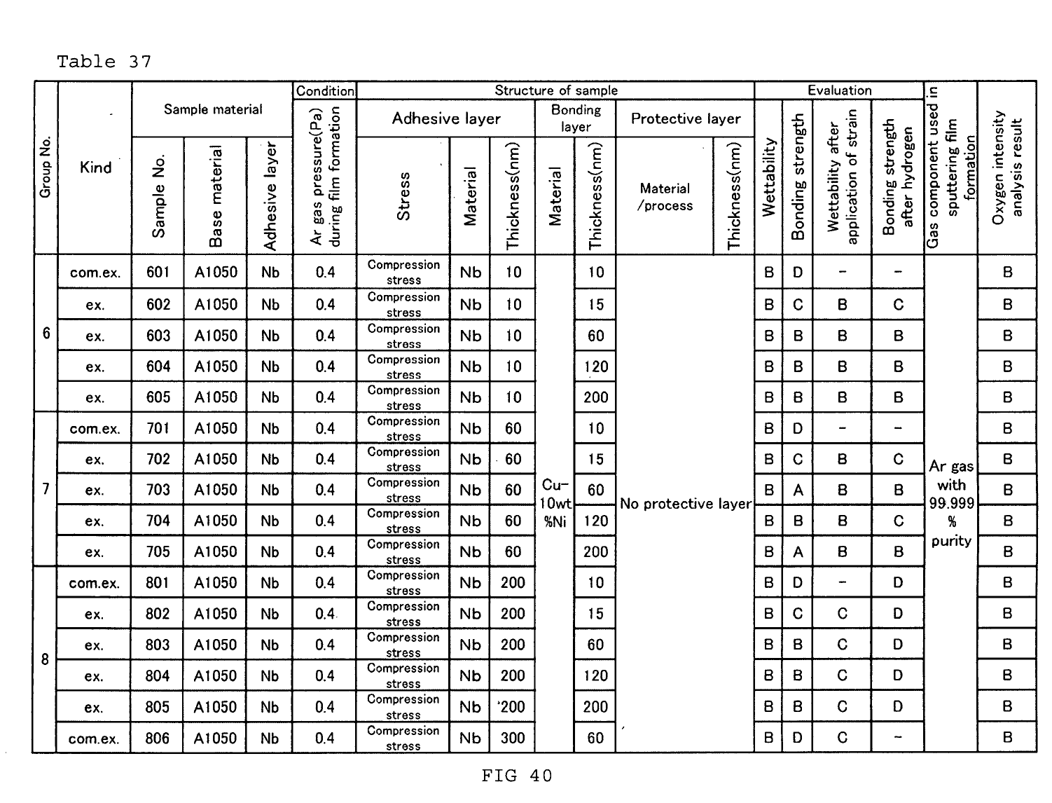

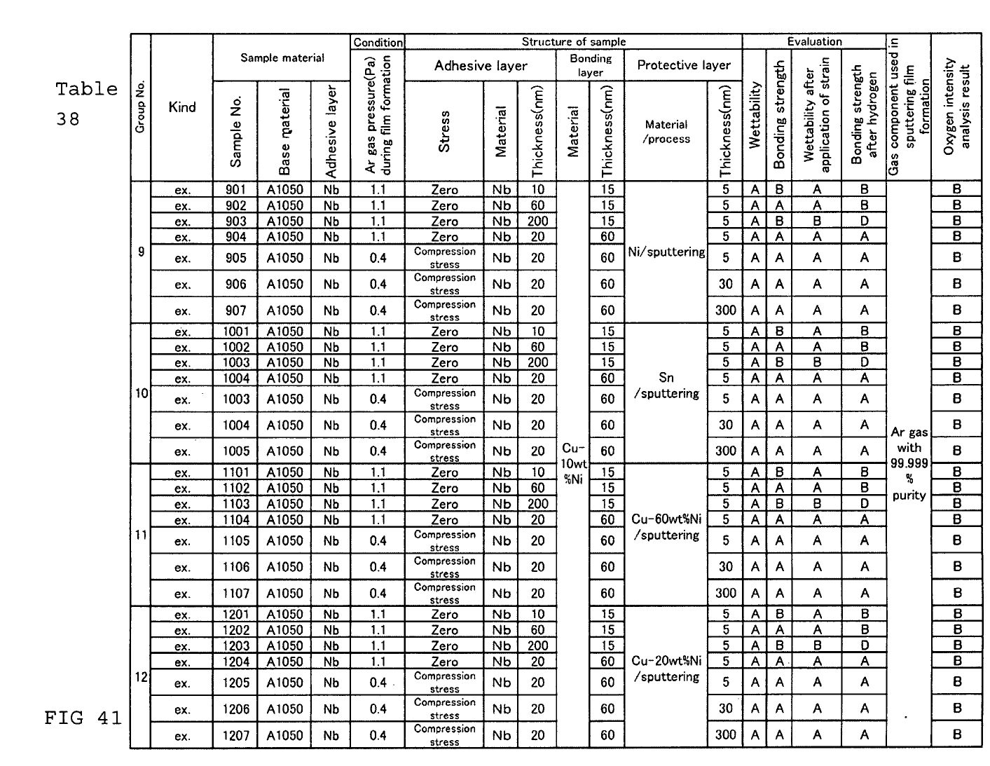

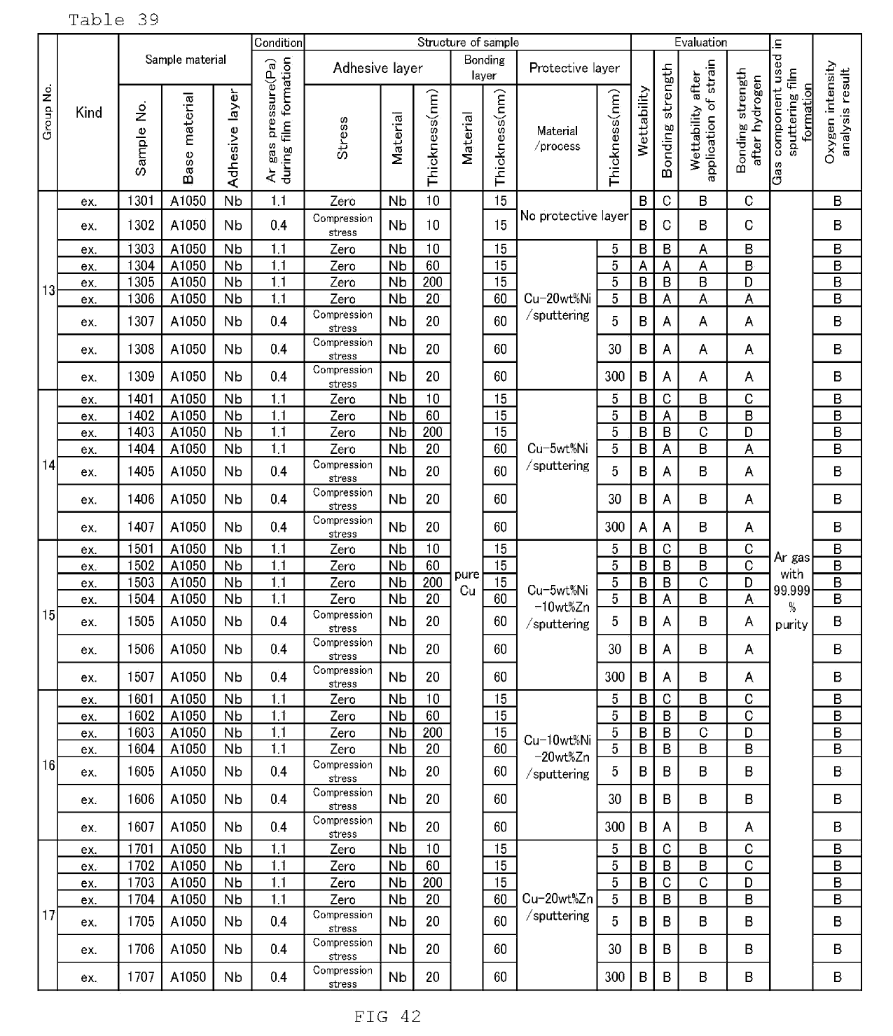

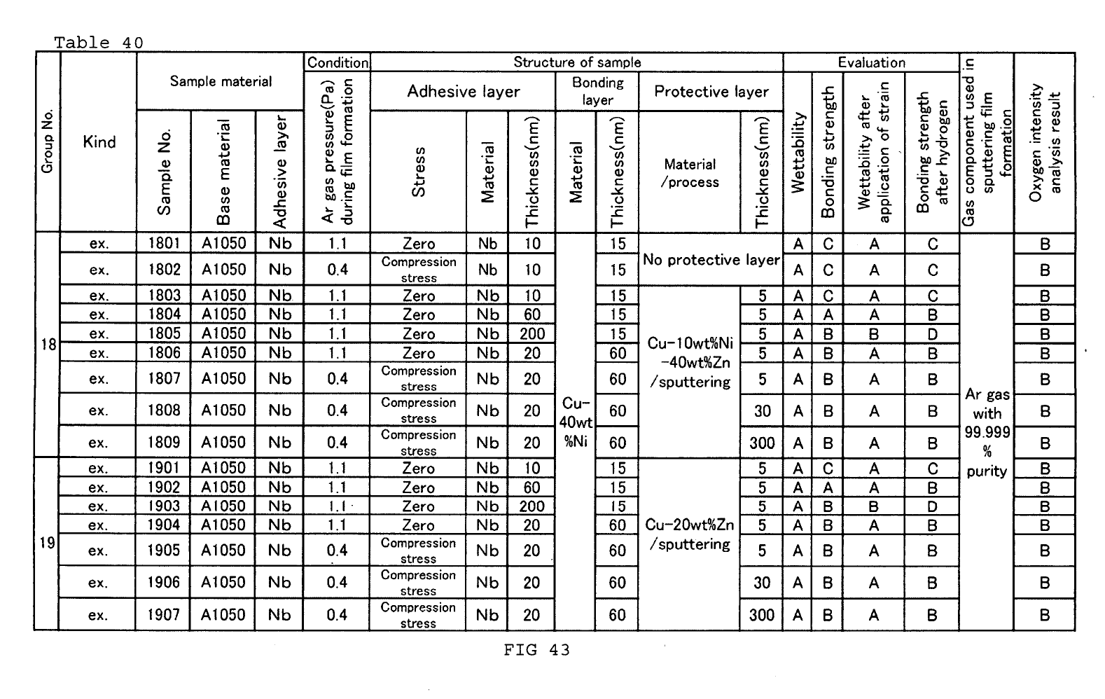

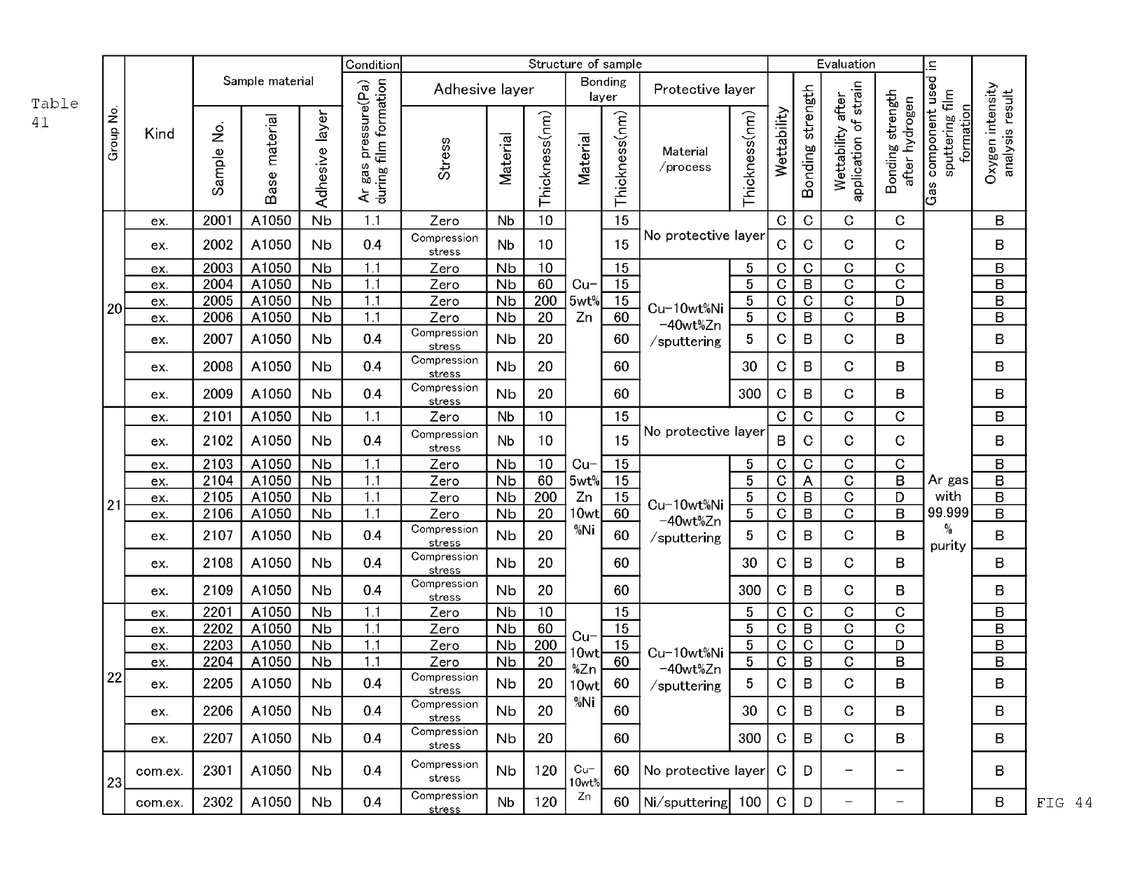

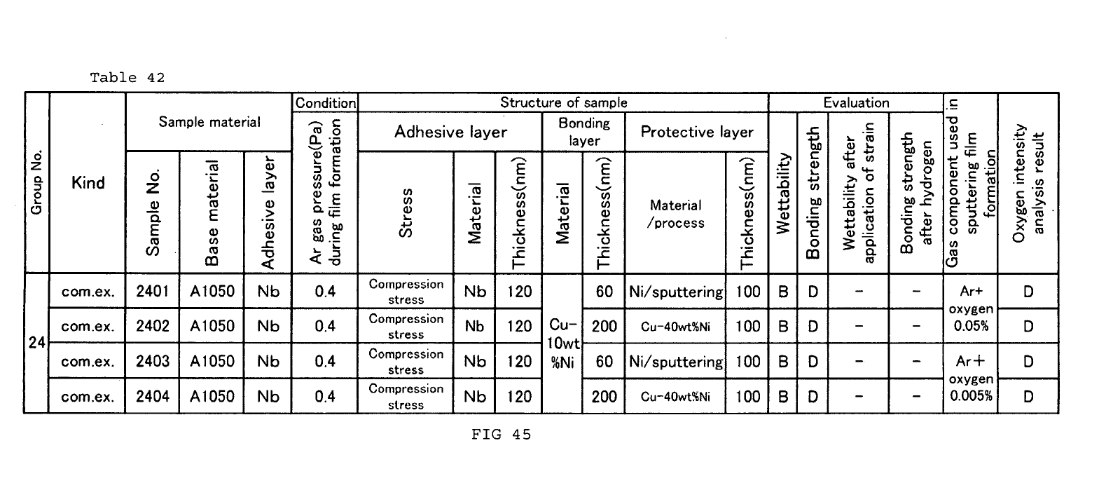

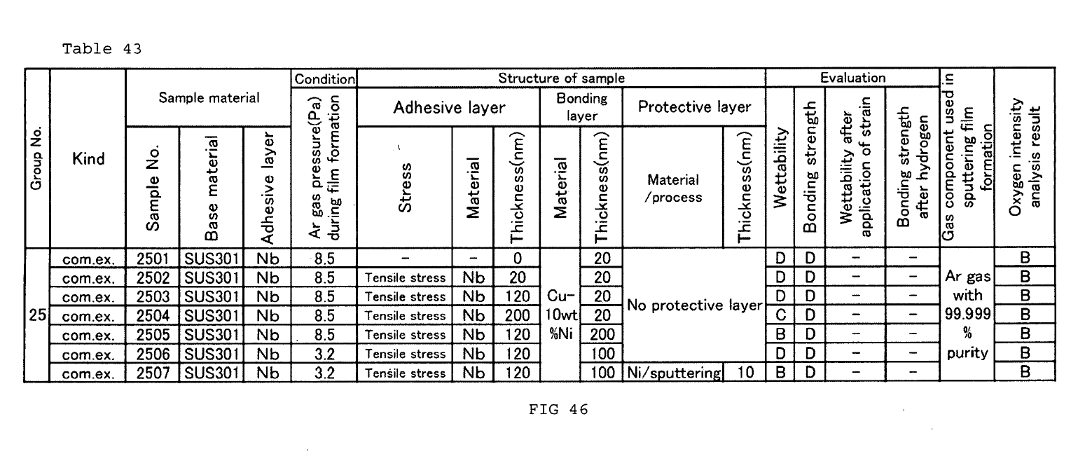

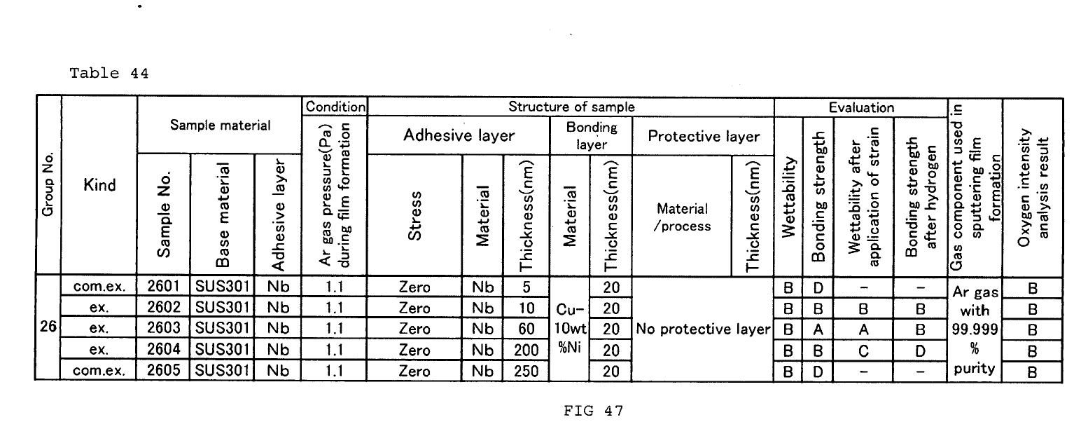

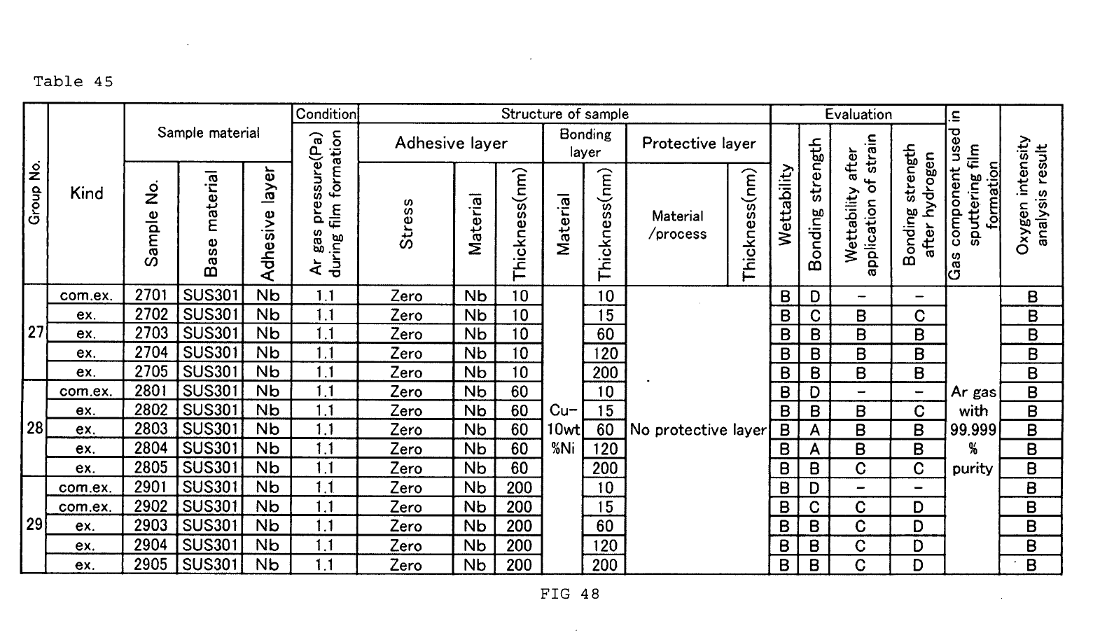

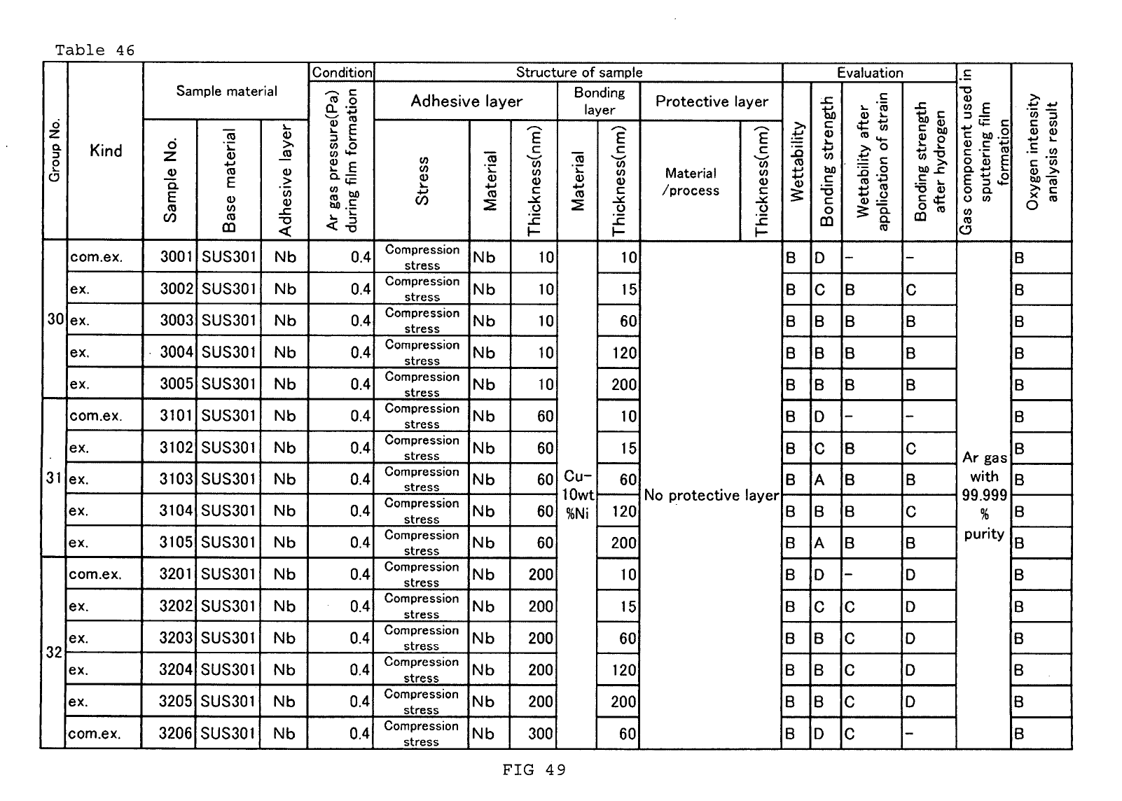

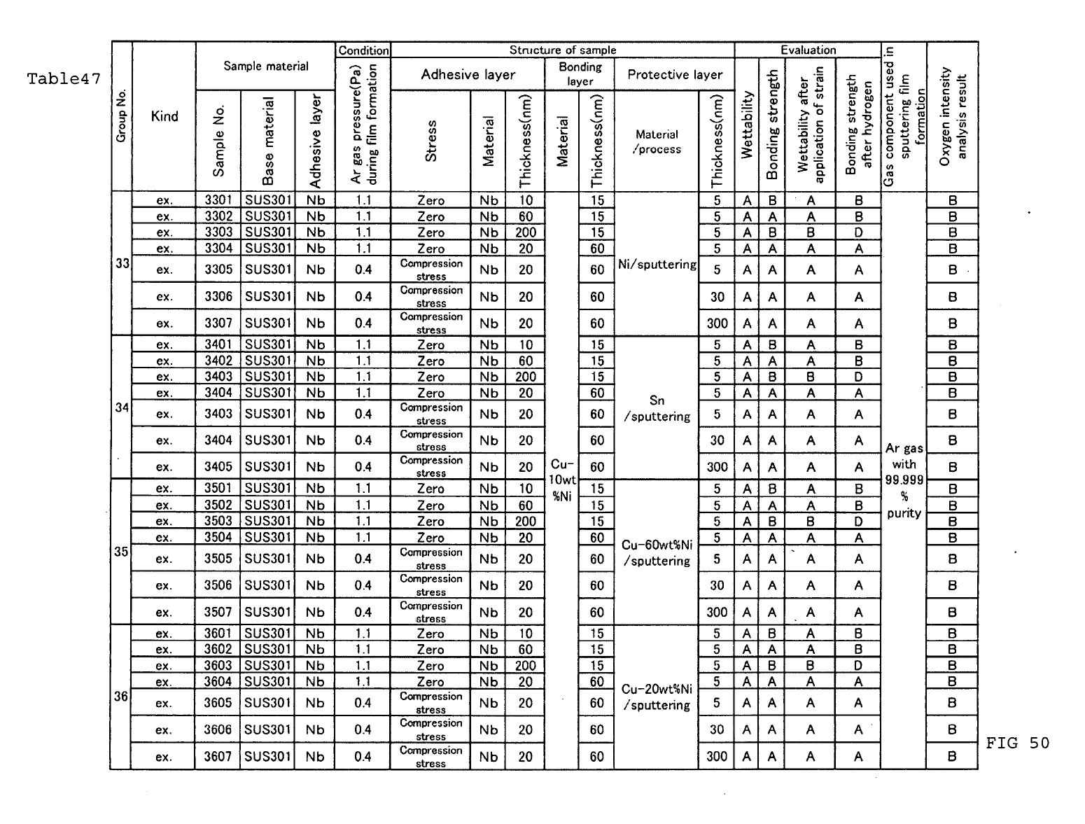

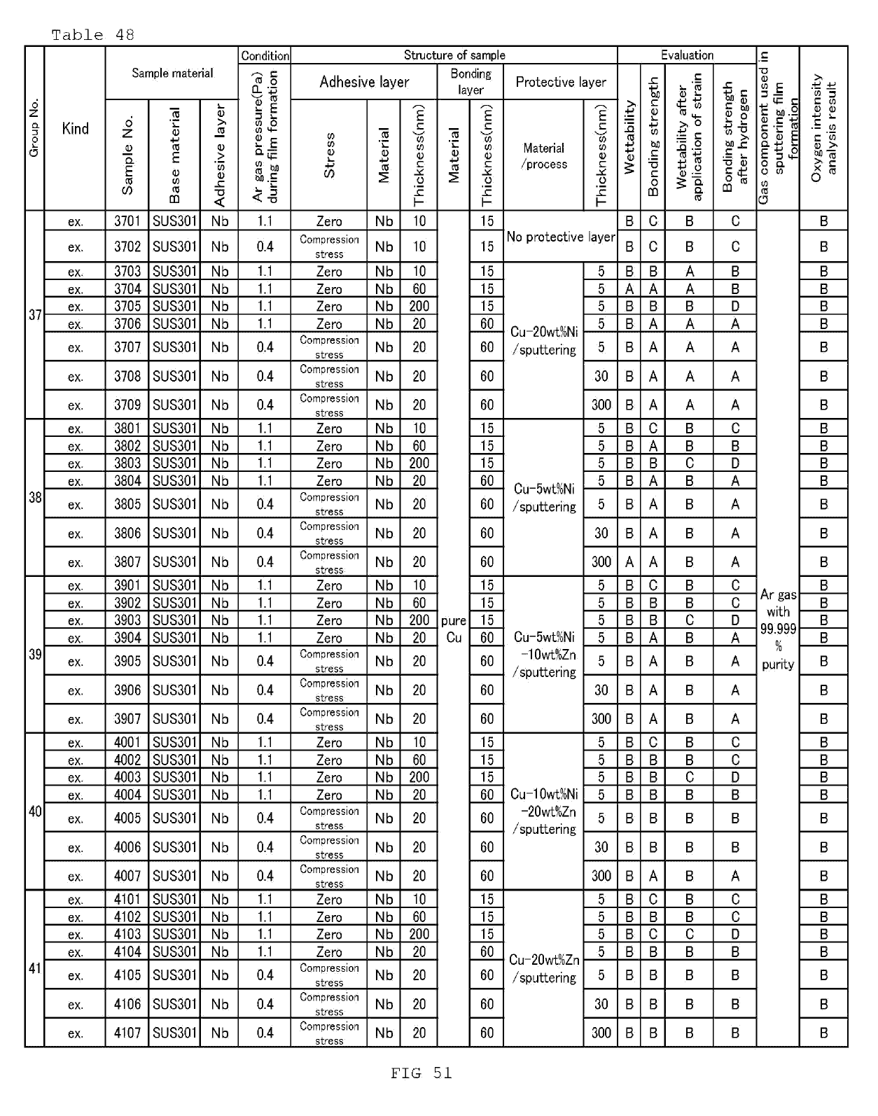

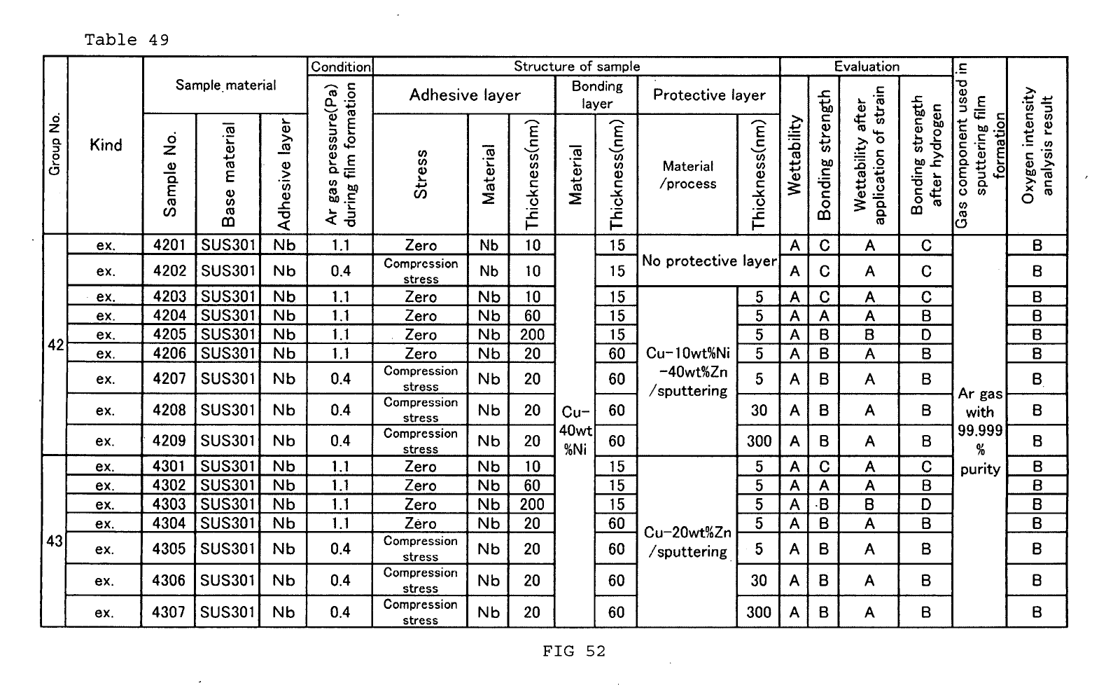

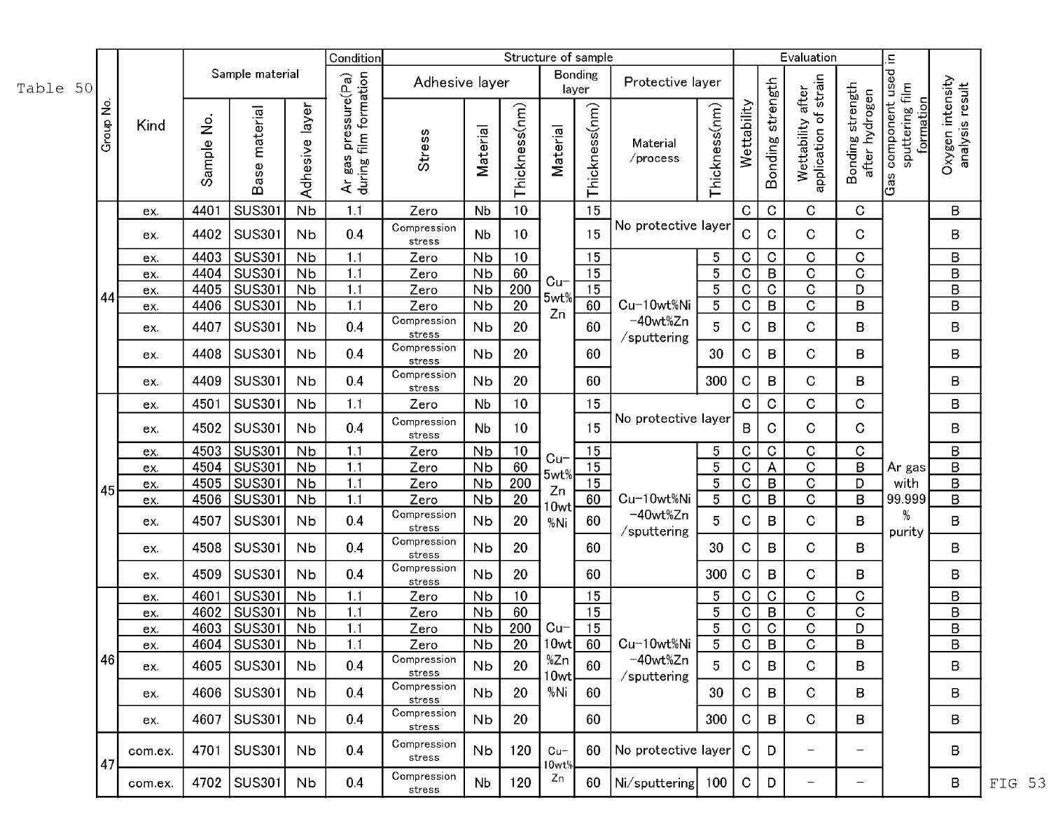

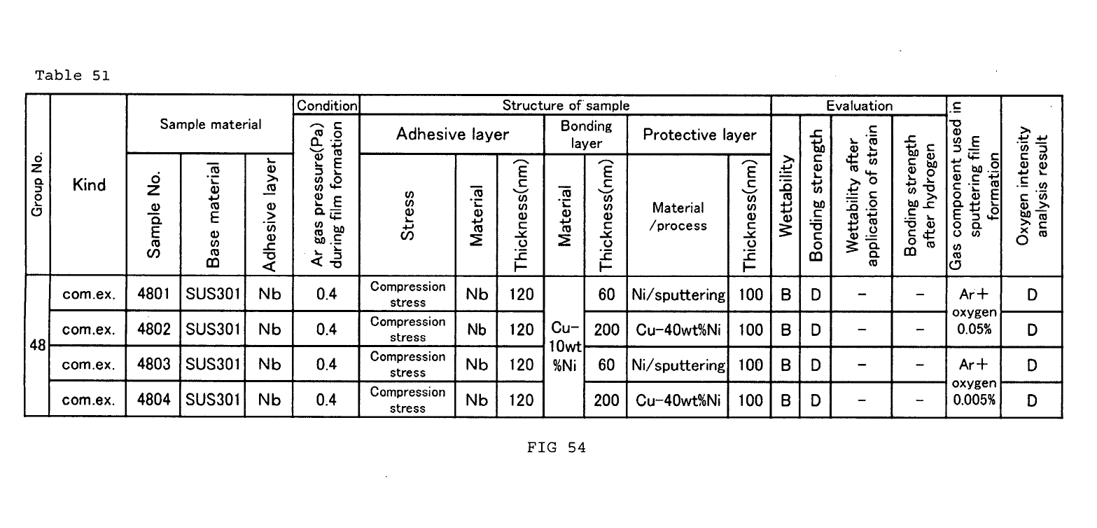

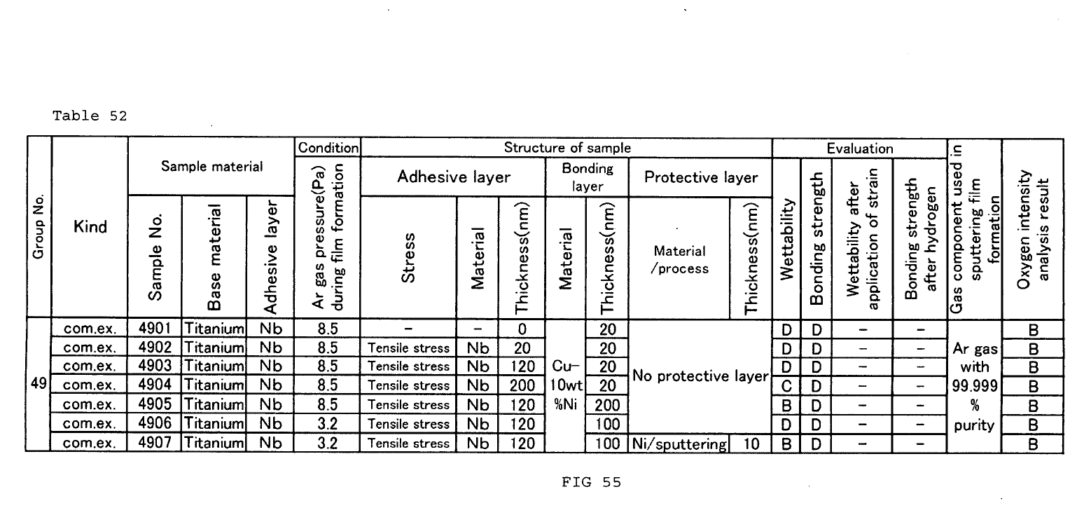

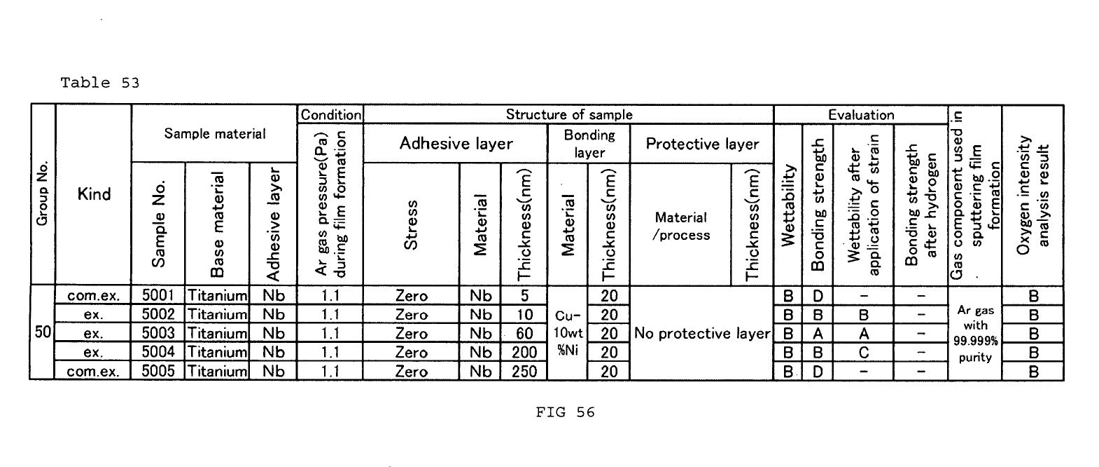

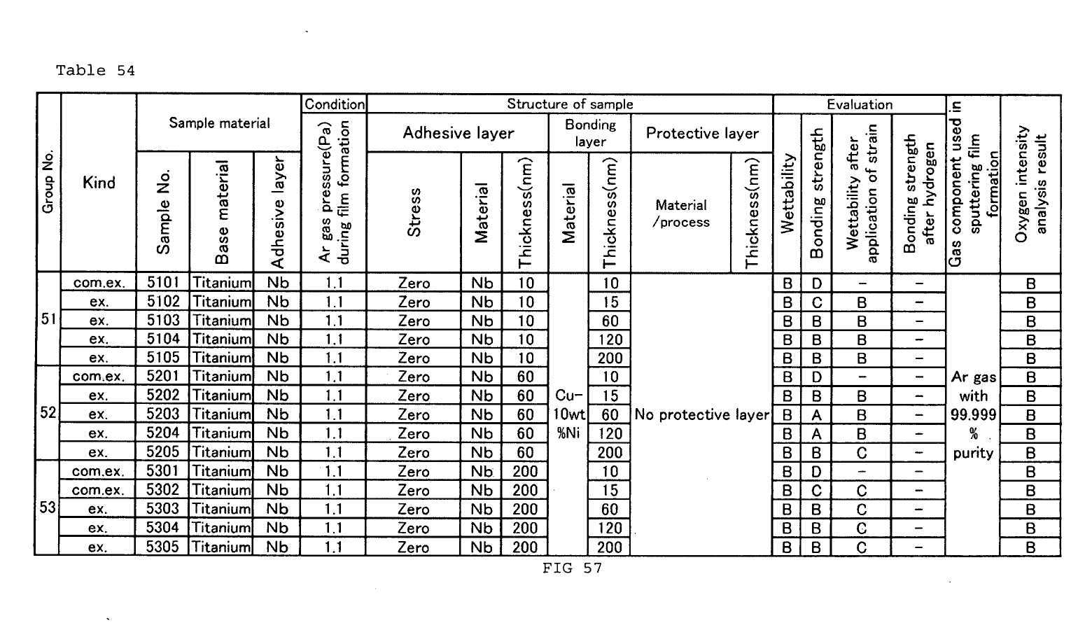

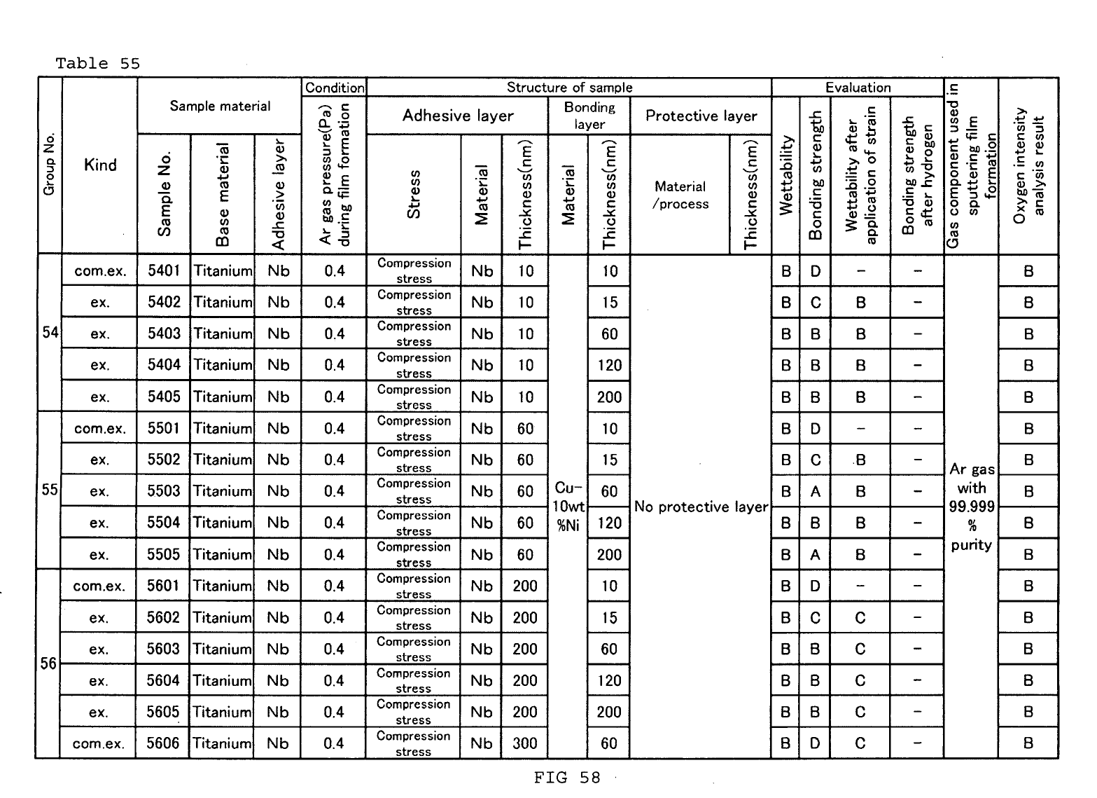

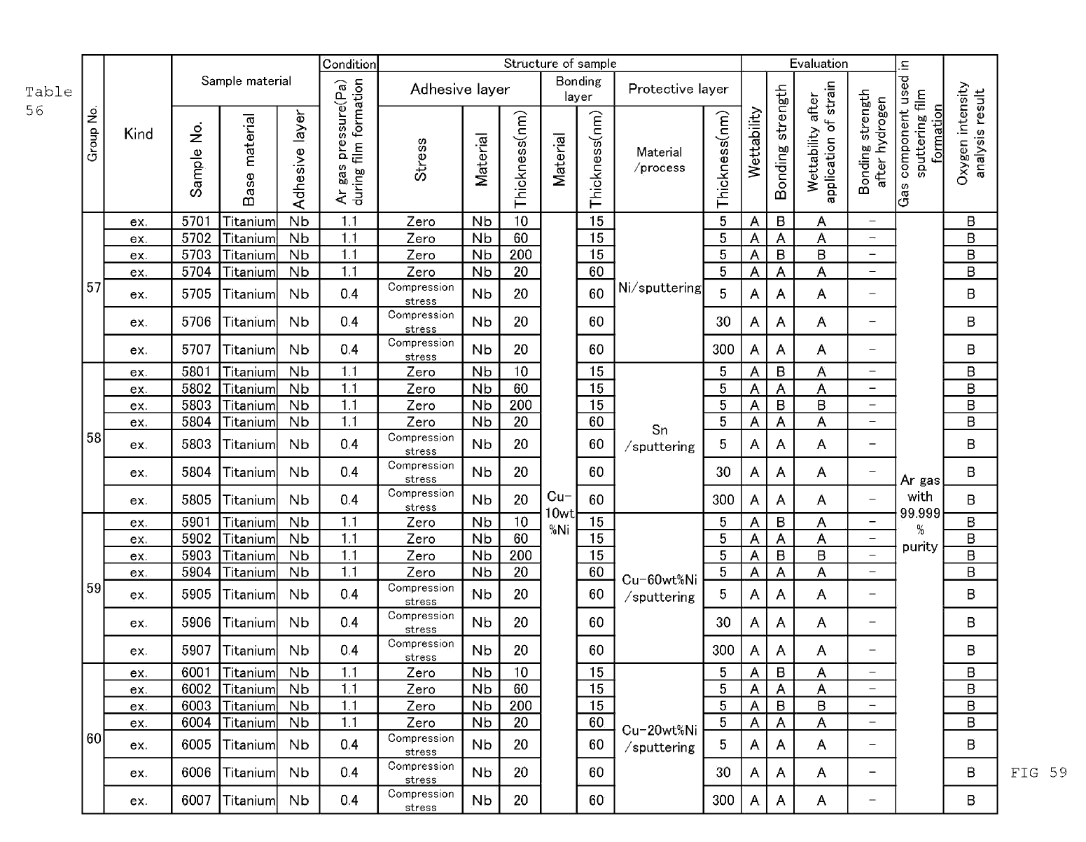

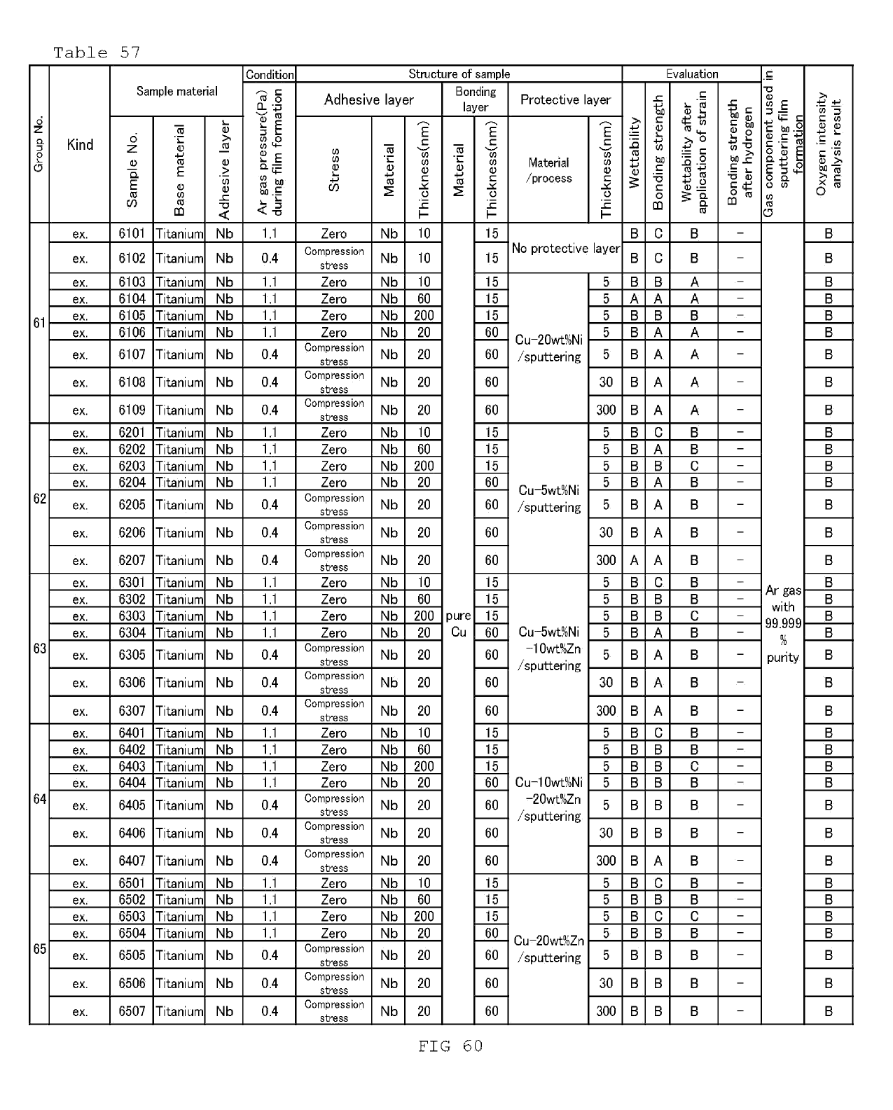

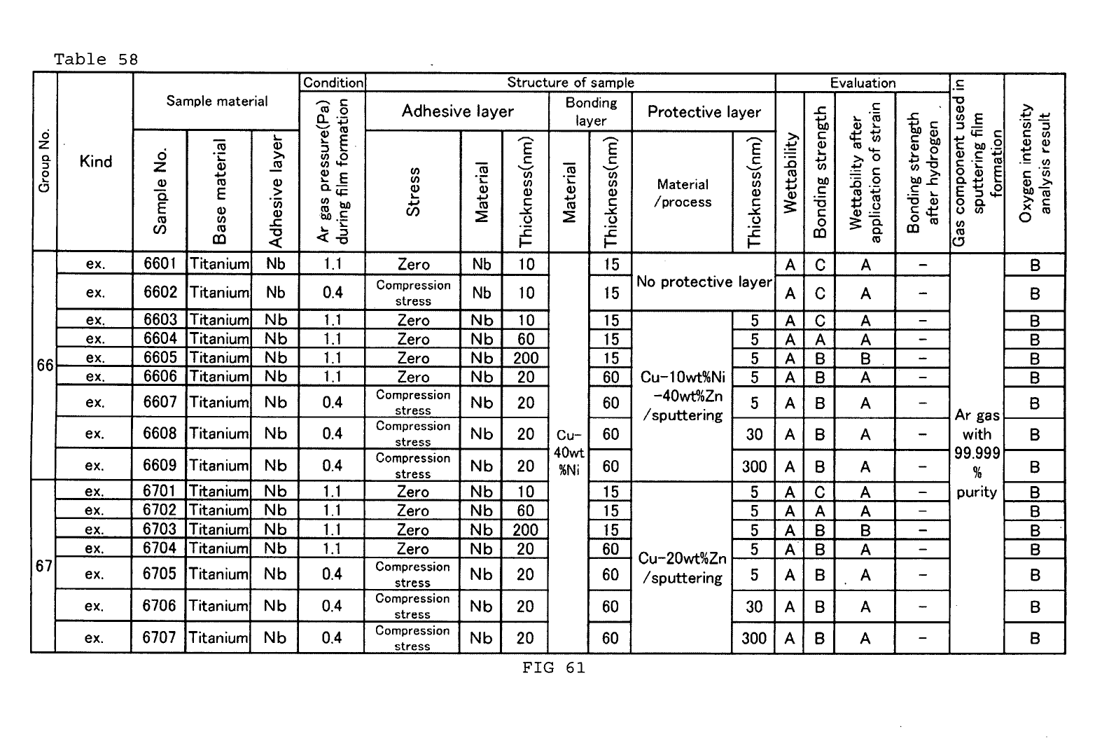

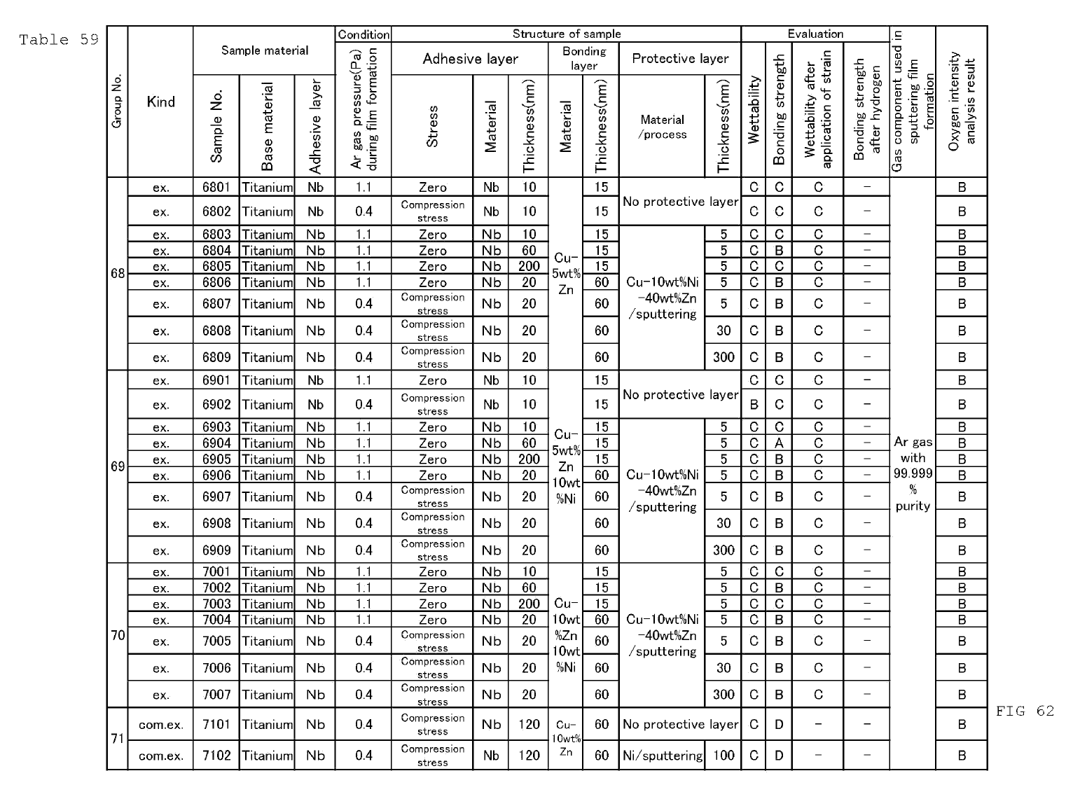

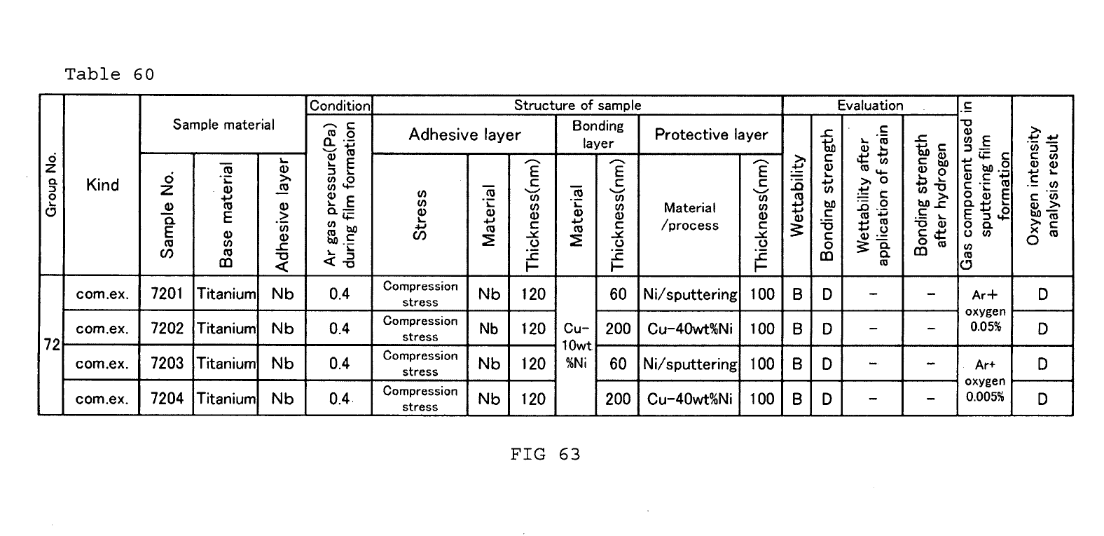

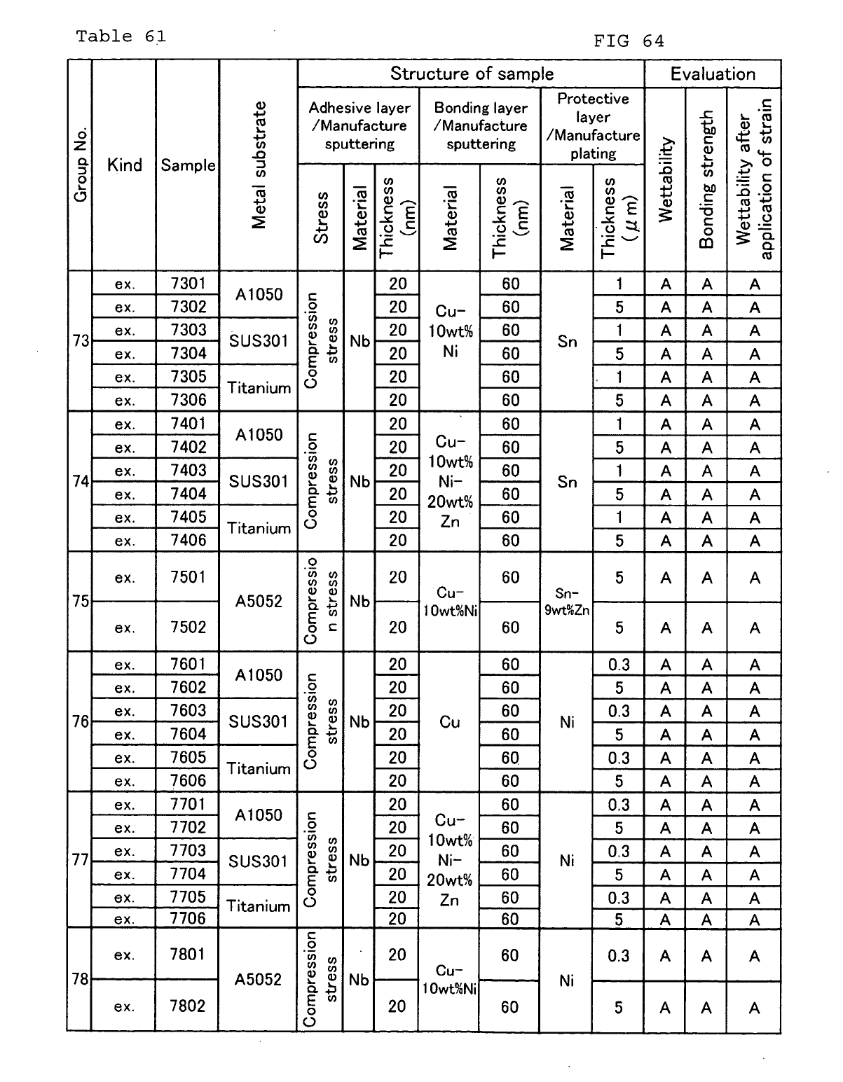

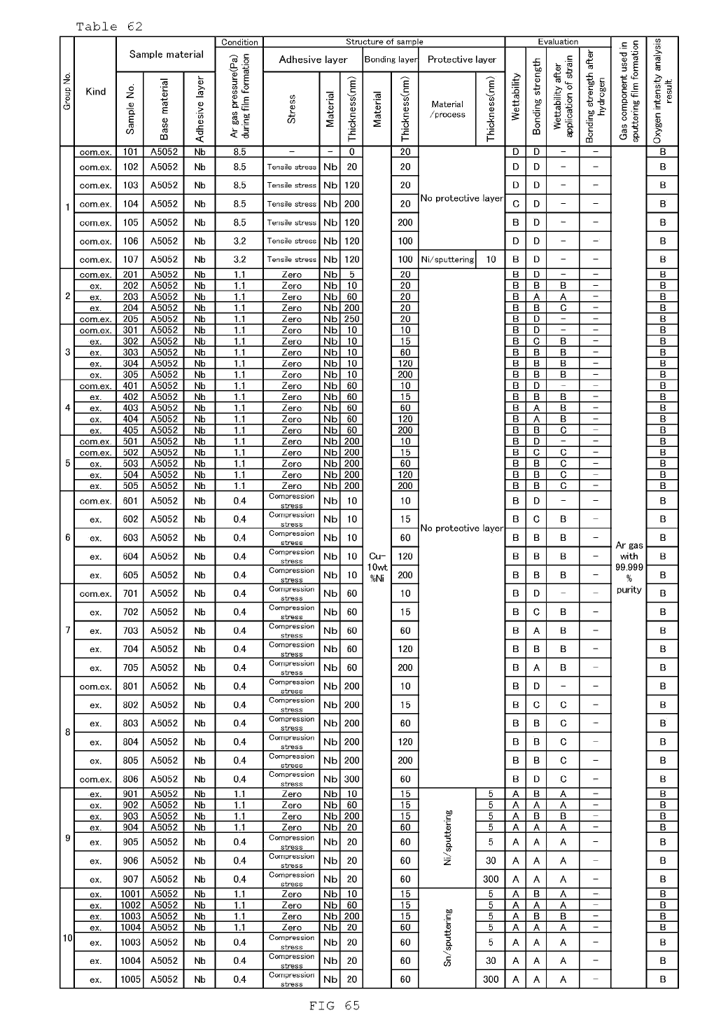

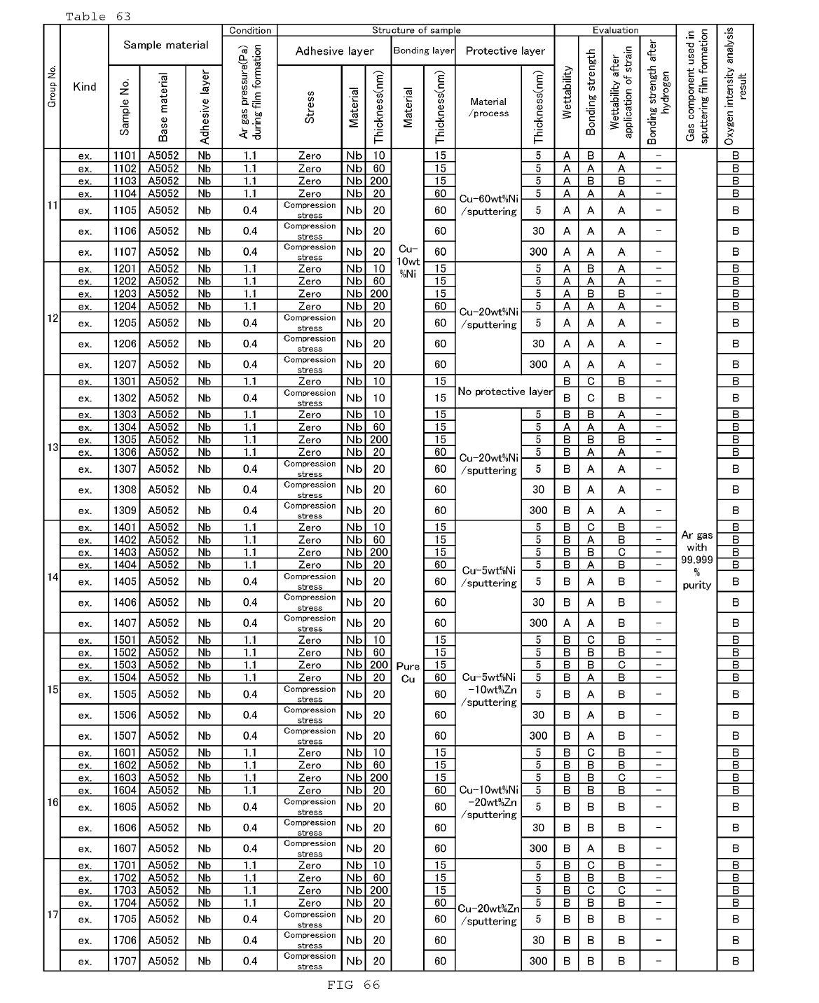

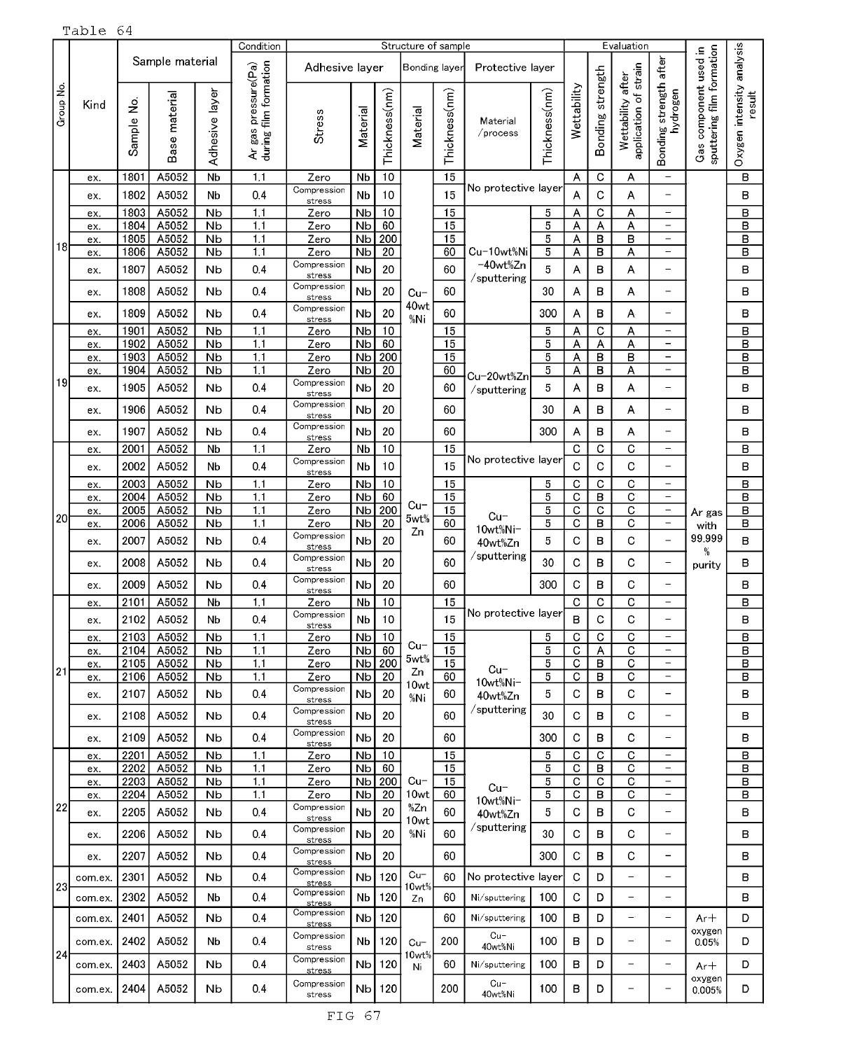

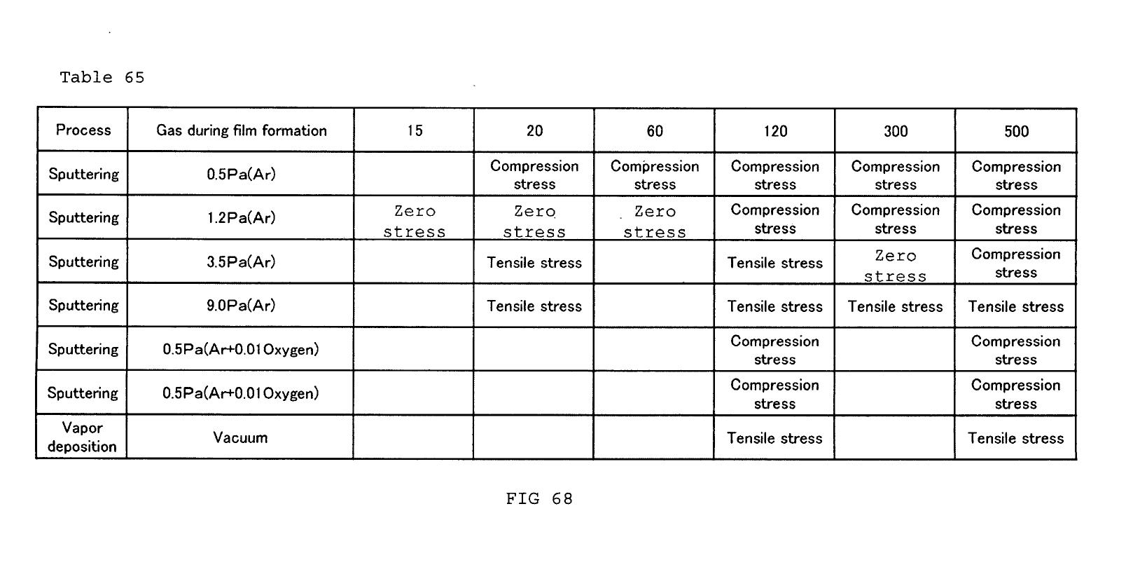

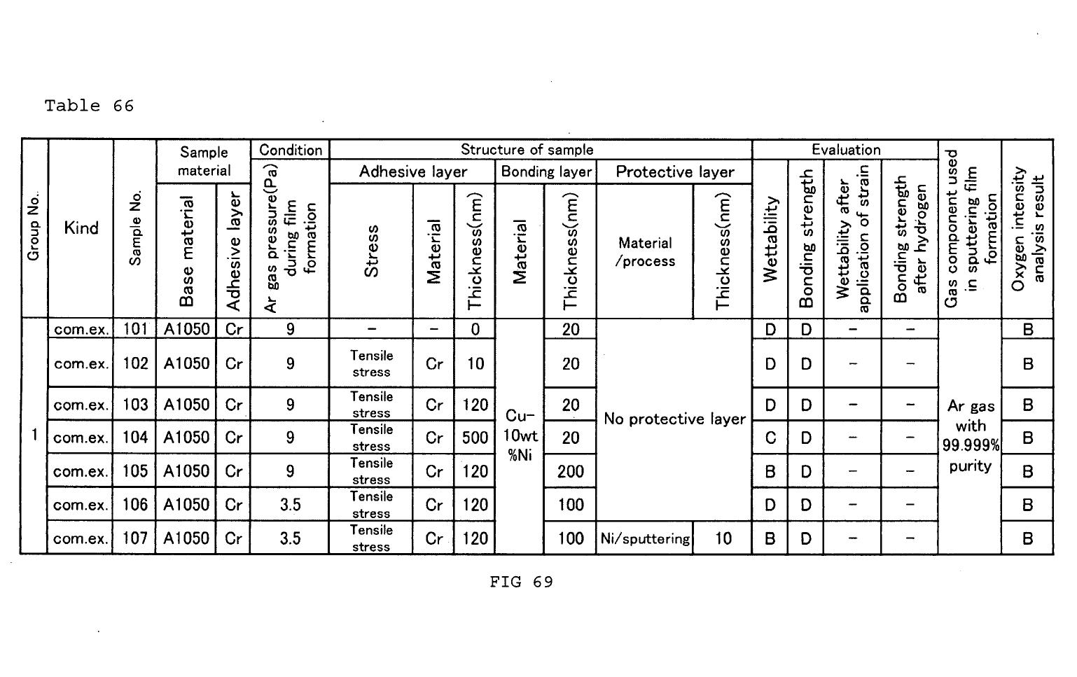

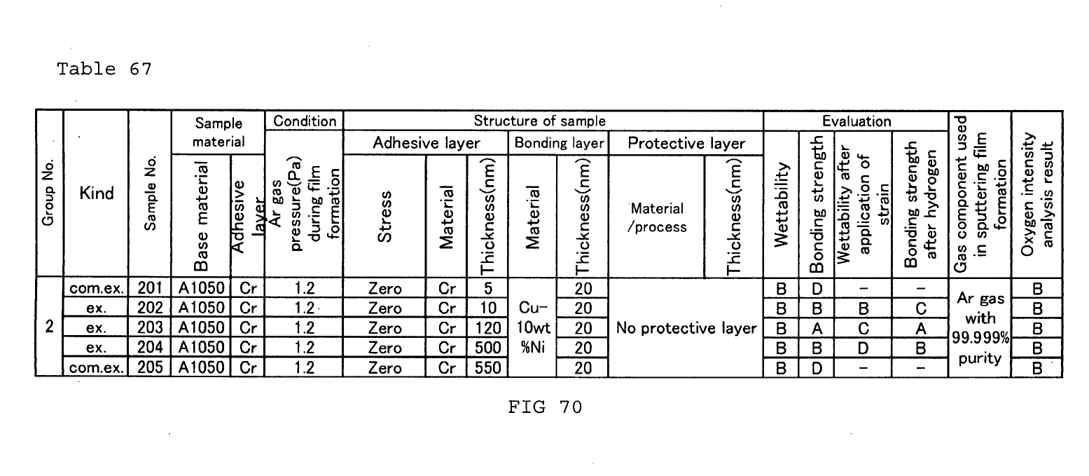

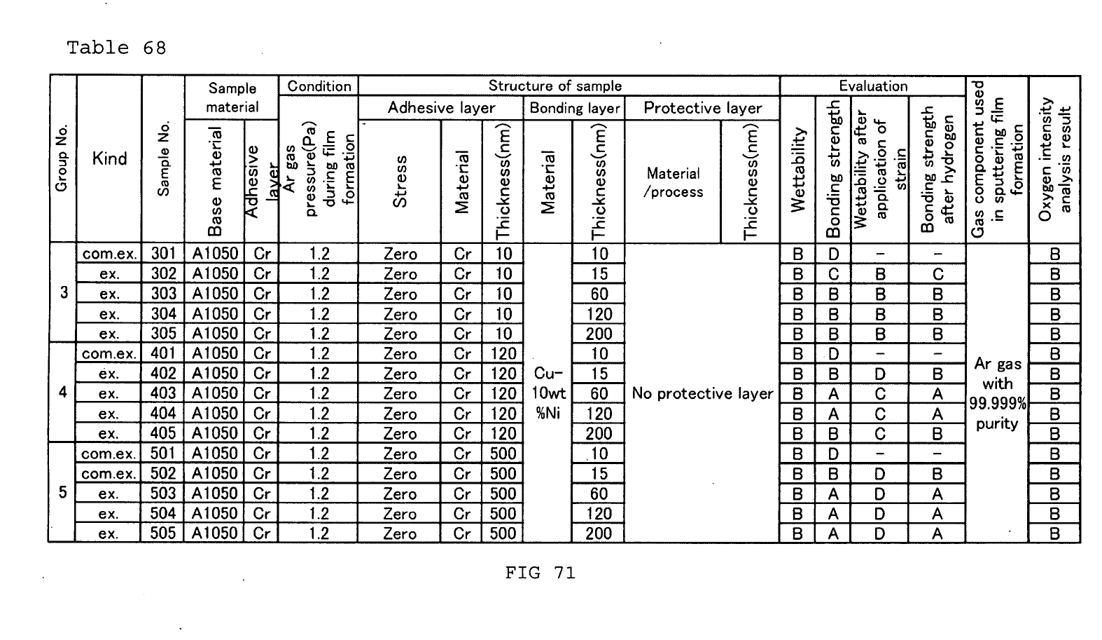

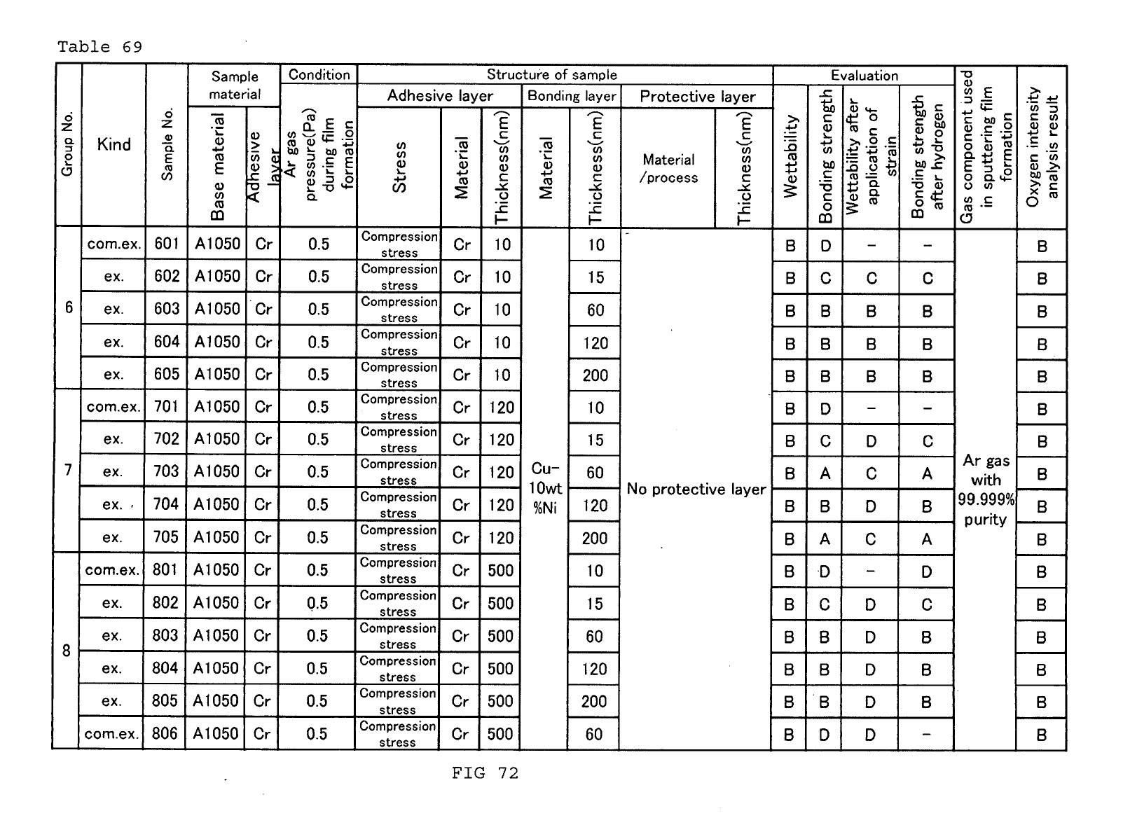

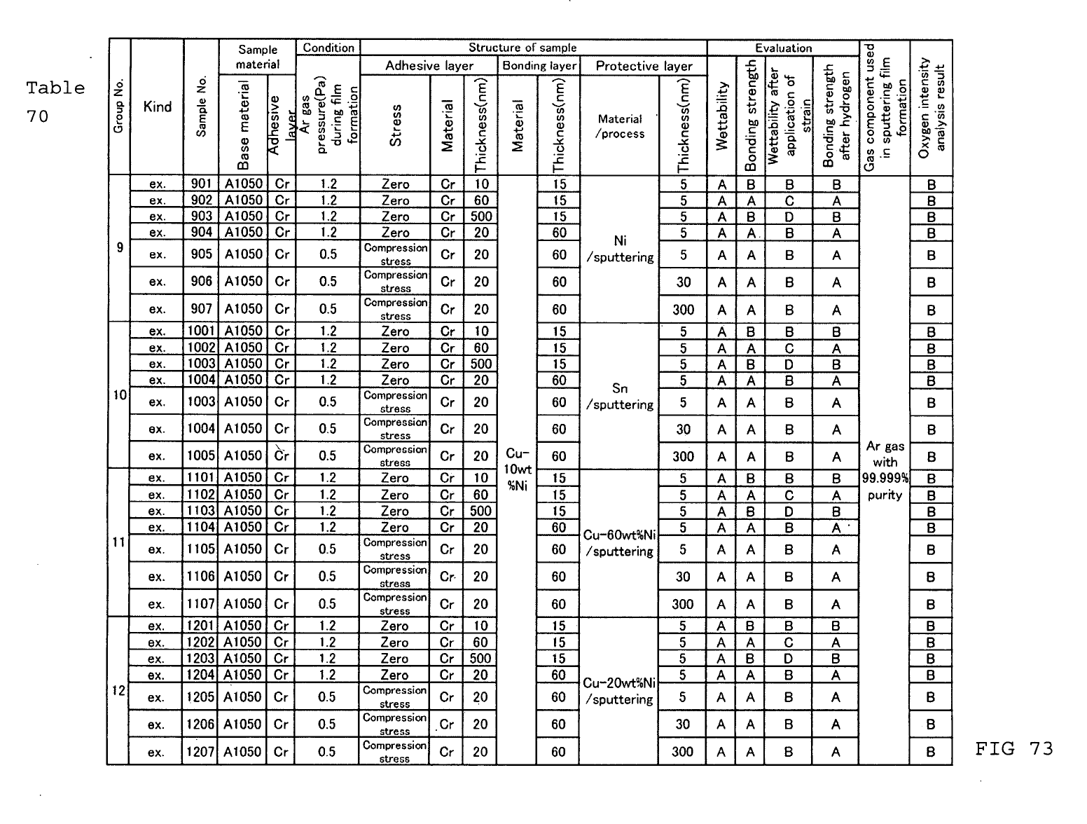

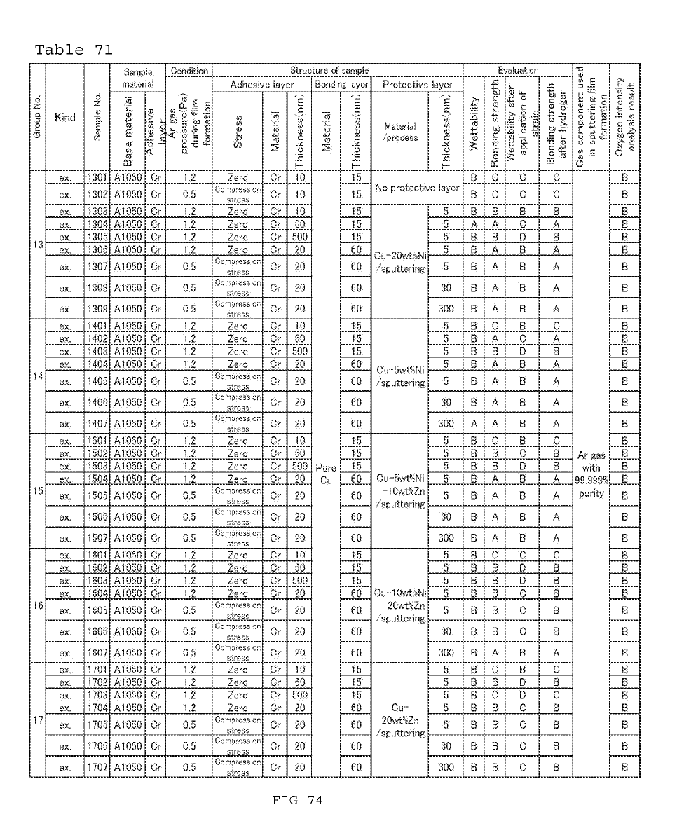

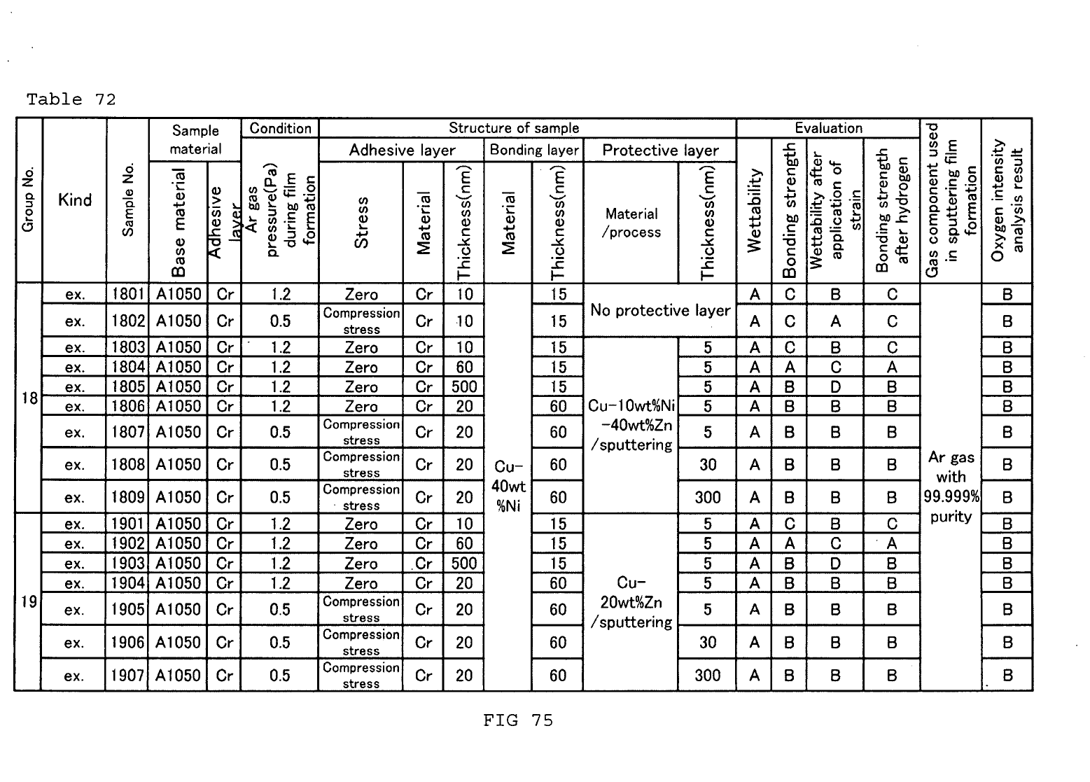

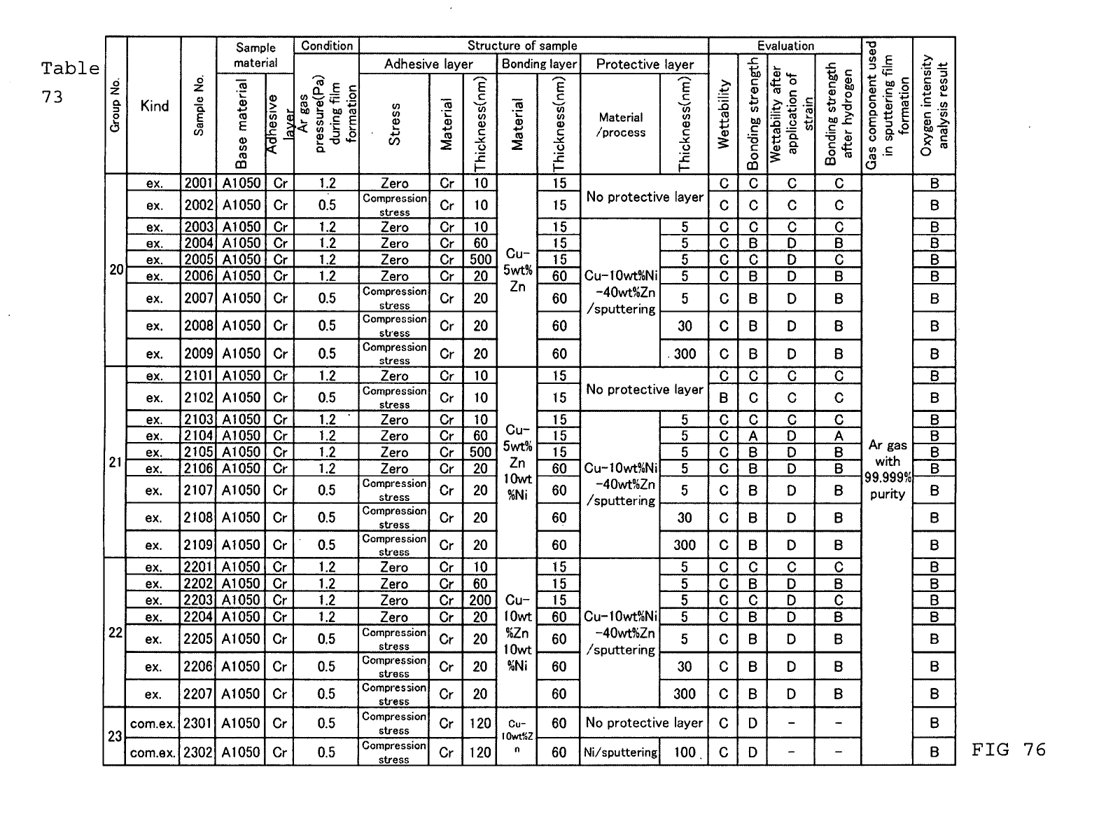

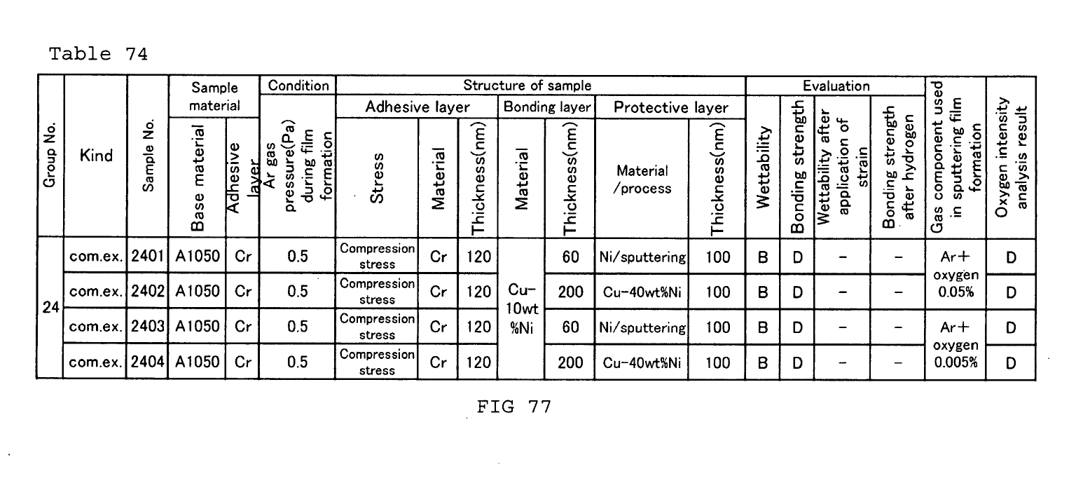

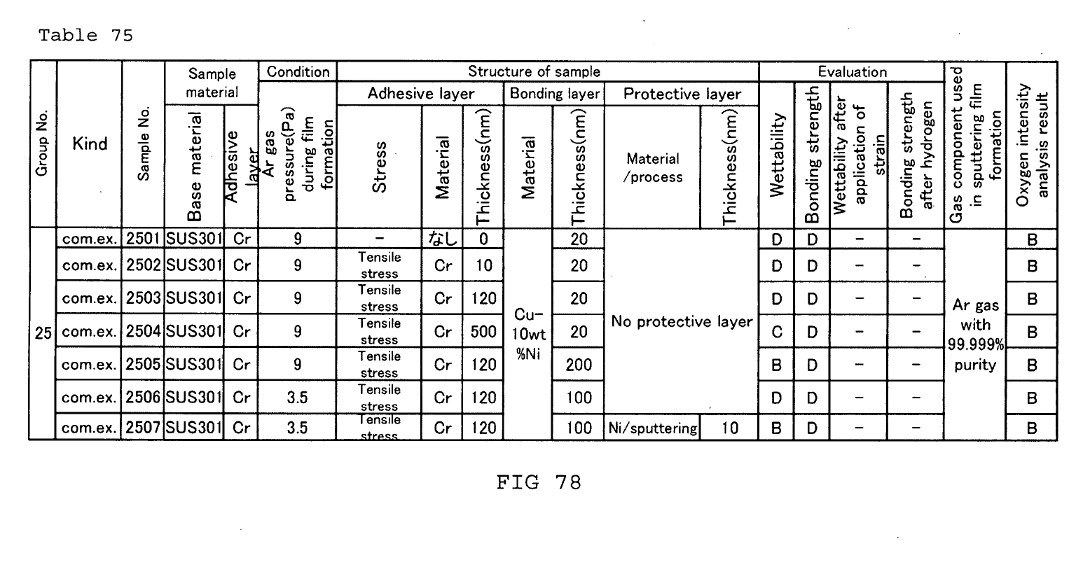

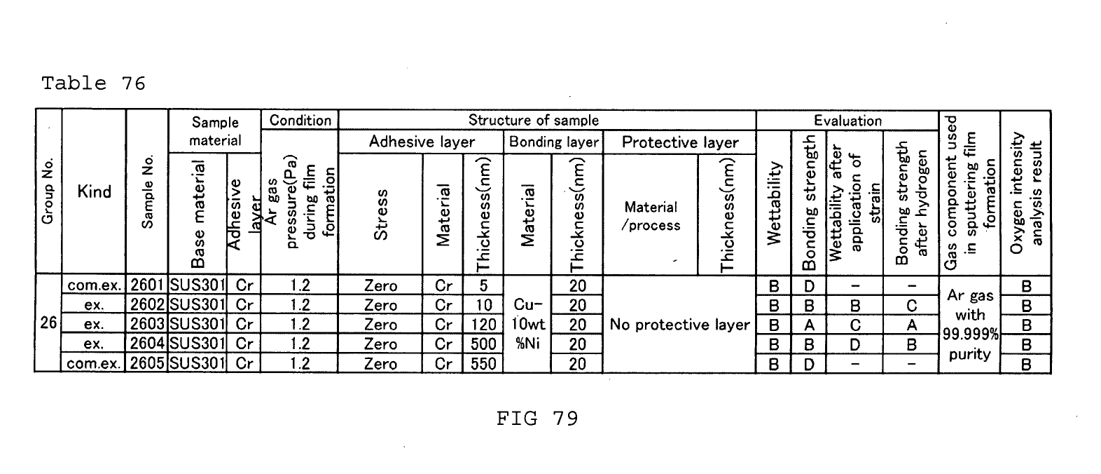

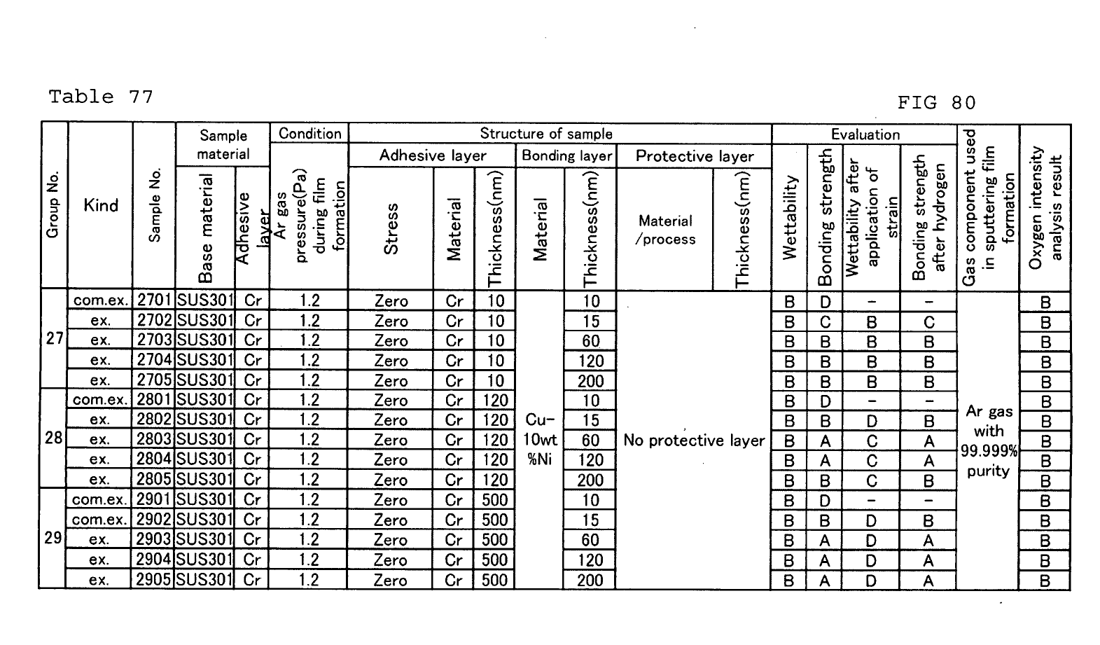

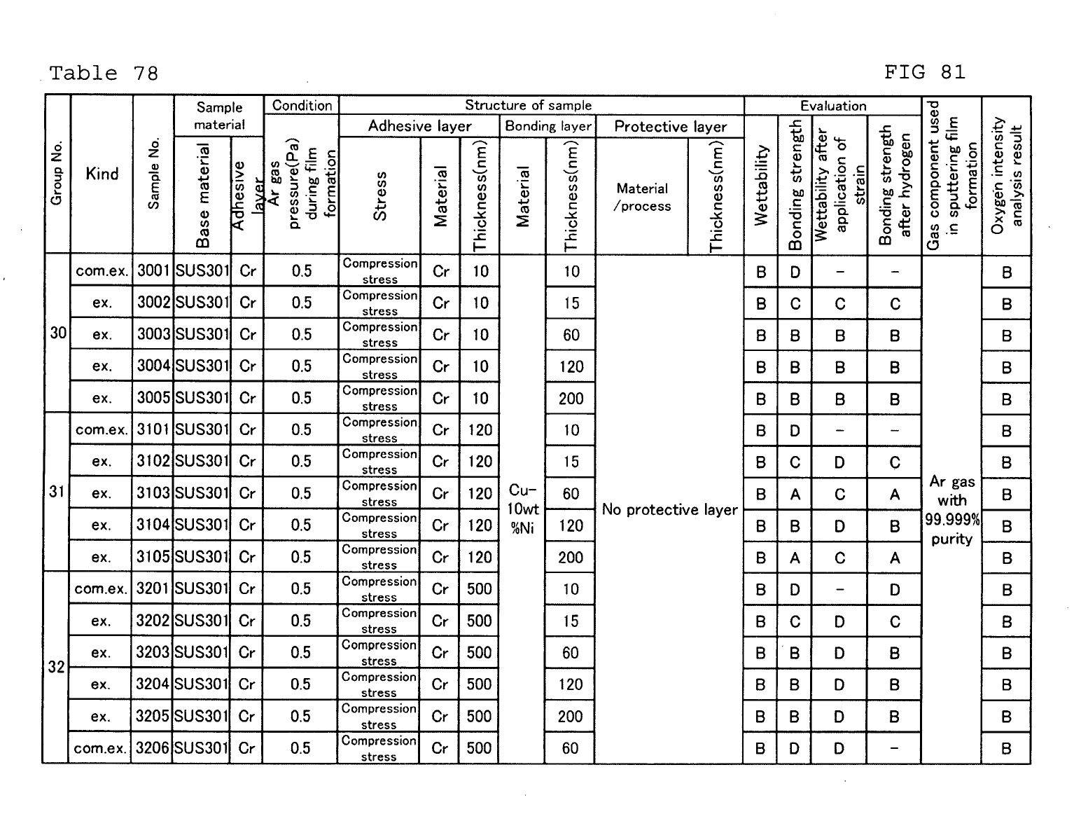

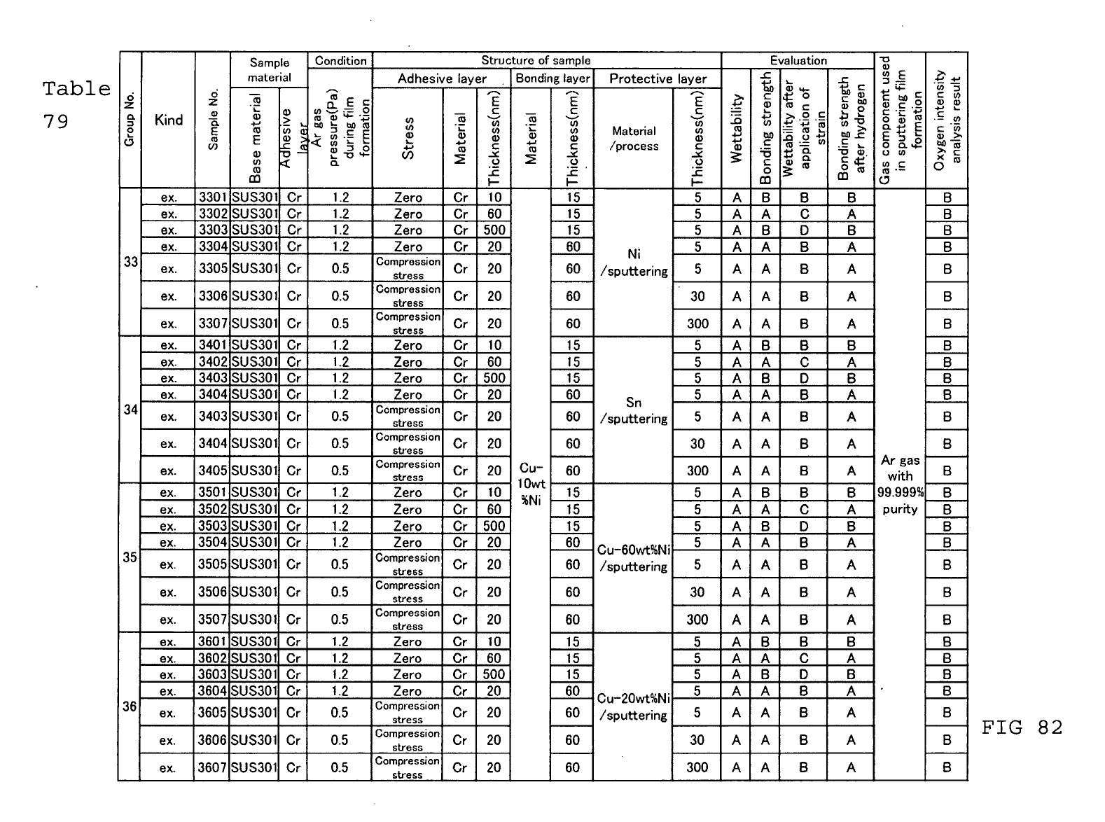

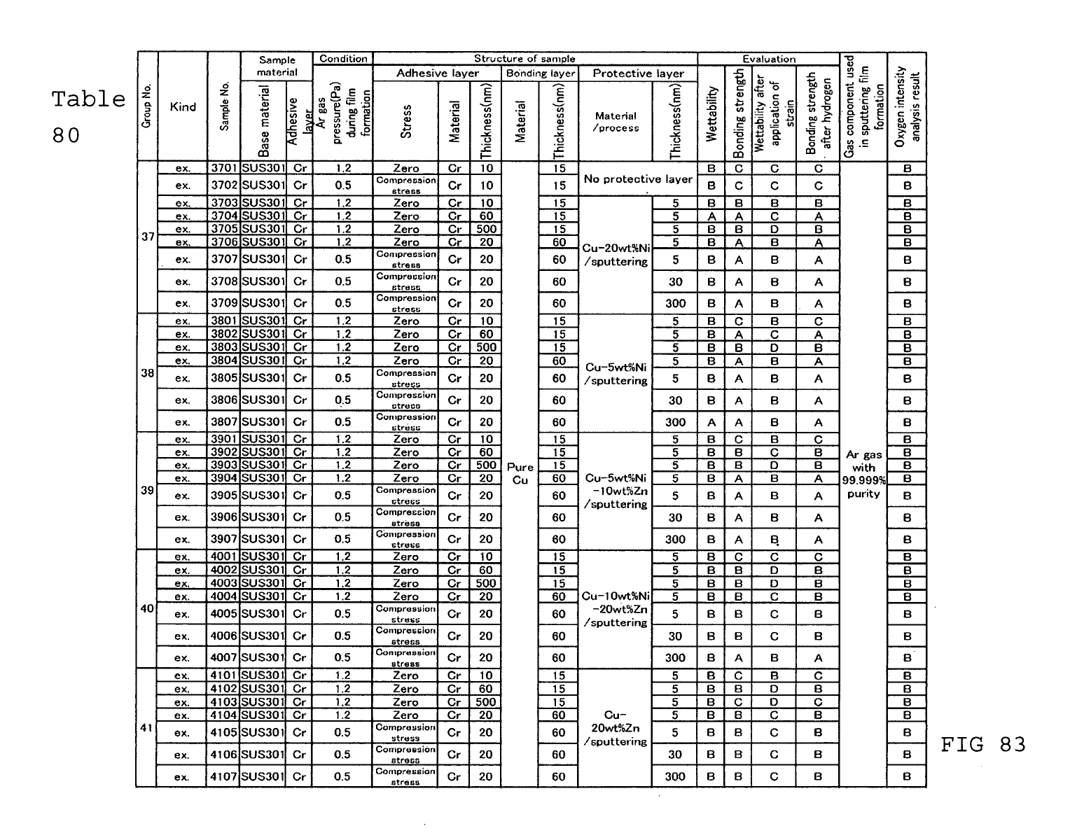

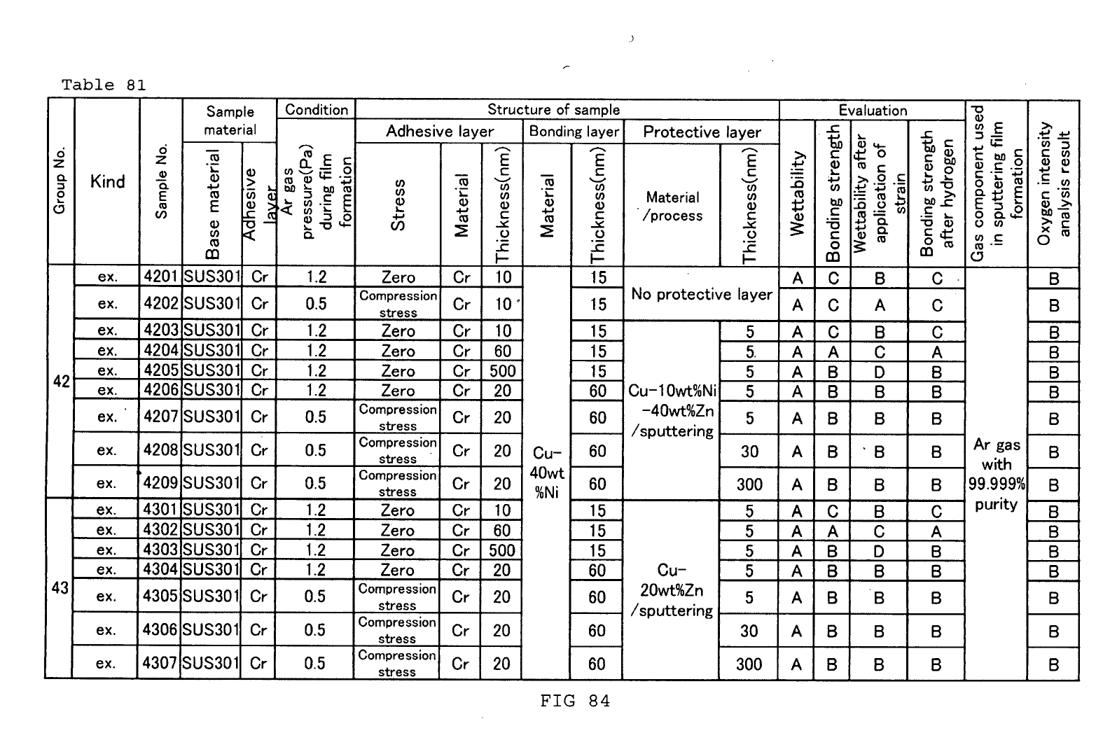

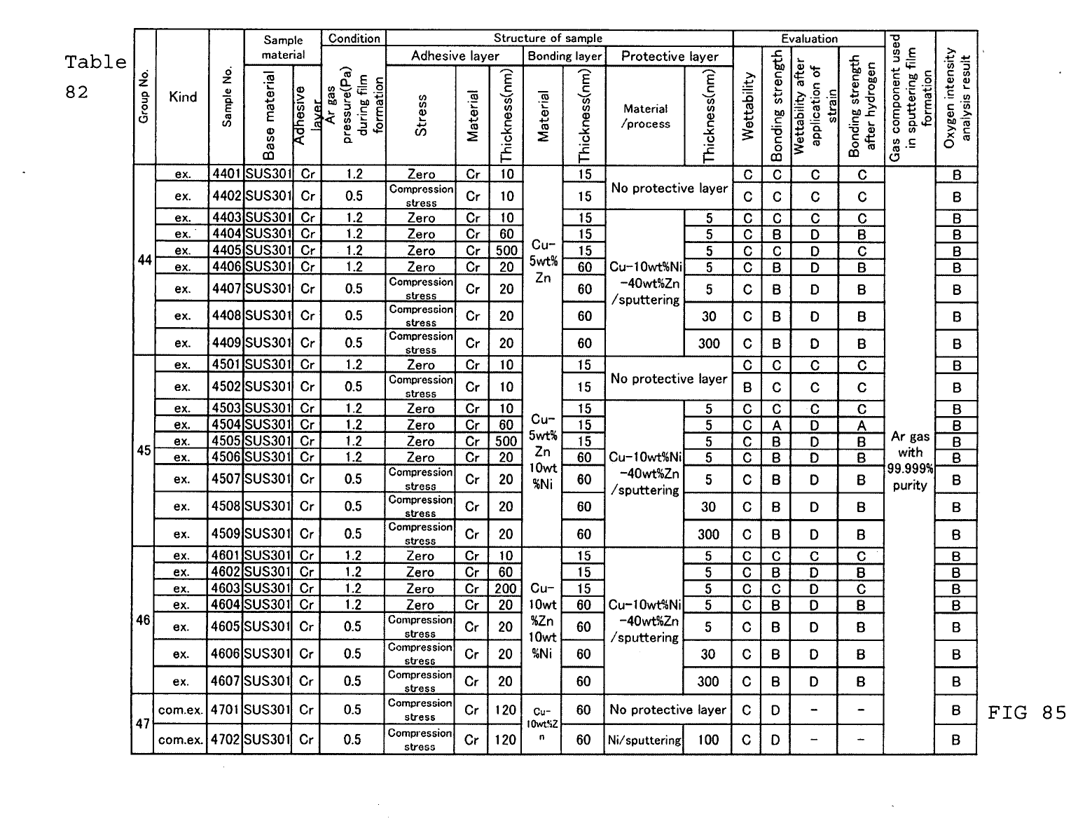

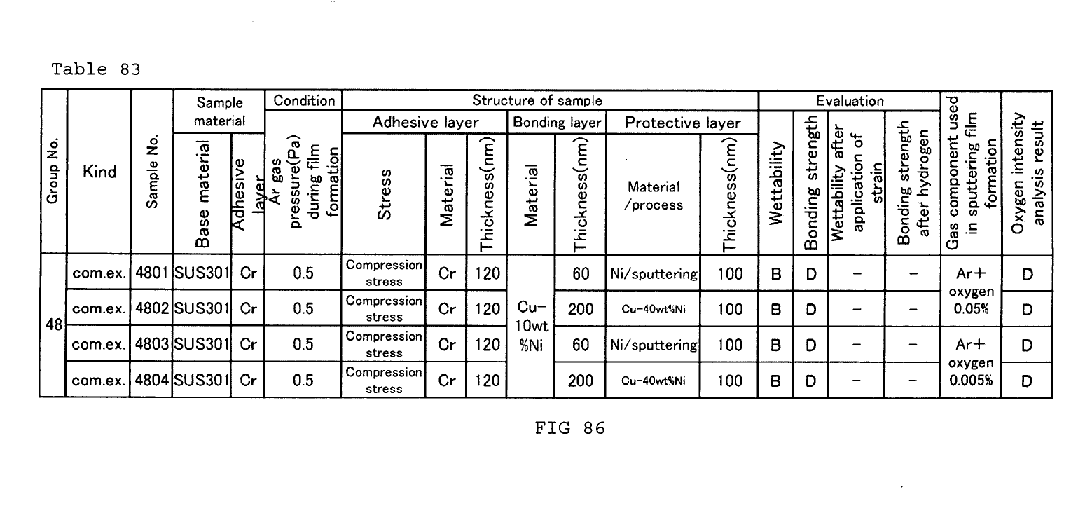

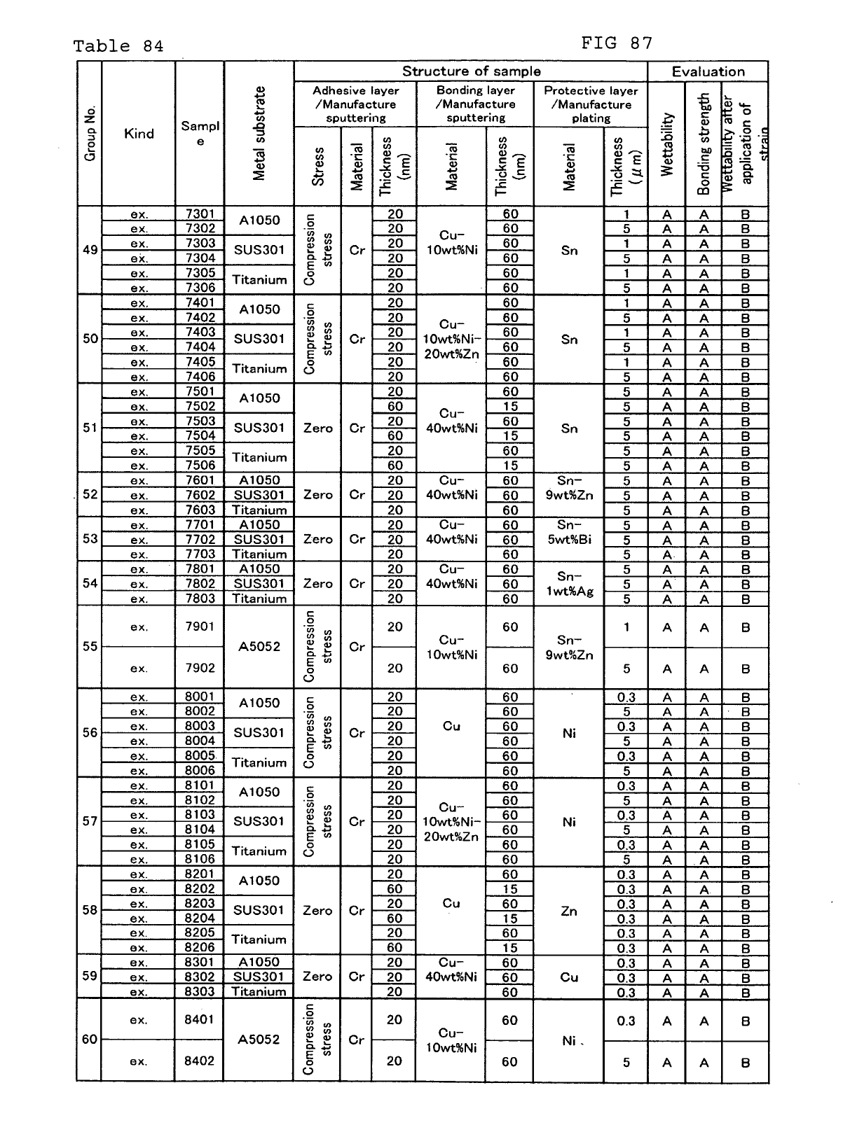

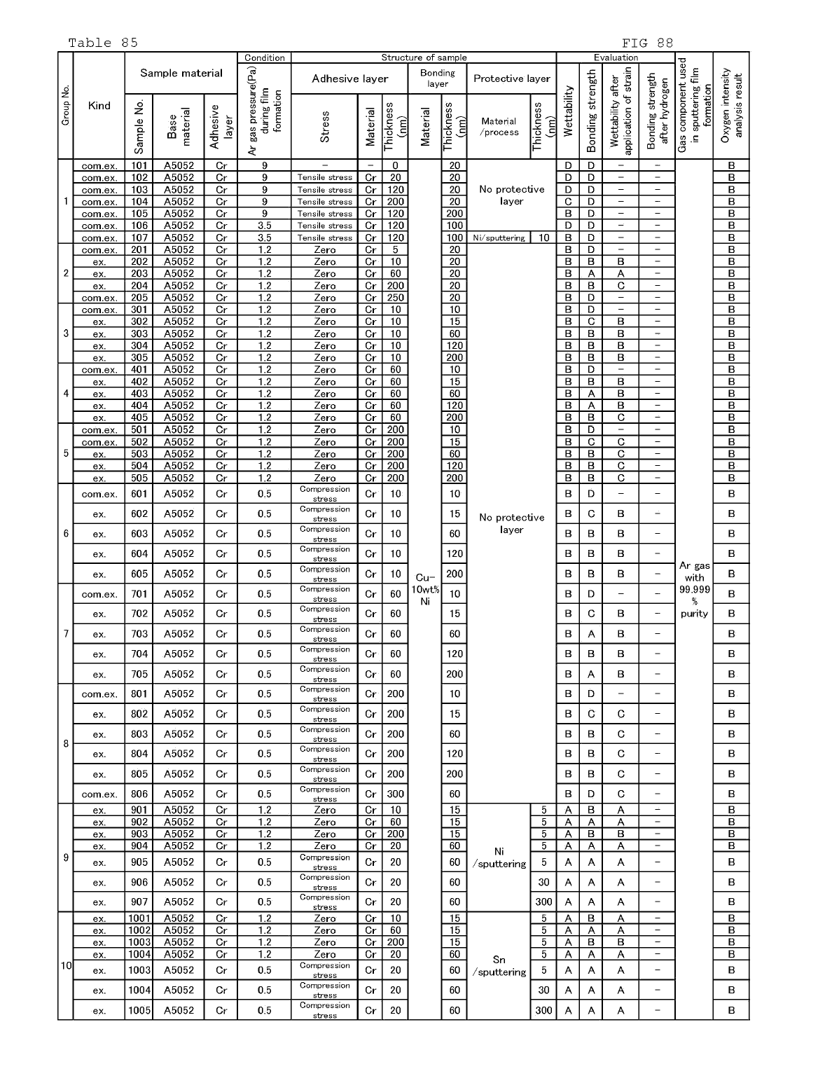

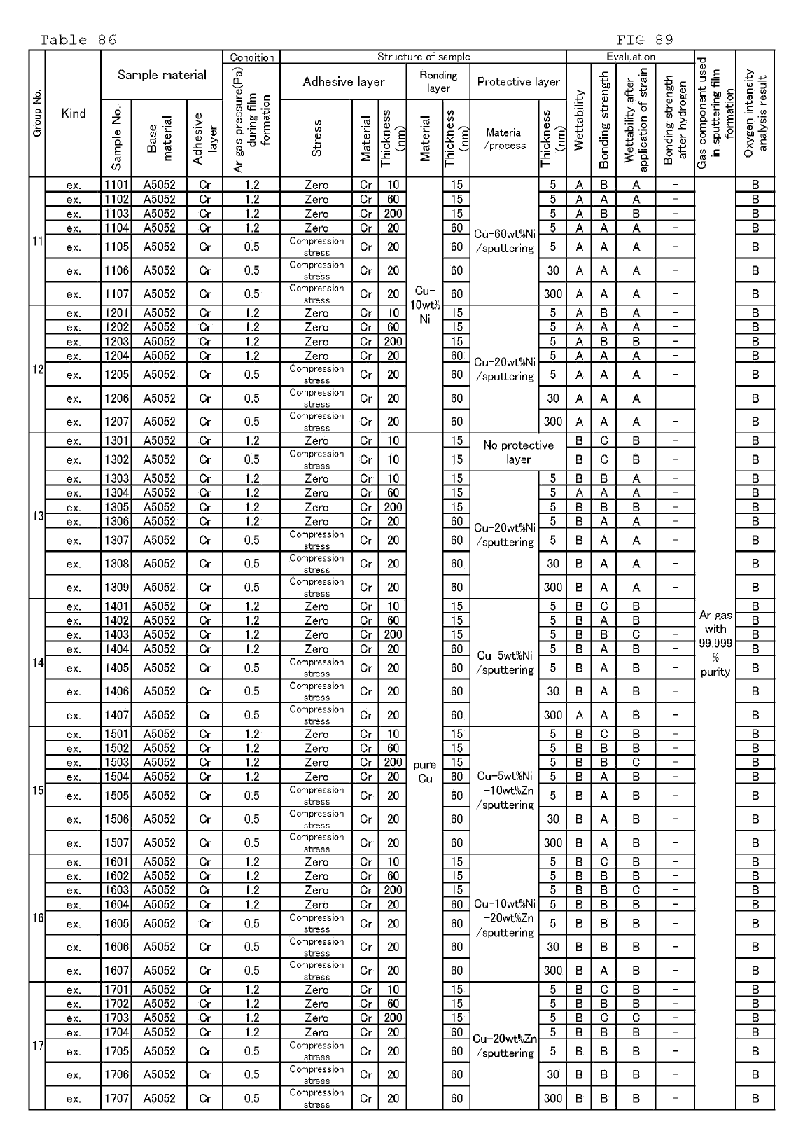

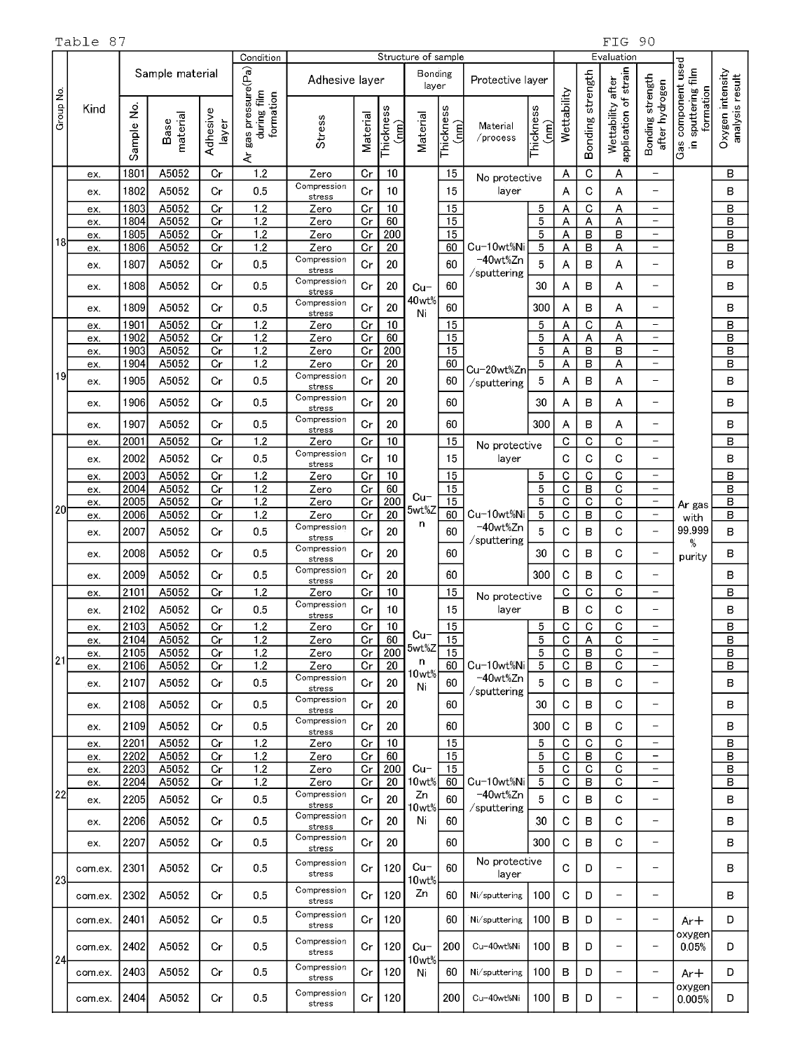

As shown in FIG. 1, the surface-treated metal substrate according to an embodiment of the present invention includes a lamination structure as a main structural element, which is basically formed by an adhesive layer 2 and a bonding layer 3 in this order on the surface of a metal substrate 1. Then, with such a structure (lamination structure), a surface on the side where the adhesive layer 2 and the bonding layer 3 are formed, being the side of this surface-treated metal substrate to which surface treatment is applied, has excellent solder wettability and sufficient bonding strength to solder.

### First Embodiment

The metal substrate 1 is made of metal having a passivation film on the outermost layer.

Specifically, for example, when expressed by JIS standard, pure aluminum (Al), an aluminum alloy, or 1000-series, 2000-series, 3000-series, 5000-series, 6000-series, and 7000-series aluminum alloy plates, etc, can be used. Also, the aluminum alloy other than JIS standard, die cast, or an aluminum clad plate material with these aluminum materials as a front layer, aluminum/SUS, aluminum/Invar (Trademark), aluminum/copper (Cu), etc, can also be used.

Further, other than the aforementioned materials, each kind of stainless steel material and Invar (Trademark) material, etc, can also be used as practical materials. Alternately, other than these materials, chrome (Cr), tantalum (Ta), niobium (Nb), and molybdenum (Mo), etc, can also be used.

As a shape of this metal substrate 1, various kinds of shapes such as plate material, round material, pipe material, tape material shapes can be possible, and the shape is not particularly limited.

The acid pickling treatment by using acid pickling medical liquid involving complicatedness of treating wastes which are produced after use as industrial wastes, is not absolutely applied to the surface of the metal substrate 1, and such an acid pickling treatment is not absolutely applied, even as a pre-treatment in a preparation stage of a surface treatment process. Accordingly, the passivation film such as a natural oxide film exists on the outermost surface of this metal substrate 1 as it is, and the adhesive layer 2 and the bonding layer 3 are formed thereon. However, it is a matter of course that general so-called degreasing and washing can be applied to the outermost surface of this metal substrate 1 using each kind of cleanser and pure water. Here, this metal substrate 1 is common in first, second, and third embodiments.

In the first embodiment, the adhesive layer 2 is formed of a sputtering film mainly composed of titanium (Ti), and the internal residual stress of this film is exerted as compression stress or zero-stress. This is because when the internal residual stress of the sputtering film of the adhesive layer 2 is a tensile stress, there is a high possibility that the bonding strength to solder (also called a solder bonding strength hereinafter) is deteriorated.

It is desirable to set an average thickness of the adhesive layer 2 made of titanium (Ti) to 20 nm or more and 200 nm or less. This is because when the thickness of the adhesive layer 2 made of titanium (Ti) is less than 20 nm which is a lower limit value, there is a high possibility that the wettability and bonding strength to solder is insufficient. Further, when the average thickness of the adhesive layer 2 exceeds 200 nm which is an upper limit value, there are high possibilities that the bonding strength is deteriorated, the solder wettability after application of strain is deteriorated, or an adverse effect appears in an environment of hydrogen.

The bonding layer 3 is formed of a sputtering film mainly composed of at least any one of pure copper (Cu), a mixture state of copper and nickel (Cu—Ni) containing 60 wt % or less of nickel (Ni) concentration and 10% or less of zinc (Zn) concentration, and a mixture state of copper, nickel, and zinc (Cu—Ni—Zn), and a mixture state of copper and zinc (Cu—Zn) containing 5% or less of Zn concentration.

When using three kinds of metals of the aforementioned nickel (Ni), copper (Cu), and zinc (Zn), being metal materials used for constituting the bonding layer 3, the following characteristics can be obtained.

The material costs of these three kinds of metals are given in an order from an expensive one, like nickel (Ni)>copper (Cu)>zinc (Zn). In a case of adding nickel (Ni) to copper (Cu), although the wettability is improved compared with a case of pure copper (Cu), the cost is increased. In a case of adding zinc (Zn) to copper (Cu), although the wettability to solder is sometimes deteriorated, the cost is reduced. Also, in a case of adding zinc (Zn), an effect that the bonding layer 3 functions as a sacrificial protection layer, can be obtained. A final composition of the alloy may be determined according to a use environment and a required function and performance, in consideration of the characteristic of each kind of metals. However, when the concentration of nickel (Ni) exceeds 60%, Cu—Ni alloy behaves as a ferromagnetic material, and therefore this is not preferable. Also, when the concentration of zinc (Zn) becomes high, the solder wettability is deteriorated, and therefore this is not preferable. Also, by adding nickel (Ni) to copper (Cu), the solder wettability in the case of adding zinc (Zn) can be adjusted.

The average thickness of the bonding layer 3 is preferably set to 15 nm or more. This is because when the thickness of the bonding layer 3 is less than 15 nm, which is the lower limit value, there is a high possibility that the wettability and the bonding strength to solder are insufficient.

Preferably, oxygen intensity ratio X is set to (0≦) X≦0.02, wherein X is a vale obtained by dividing {intensity of oxygen (O)} by {intensity of oxygen (O)+intensity of titanium (Ti) of the adhesive layer 2+intensity of component elements (copper (Cu), nickel (Ni), zinc (Zn) of the bonding layer 3}, based on an element photoelectron spectroscopy analytical result in a depth direction measured with a resolution of 2 nm by a spectroscopic analytical method such as photoelectron spectroscopy or Auger analysis, in the vicinity of an interface between the adhesive layer 2 and the bonding layer 3 (more specifically, an area extending over the thickness in the vicinity of the interface).

However, when the metal substrate 1 is made of a material intentionally added with magnesium (Mg) such as 5000-series aluminum-magnesium (Al—Mg) alloy based on the JIS standard, preferably, the oxygen intensity ratio X is set to (0≦) X≦0.04.

Namely, this is because when the oxygen intensity ratio X exceeds 0.02 (exceeds 0.04 in a case that the metal substrate 1 contains Mg), there is a high possibility that a sufficient bonding strength is hardly obtained even when other structure and the numerical value are appropriately set, but by forming the adhesive layer 2 and the bonding layer 3 by sputtering in the film formation atmosphere in which a low oxygen concentration state is intentionally set so that the oxygen intensity ratio X is set to the aforementioned value, excellent bonding strength can be obtained.

Here, as shown in FIG. 2, a protective layer 4 formed of the sputtering film mainly composed of at least any one of the nickel (Ni), tin (Sn), the mixture state of copper and nickel (Cu—Ni), the mixture state of copper, nickel, and zinc (Cu—Ni—Zn), and the mixture state of copper and zinc (Cu—Zn), may be further formed on the bonding layer 3.

When this protective layer 4 is made of copper and nickel (Cu—Ni), preferably the concentration of nickel (Ni) is set to 10 wt % or more and 60 wt % or less. This is because when the concentration of nickel (Ni) is set to 60 wt % or more, due to an increase of a use amount of a target material of the nickel (Ni) alloy and due to a prolonged time required for the film forming process, inconveniences such as deterioration of throughput and increase of the manufacturing cost are generated, resulting in making the material of the protective layer 4 turned into the ferromagnetic material. Generally, the formed ferromagnetic material has a strong tendency of decreasing a film forming rate by sputtering, and there is a high possibility that the throughput is deteriorated. Further, this is because when an entire body of the formed protective layer 4 is the ferromagnetic material, this ferromagnetic property becomes a constraint in some cases, to cause inconvenience to be generated in using this surface-treated metal substrate, such that it is hardly used as a member and a material plate for electronic components.

Therefore, by not using the sputtering film of Ni simple body, but using the sputtering film of Cu—Ni, the obtained protective layer 4 is rendered paramagnetic body, and therefore film formation is possible without decreasing a sputtering rate, and the protective layer 4 can be made of a material which is magnetically neutral and easy to be used.

Further, about 40 wt % of zinc (Zn) may also be added to copper and nickel (Cu—Ni). Thus, further lower cost can be achieved, and this protective layer 4 can also have a function as a so-called sacrificial protection layer.

Alternately, the protective layer 4 may also be formed of a plating film mainly composed of copper (Cu), or nickel (Ni), or zinc (Zn), on the bonding layer 3. In the other case also, the protective layer 4 can be formed, for example, by a vapor deposition method.

Further, as shown in FIG. 3, a solder layer 5 formed by A tin (Sn) plating or a tin-alloy plating such as tin-zinc (Sn—Zn), tin-silver (Sn—Ag) having a composition for the purpose of use for solder, may be further provided on the bonding layer 3 (or can be formed on the protective layer 4, not shown). Thus, by further forming the solder layer 5, the solder wettability on the surface of the surface-treated metal substrate according to the first embodiment of the present invention can be further strengthened.

A main essential flow of the manufacturing method of the surface-treated metal substrate having the lamination structure shown in FIG. 1 is as follows. First, the metal substrate 1, being a treatment target, is stored in a chamber (not shown: similar as follows) of a film forming apparatus such as a sputtering apparatus, in a state of not applying the acid pickling treatment thereto (namely, in a state of forming the passivation film such as a natural aluminum oxide (Al) layer. Then, the adhesive layer 2 mainly composed of titanium (Ti), in which the internal residual stress of the sputtering film is the compression stress or the zero-stress, is formed by vapor deposition. Subsequently, the bonding layer 3 mainly composed of at least any one of copper (Cu), the mixture state of copper and nickel (Cu—Ni), the mixture state of copper and zinc (Cu—Zn), and the mixture state of copper and nickel and zinc (Cu—Ni—Zn), is formed on the adhesive layer 2. As the main essential process conditions in this film formation by sputtering, oxygen is intentionally removed to set the oxygen concentration to 0.001% or less, and inactive gas such as argon (Ar) is set as a main component, and the film is formed by sputtering sequentially in the same chamber in which the film formation atmosphere is maintained to 1.5 Pa or less, even when the materials of the formed layers are switched from the adhesive layer 2 to the bonding layer 3. Here, it is a matter of course that the gas other than the aforementioned Ar can be used, as the inactive gas used as the main component of the film formation atmosphere. However, in this case also, similarly to the above case, the oxygen concentration needs to be maintained to an extremely low concentration such as 0.001% or less.

According to the surface-treated metal substrate and the manufacturing method of the same according to the first embodiment of the present invention, the adhesive layer 2 made of titanium (Ti) and the bonding layer 3, etc, can be formed on the outermost surface of the metal substrate 1, in a state of allowing the passivation film such as the natural oxide film to exist on the outermost surface of the metal substrate 1. Therefore, application of the acid pickling treatment to the outermost surface of the metal substrate 1 can be basically completely eliminated.

Namely, by forming the following adhesive layer and the bonding layer, it is found by the inventors of the present invention that excellent wettability and the bonding strength to solder can be provided to the surface of the metal substrate such as aluminum (Al) and stainless steel, being materials hardly plated and also hardly soldered originally because the passivation film such as the oxide film (natural oxide film) is formed on the outermost surface, even if the passivation film is left thereon, accordingly, even if the acid pickling treatment is not applied thereto. Then, after various experiments are performed, it is confirmed that an effect can be correctly obtained by this means, and the present invention is thereby achieved.

Further, the adhesive layer 2 made of titanium (Ti) and the bonding layer 3 are formed on the surface of the metal substrate 1 in this order, and the protective layer 4 and the solder layer 5 are further formed on the bonding layer 3, and therefore by providing these layers, the wettability to solder can be greatly improved. As a result, even if not using a flux with weak activity or completely not using the flux, etc, soldering with sufficient bonding strength is possible, by a so-called lead-free solder not containing lead (Pb), etc, being RoHs regulated substance.

Further, the thickness of the adhesive layer 2 made of titanium (Ti) is set to 20 nm or more and 200 nm or less, and the thickness of the bonding layer 3 is set to an appropriate thickness of 15 nm or more, and the metal plate is made extremely thin, compared with a conventional general thickness, as the surface-treated structure of this kind of metal plate. Thus, the film formation of the adhesive layer 2 and the bonding layer 3 can be performed for a short period of time, and as a result, improvement of the throughput and the reduction of the material cost can be achieved.

Also, by forming the protective layer 4, the generation of the oxide film on the outermost surface of the bonding layer 3 can be suppressed, and as a result, the bonding strength to solder can be strengthened. In addition, by adding nickel (Ni) and copper (Cu) as the forming materials, the reduction of the material cost and the improvement of a sputter efficiency can be expected. Alternately, by adding copper (Cu) and zinc (Zn), the reduction of the manufacturing cost can be achieved, and improvement of a sacrificial protection effect can be obtained. Alternately, by using three materials of Cu—Ni—Zn, three effects of the solder wettability, the reduction of the manufacturing cost, and the sacrificial protection effect can be simultaneously achieved.

Further, by forming the bonding layer 3 by the mixture or the alloy of copper and nickel (Cu—Ni), or the mixture or the alloy of Cu—Ni—Zn, an oxidation suppressing effect of the outermost surface of the bonding layer 3 can be obtained. Further, by adding nickel (Ni), diffusion control of the bonding layer 3 can be achieved. As a result, strengthening of the bonding strength to solder can be expected. Further, by adding zinc (Zn), the sacrificial protection effect can be obtained, and thus the corrosion resistance and durability of the outermost surface of this surface-treated metal substrate can be improved.

### Second Embodiment

In the surface-treated metal substrate according to a second embodiment of the present invention, the adhesive layer 2 is formed of a sputtering film mainly composed of niobium (Nb), and the internal residual stress of this film is exerted as the compression stress or the zero stress. This is because when the internal residual stress of the sputtering film of this adhesive layer 2 is a tensile stress, there is a high possibility that the bonding strength to solder (also called a solder bonding strength hereinafter) is strengthened.

Preferably, the average thickness of the adhesive layer 2 made of niobium (Nb) is set to 10 nm or more and 200 nm or less. This is because when the thickness of the adhesive layer 2 made of niobium (Nb) is less than 10 nm, being the lower limit value, there is a high possibility that the wettability and the bonding strength to solder are insufficient. Also, this is because when the thickness of the adhesive layer 2 exceeds 200 nm, there is a high possibility that the bonding strength and the solder wettability after application of strain are deteriorated, or an adverse effect appears in a hydrogen environment.

The bonding layer 3 is formed of a sputtering film mainly composed of at least any one of pure copper (Cu), a mixture state of copper and nickel (Cu—Ni) containing 60 wt % or less of nickel (Ni) concentration and 10% or less of zinc (Zn) concentration, and a mixture state of copper, nickel, and zinc (Cu—Ni—Zn), and a mixture state of copper and zinc (Cu—Zn) containing 5% or less of Zn concentration.

When using three kinds of metals of the aforementioned nickel (Ni), copper (Cu), and zinc (Zn), being metal materials used for constituting the bonding layer 3, the following characteristics can be obtained.

The material costs of these three kinds of metals are given in an order from an expensive one, like nickel (Ni)>copper (Cu)>zinc (Zn). In a case of adding nickel (Ni) to copper (Cu), although the wettability is improved compared with a case of pure copper (Cu), the cost is increased. In a case of adding zinc (Zn) to copper (Cu), although the wettability to solder is sometimes deteriorated, the cost is reduced. Also, in a case of adding zinc (Zn), an effect that the bonding layer 3 functions as a sacrificial protection layer, can be obtained. A final composition of the alloy may be determined according to a use environment and a required function and performance, in consideration of the characteristic of each kind of metals. However, when the concentration of nickel (Ni) exceeds 60%, Cu—Ni alloy behaves as a ferromagnetic material, and therefore this is not preferable. Also, when the concentration of zinc (Zn) becomes high, the solder wettability is deteriorated, and therefore this is not preferable. Also, by adding nickel (Ni) to copper (Cu), the solder wettability in the case of adding zinc (Zn) can be adjusted.

The average thickness of the bonding layer 3 is preferably set to 15 nm or more. This is because when the thickness of the bonding layer 3 is less than 15 nm, which is the lower limit value, there is a high possibility that the wettability and the bonding strength to solder are insufficient.

Preferably, oxygen intensity ratio X is set to (0≦) X≦0.02, wherein X is a vale obtained by dividing {intensity of oxygen (O)} by {intensity of oxygen (O)+intensity of niobium (Nb) of the adhesive layer 2+intensity of component elements (copper (Cu), nickel (Ni), zinc (Zn) of the bonding layer 3}, based on an element photoelectron spectroscopy analytical result in a depth direction measured by a resolution of 2 nm by a spectroscopic analytical method such as photoelectron spectroscopy or Auger analysis, in the vicinity of an interface between the adhesive layer 2 and the bonding layer 3 (more specifically, an area extending over the thickness in the vicinity of the interface).

However, when the metal substrate 1 is made of a material intentionally added with magnesium (Mg) such as 5000-series aluminum-magnesium (Al—Mg) alloy based on the JIS standard, preferably, the oxygen intensity ratio X is set to (0≦) X≦0.04.

Namely, this is because when the oxygen intensity ratio X exceeds 0.02 (exceeds 0.04 in a case that the metal substrate 1 contains Mg), there is a high possibility that a sufficient bonding strength is hardly obtained even when other structure and the numerical value are appropriately set, but by forming the adhesive layer 2 and the bonding layer 3 by sputtering in the film formation atmosphere in which a low oxygen concentration state is intentionally set so that the oxygen intensity ratio X is set to the aforementioned value, excellent bonding strength can be obtained.

Here, as shown in FIG. 2, the protective layer 4 formed of a sputtering film mainly composed of at least any one of the nickel (Ni), tin (Sn), the mixture state of copper and nickel (Cu—Ni), the mixture state of copper, nickel, and zinc (Cu—Ni—Zn), and the mixture state of copper and zinc (Cu—Zn), may be further formed on the bonding layer 3.

When this protective layer 4 is made of copper and nickel (Cu—Ni), preferably the concentration of nickel (Ni) is set to 10 wt % or more and 60 wt % or less. This is because when the concentration of nickel (Ni) is set to 60 wt % or more, due to an increase of a use amount of a target material of the nickel (Ni) alloy and due to a prolonged time required for the film forming process, inconveniences such as deterioration of throughput and increase of the manufacturing cost are generated, resulting in making the material of the protective layer 4 turned into the ferromagnetic material. Generally, the formed ferromagnetic material has a strong tendency of decreasing the film forming rate by sputtering, and there is a high possibility that the throughput is deteriorated. Further, this is because when an entire body of the formed protective layer 4 is the ferromagnetic material, this ferromagnetic property becomes a constraint in some cases, to cause inconvenience to be generated in using this surface-treated metal substrate, such that it is hardly used as a member and a material plate for electronic components.

Therefore, by not using the sputtering film of Ni simple body, but using the sputtering film of Cu—Ni, the obtained protective layer 4 is rendered paramagnetic body, and therefore film formation is possible without decreasing the sputtering rate, and the protective layer 4 can be made of a material which is magnetically neutral and easy to be used.

Further, about 40 wt % of zinc (Zn) may also be added to copper and nickel (Cu—Ni). Thus, further lower cost can be achieved, and this protective layer 4 can also have a function as a so-called sacrificial protection layer.

Alternately, the protective layer 4 may also be formed of a plating film mainly composed of copper (Cu), or nickel (Ni), or zinc (Zn), on the bonding layer 3. In the other case also, the protective layer 4 can be formed, for example, by a vapor deposition method.

Further, as shown in FIG. 3, a solder layer 5 formed by a tin (Sn) plating or a tin-alloy plating such as tin-zinc (Sn—Zn), tin-silver (Sn—Ag) having a composition for the purpose of use for solder, may be further provided on the bonding layer 3 (or can be formed on the protective layer 4, not shown). Thus, by further forming the solder layer 5, the solder wettability on the surface of the surface-treated metal substrate according to the first embodiment of the present invention can be further strengthened.

The main essential flow of the manufacturing method of the surface-treated metal substrate having the lamination structure shown in FIG. 1 is as follows. First, the metal substrate 1, being a treatment target, is stored in the chamber (not shown: similar as follows) of the film forming apparatus such as a sputtering apparatus, in a state of not applying the acid pickling treatment thereto (namely, in a state of forming the passivation film such as a natural aluminum oxide (Al) layer. Then, the adhesive layer 2 mainly composed of niobium (Nb), in which the internal residual stress of the sputtering film is the compression stress or the zero-stress, is formed by vapor deposition. Subsequently, the bonding layer 3 mainly composed of at least any one of copper (Cu), the mixture state of copper and nickel (Cu—Ni), the mixture state of copper and zinc (Cu—Zn), and the mixture state of copper and nickel and zinc (Cu—Ni—Zn), is formed on the adhesive layer 2. As main essential process conditions in this film formation by sputtering, oxygen is intentionally removed to set the oxygen concentration to 0.001% or less, and inactive gas such as argon (Ar) is set as a main component, and the film is formed by sputtering sequentially in the same chamber while maintaining the film formation atmosphere to 1.5 Pa or less, even when the materials of the formed layers are switched from the adhesive layer 2 to the bonding layer 3. Here, it is a matter of course that the gas other than the aforementioned Ar can be used, as the inactive gas used as the main component of the film formation atmosphere. However, in this case also, similarly to the above case, the oxygen concentration needs to be maintained to an extremely low concentration such as 0.001% or less.

According to the surface-treated metal substrate and the manufacturing method of the same according to the first embodiment of the present invention, the adhesive layer 2 made of titanium (Ti) and the bonding layer 3, etc, can be formed on the outermost surface of the metal substrate 1, in a state of allowing the passivation film such as the natural oxide film to exist on the outermost surface of the metal substrate 1. Therefore, application of the acid pickling treatment to the outermost surface of the metal substrate 1 can be basically completely eliminated.

Further, the adhesive layer 2 made of niobium (Nb) and the bonding layer 3 are formed on the surface of the metal substrate 1 in this order, and the protective layer 4 and the solder layer 5 are further formed on the bonding layer 3. Therefore, by providing these layers, the wettability to solder can be greatly improved. Moreover, as a result, even if not using a flux with weak activity or completely not using the flux, etc, soldering with sufficient bonding strength is possible, by a so-called lead-free solder not containing lead (Pb), etc, being RoHs regulated substance.

Further, the thickness of the adhesive layer 2 made of niobium (Nb) is set to 10 nm or more and 200 nm or less, and the thickness of the bonding layer 3 is set to an appropriate thickness of 15 nm or more, and the metal plate is made extremely thin, compared with a conventional general thickness, as the surface-treated structure of this kind of metal plate. Thus, the film formation of the adhesive layer 2 and the bonding layer 3 can be performed for a short period of time, and as a result, improvement of the throughput and the reduction of the manufacturing cost can be achieved.

Also, by forming the protective layer 4, the generation of the oxide film on the outermost surface of the bonding layer 3 can be suppressed, and as a result, the bonding strength to solder can be strengthened. In addition, by adding nickel (Ni) and copper (Cu) as the forming materials, the reduction of the material cost and the improvement of a sputter efficiency can be expected. Alternately, by adding copper (Cu) and zinc (Zn), the reduction of the manufacturing cost can be achieved, and a sacrificial protection effect can be obtained. Alternately, by using three materials of Cu—Ni—Zn, three effects of the solder wettability, the reduction of the manufacturing cost, and the sacrificial protection effect can be simultaneously achieved.

Further, by forming the bonding layer 3 by the mixture or the alloy of copper and nickel (Cu—Ni), or the mixture or the alloy of Cu—Ni—Zn, an oxidation suppressing effect of the outermost surface of the bonding layer 3 can be obtained. Further, by adding nickel (Ni), diffusion control of the bonding layer 3 can be achieved. As a result, strengthening of the bonding strength to solder can be expected. Further, by adding zinc (Zn), the sacrificial protection effect can be obtained, and thus the corrosion resistance and durability of the outermost surface of this surface-treated metal substrate can be improved.

### Third Embodiment

According to the third embodiment, the adhesive layer 2 is formed of a sputtering film mainly composed of chromium (Cr), and the internal residual stress of this film is exerted as the compression stress or zero stress. This is because when the internal residual stress of the sputtering film of the adhesive layer 2 is a tensile stress, there is a high possibility that the bonding strength to solder is strengthened.

It is desirable to set an average thickness of the adhesive layer 2 made of chromium (Cr) to 10 nm or more and 500 nm or less. This is because when the thickness of the adhesive layer 2 made of chromium (Cr) is less than 10 nm which is the lower limit value, there is a high possibility that the wettability and bonding strength to solder is insufficient. Further, when the average thickness of the adhesive layer 2 exceeds 500 nm which is the upper limit value, there are high possibilities that the bonding strength is deteriorated, the solder wettability after application of strain is deteriorated, or an adverse effect appears in an environment of hydrogen.

The bonding layer 3 is formed of a sputtering film mainly composed of at least any one of pure copper (Cu), a mixture state of copper and nickel (Cu—Ni) containing 60 wt % or less of nickel (Ni) concentration and 10% or less of zinc (Zn) concentration, and a mixture state of copper, nickel, and zinc (Cu—Ni—Zn), and a mixture state of copper and zinc (Cu—Zn) containing 5% or less of Zn concentration.

When using three kinds of metals of the aforementioned nickel (Ni), copper (Cu), and zinc (Zn), being metal materials used for constituting the bonding layer 3, the following characteristics can be obtained.

The material costs of these three kinds of metals are given in an order from an expensive one, like nickel (Ni)>copper (Cu)>zinc (Zn). In a case of adding nickel (Ni) to copper (Cu), although the wettability is improved compared with a case of pure copper (Cu), the cost is increased. In a case of adding zinc (Zn) to copper (Cu), although the wettability to solder is sometimes deteriorated, the cost is reduced. Also, in a case of adding zinc (Zn), an effect that the bonding layer 3 functions as a sacrificial protection layer, can be obtained. A final composition of the alloy may be determined according to a use environment and a required function and performance, in consideration of the characteristic of each kind of metals. However, when the concentration of nickel (Ni) exceeds 60%, Cu—Ni alloy behaves as a ferromagnetic material, and therefore this is not preferable. Also, when the concentration of zinc (Zn) becomes high, the solder wettability is deteriorated, and therefore this is not preferable. Also, by adding nickel (Ni) to copper (Cu), the solder wettability in the case of adding zinc (Zn) can be adjusted.

The average thickness of the bonding layer 3 is preferably set to 15 nm or more. This is because when the thickness of the bonding layer 3 is less than 15 nm, which is the lower limit value, there is a high possibility that the wettability and the bonding strength to solder are insufficient.

Preferably, oxygen intensity ratio X is set to (0≦) X≦0.02, wherein X is a vale obtained by dividing {intensity of oxygen (O)} by {intensity of oxygen (O)+intensity of chromium (Cr) of the adhesive layer 2+intensity of component elements (copper (Cu), nickel (Ni), zinc (Zn) of the bonding layer 3}, based on an element photoelectron spectroscopy analytical result in a depth direction measured with a resolution of 2 nm by a spectroscopic analytical method such as photoelectron spectroscopy or Auger analysis, in the vicinity of an interface between the adhesive layer 2 and the bonding layer 3 (more specifically, an area extending over the thickness in the vicinity of the interface).

However, when the metal substrate 1 is made of a material intentionally added with magnesium (Mg) such as 5000-series aluminum-magnesium (Al—Mg) alloy based on the JIS standard, preferably, the oxygen intensity ratio X is set to (0≦) X≦0.04.

Namely, this is because when the oxygen intensity ratio X exceeds 0.02 (exceeds 0.04 in a case that the metal substrate 1 contains Mg), there is a high possibility that a sufficient bonding strength is hardly obtained even when other structure and the numerical value are appropriately set, but by forming the adhesive layer 2 and the bonding layer 3 by sputtering in the film formation atmosphere in which a low oxygen concentration state is intentionally set so that the oxygen intensity ratio X is set to the aforementioned value, excellent bonding strength can be obtained.

Here, as shown in FIG. 2, a protective layer 4 formed of a sputtering film mainly composed of at least any one of the nickel (Ni), tin (Sn), the mixture state of copper and nickel (Cu—Ni), the mixture state of copper, nickel, and zinc (Cu—Ni—Zn), and the mixture state of copper and zinc (Cu—Zn), may be further formed on the bonding layer 3.

When this protective layer 4 is made of copper and nickel (Cu—Ni), preferably the concentration of nickel (Ni) is set to 10 wt % or more and 60 wt % or less. This is because when the concentration of nickel (Ni) is set to 60 wt % or more, due to an increase of a use amount of a target material of the nickel (Ni) alloy and due to a prolonged time required for the film forming process, inconveniences such as deterioration of throughput and increase of the manufacturing cost are generated, resulting in making the material of the protective layer 4 turned into the ferromagnetic material. Generally, the formed ferromagnetic material has a strong tendency of decreasing a film forming rate by sputtering, and there is a high possibility that the throughput is deteriorated. Further, this is because when an entire body of the formed protective layer 4 is the ferromagnetic material, this ferromagnetic property becomes a constraint in some cases, to cause inconvenience to be generated in using this surface-treated metal substrate, such that it is hardly used as a member and a material plate for electronic components.

Therefore, by not using the sputtering film of Ni simple body, but using the sputtering film of Cu—Ni, the obtained protective layer 4 is rendered paramagnetic body, and therefore film formation is possible without decreasing the sputtering rate, and the protective layer 4 can be made of a material which is magnetically neutral and easy to be used.

Further, about 40 wt % of zinc (Zn) may also be added to copper and nickel (Cu—Ni). Thus, further lower cost can be achieved, and this protective layer 4 can also have a function as a so-called sacrificial protection layer.

Alternately, the protective layer 4 may also be formed of a plating film mainly composed of copper (Cu), or nickel (Ni), or zinc (Zn), on the bonding layer 3. In the other case also, the protective layer 4 can be formed, for example, by a vapor deposition method.

Further, as shown in FIG. 3, the solder layer 5 formed by a tin (Sn) plating or a tin-alloy such as tin-zinc (Sn—Zn), tin-silver (Sn—Ag) having a composition for the purpose of use for solder, may be further provided on the bonding layer 3 (or can be formed on the protective layer 4, not shown). Thus, by further forming the solder layer 5, the solder wettability on the surface of the surface-treated metal substrate according to the first embodiment of the present invention can be further strengthened.

The main essential flow of the manufacturing method of the surface-treated metal substrate having the lamination structure shown in FIG. 1 is as follows. First, the metal substrate 1, being a treatment target, is stored in a chamber (not shown: similar as follows) of the film forming apparatus such as a sputtering apparatus, in a state of not applying the acid pickling treatment thereto (namely, in a state of forming the passivation film such as a natural aluminum oxide (Al) layer. Then, the adhesive layer 2 mainly composed of chromium (Cr), in which the internal residual stress of the sputtering film is the compression stress or the zero-stress, is formed by vapor deposition. Subsequently, the bonding layer 3 mainly composed of at least any one of copper (Cu), the mixture state of copper and nickel (Cu—Ni), the mixture state of copper and zinc (Cu—Zn), and the mixture state of copper and nickel and zinc (Cu—Ni—Zn), is formed on the adhesive layer 2. As the main essential process conditions in this film formation by sputtering, oxygen is intentionally removed to set the oxygen concentration to 0.001% or less, and inactive gas such as argon (Ar) is set as the main component, and the film is formed by sputtering sequentially in the same chamber while maintaining the film formation atmosphere to 1.5 Pa or less, even when the materials of the formed layers are switched from the adhesive layer 2 to the bonding layer 3. Here, it is a matter of course that the gas other than the aforementioned Ar can be used, as the inactive gas used as the main component of the film formation atmosphere. However, in this case also, similarly to the above case, the oxygen concentration needs to be maintained to an extremely low concentration such as 0.001% or less.

According to the surface-treated metal substrate and the manufacturing method of the same according to the third embodiment of the present invention, the adhesive layer 2 and the bonding layer 3, etc, can be formed on the outermost surface of the metal substrate 1, in a state of allowing the passivation film such as the natural oxide film to exist on the outermost surface of the metal substrate 1. Therefore, application of the acid pickling treatment to the outermost surface of the metal substrate 1 can be basically completely eliminated.

Further, the adhesive layer 2 and the bonding layer 3 are formed on the surface of the metal substrate 1 in this order, and the protective layer 4 and the solder layer 5 are further formed on the bonding layer 3, and therefore by providing these layers, the wettability to solder can be greatly improved. As a result, even if not using a flux with weak activity or completely not using the flux, etc, soldering with sufficient bonding strength is possible, by a so-called lead-free solder not containing lead (Pb), etc, being RoHs regulated substance.

Further, the thickness of the adhesive layer 2 made of chromium (Cr) is set to 10 nm or more and 500 nm or less, and the thickness of the bonding layer 3 is set to an appropriate thickness of 15 nm or more, and the metal plate is made extremely thin, compared with a conventional general thickness, as the surface-treated structure of this kind of metal plate. Thus, the film formation of the adhesive layer 2 and the bonding layer 3 can be performed for a short period of time, and as a result, improvement of the throughput and the reduction of the manufacturing cost can be achieved.

Also, by forming the protective layer 4, the generation of the oxide film on the outermost surface of the bonding layer 3 can be suppressed, and as a result, the bonding strength to solder can be strengthened. In addition, by adding nickel (Ni) and copper (Cu) as the forming materials, the reduction of the material cost and the improvement of a sputter efficiency can be expected. Alternately, by adding copper (Cu) and zinc (Zn), the reduction of the manufacturing cost can be achieved, and a sacrificial protection effect can be obtained. Alternately, by using three materials of Cu—Ni—Zn, three effects of the solder wettability, the reduction of the material cost, and the sacrificial protection effect can be simultaneously achieved.

Further, by forming the bonding layer 3 by the mixture or the alloy of copper and nickel (Cu—Ni), or the mixture or the alloy of Cu—Ni—Zn, an oxidation suppressing effect of the outermost surface of the bonding layer 3 can be obtained. Further, by adding nickel (Ni), diffusion control of the bonding layer 3 can be achieved. As a result, strengthening of the bonding strength to solder can be expected. Further, by adding zinc (Zn), the sacrificial protection effect can be obtained, and thus the corrosion resistance and durability of the outermost surface of this surface-treated metal substrate can be improved.

In conclusion, according to the manufacturing method of the surface-treated metal substrate of the embodiments of the present invention, the adhesive layer 2 and the bonding layer 3 are formed on the surface of the metal substrate 1 in this order. Therefore, even if not applying the acid pickling of the passivation film, to the surface of the metal substrate 1 such as aluminum (Al), or an aluminum alloy, or stainless steel, having the passivation film on the outermost surface, which is a material hardly plated and hardly soldered originally, excellent solder wettability and the bonding strength to solder can be provided, with the adhesive layer 2 and the bonding layer 3 formed in this order. In addition, the adhesive layer and the bonding layer 3 capable of exhibiting such excellent action and effect can be formed in a short period of time and at a low cost. Therefore, the improvement of the throughput and the reduction of the cost of the surface-treated metal substrate according to the first embodiment of the present invention can be achieved.

Note that as the material of the adhesive layer 2, as described above, titanium (Ti), niobium (Nb), and chromium (Cr) can be used. However, these materials are given in an order from the one least influenced by hydrogen gas, like chromium (Cr)<niobium (Nb)<titanium (Ti). Chromium (Cr) is the one least influenced by the hydrogen gas. Therefore, when there is a concern about an adverse influence due to a hydrogen gas environment, chromium (Cr) is preferably selected as the material of the adhesive layer 2. Particularly, when the adhesive layer 2 is made of chromium (Cr), it is assumed that there is absolutely no deterioration of the performance due to hydrogen gas.

Further, the materials of the adhesive layer 2 are given in an order of the one least influenced by the application of strain, like niobium (Nb)<titanium (Ti)<chromium (Cr). Therefore, If there is a concern about the application of strain that cannot be ignored, for example, in a treatment involving a plastic deformation such as press forming using a metal die, it is most desirable to select niobium (Nb) as the material of the adhesive layer 2.

Further, when the adhesive layer 2 is formed, niobium (Nb)<titanium (Ti)<chromium (Cr) is established as an order of the one from a softer material of the adhesive layer 2. For example, when an aluminum (Al) plate is used as the metal substrate 1, there is a high possibility that abrasion of this press die is accelerated when press molding is applied to the surface-treated metal substrate including the adhesive layer 2 by using the press die. From this point of view, it is desirable to select a softer material as much as possible. Therefore, in this case, it is desirable to select niobium (Nb).

Further, for the reference for considering the material cost, the material costs of mining products in the present general market are arranged from the most inexpensive one, like chromium (Cr)<titanium (Ti)<niobium (Nb). Therefore, for example when it is requested that the most inexpensive material should be used, it is desirable to select chromium (Cr).

As described above, best material suited to the purpose at that time may be selected, in consideration of merit and demerit of each material.

Here, in the surface-treated metal substrate and the manufacturing method of the same according to the embodiments of the present invention, by forming at least the adhesive layer 2 and the bonding layer 3 on the surface of the metal substrate 1 having the passivation film on the outermost surface, the lead-free solder can be bonded to the surface by using the flux of weak activity. Therefore, it can be assumed that the present invention can be suitably applied to product fields as shown below.

(1) For example, a heat exchanger, a heat sink, and a heat releasing material, etc, in which aluminums (Al) need to be heated and bonded to each other by lead (Pb)-free solder.
(2) A cross fin-tube heat exchanger, the heat sink, and a heat releasing material, etc, in which an aluminum (Al) fin and a copper tube material are heated and bonded to each other by lead (Pb)-free solder.
(3) The heat exchanger, the heat sink, and the heat releasing material, etc, in which a stainless steel (SUS) material and a titanium (Ti) material need to be heated and bonded by lead (Pb)-free solder.
(4) By forming the lamination structure including at least the adhesive layer 2 and the bonding layer 3 on an outer layer of an aluminum (Al) wire material, a surface-treated aluminum wire can be provided, thereby making it possible to perform bonding such as a terminal connection by lead (Pb)-free solder.
(5) A wire material and an antenna material, etc, with a copper (Cu) wire solder-bonded to the aluminum (Al) material, the stainless steel (SUS) material, and the titanium (Ti) material, whose surfaces are treated such that at least the adhesive layer 2 and the bonding layer 3 are formed thereon.
(6) Aluminum (Al) bus-bar material, a sheet conductor, a titanium conductor, and a stainless steel conductor, etc, which are formed by applying surface treatment of forming at least the adhesive layer 2 and the bonding layer 3 thereon.
(7) A crimp terminal sheet for connecting each kind of wires, fabricated by processing the aluminum (Al) material whose surfaces are treated such that at least the adhesive layer 2 and the bonding layer 3 are formed thereon. However, these are only for examples, and an application range of the present invention is not limited thereto.

### EXAMPLES

### First Example

Various kinds of the surface-treated metal substrates explained in the first embodiment were fabricated by the aforementioned manufacturing method, with each kind of specification changed, to obtain a sample of a first example. Further, the surface-treated metal substrate by a specification/manufacturing method different from that of the first embodiment of the present invention was fabricated separately, to obtain a sample of a comparative example. Then, by using these samples, the solder wettability and the bonding strength of each of them were respectively evaluated.

### (Fabrication of the Samples)

Three kinds of aluminum (Al)-based metal, stainless steel-based metal, titanium (Ti)-based metal were prepared for the metal substrate 1, and regarding each of them, the surface-treated metal substrate was fabricated, with the adhesive layer 2 and the bonding layer 3 formed thereon, having structures described in the first embodiment, and each performance, etc, was evaluated.

A1050, being pure aluminum (Al), was prepared as typical aluminum (Al). Also, A5052 containing Mg was prepared as its variation, to conduct the same experiment (A5052 will be described later).

SUS301 was prepared as a stainless steel-based material, and one-kind titanium material was prepared as a titanium-based metal. A plate-shaped material having a thickness of 0.15 nm was prepared for each kind of them. The acid pickling treatment was not applied to the surface of these metal substrates 1, and sputtering film formation was performed thereafter, in a state that the passivation film remains on the outermost surface.

A sputtering film formation process was performed by using a DC magnetron sputtering apparatus (Type: SH-350 by ULVAC, Inc.). Argon (Ar) gas with pressure of 0.3 Pa or more and 9 Pa or less was set as an atmosphere (film formation atmosphere; similar as follows) when each film was formed. DC electric power (applied energy) applied to a target material was suitably adjusted according to the kind of metal. Thickness control of each film was performed by adjusting a film formation time based on a previously measured average film forming rate. The adhesive layer 2, the bonding layer 3, and further the protective layer 4 and the solder layer 5 in some cases, were formed on the surface of the metal substrate 1 in this order, and such a series of film forming step was sequentially performed in the same chamber, so that oxygen (or air, etc, like an indoor atmosphere) was not mixed therein, even when the kind of the metal was changed. Purity of the argon (Ar) gas during film formation was set to the purity of 99.999% or more, and each film forming step was executed while continuously flowing a constant amount of flow rate, and while maintaining the purity. The oxygen concentration in the film formation atmosphere at that time was assumed to be 0.001% or less.

Two kinds of gases of argon (Ar)+oxygen, and pure argon (Ar) were prepared as the film formation atmosphere used when the sample of the comparative example was fabricated. An oxygen content in the film formation atmosphere was adjusted by adjusting a flow rate ratio.

### (An Experiment Method and an Evaluation Method of the Samples)

### (1) Evaluation of the Solder Wettability

Tin-0.7 wt % copper (Sn-0.7 wt % Cu) alloy, being Pb-free solder, was used as the solder material, and by a meniscograph method, a wettability test device (Type: manufacture No. 2015) by TAMURA Corporation was used, and a sample piece with width of 10 mm cut out from each sample was immersed into flux (Type H-728 of HOZAN), 2 mm of which was then immersed into a bath tub maintained to a temperature of 220° C. at an immersion rate of 2 mm/seconds. Then, a time (zero cross time) required from the aforementioned immersion of the sample piece until obtaining a so-called solder coating state, was measured. Then, based on this time, the solder wettability of each sample was evaluated based on a reference shown below. This evaluation method shows that the shorter the time is, the more excellent the solder wettability is.

A: under 5 seconds

B: 5 seconds or more, and under 7 seconds

C: 7 seconds or more, and under 10 seconds

D: 10 seconds or more

(The aforementioned A, B, C, D are described in the corresponding column of each table)
(2) Evaluation of the Initial Solder Bonding Strength (Initial Evaluation Immediately after Film Formation);

Regarding each sample piece with solder coating applied to the surface by the method described in the aforementioned (1), bending was repeatedly performed, and the number of times of bending until a solder coating film was peeled off from the surface was counted, and thereby the bonding strength was counted. In this evaluation method, the bending was repeatedly performed until five times, to evaluate the bonding strength based on the reference described below.

A: Not peeled-off even in 5 times bending

B: Peeled-off in 3 to 4 times bending

C: Not peeled-off until first bending but peeled-off in second bending

D: Peeled-off before bending and cannot be evaluated due to a bonding failure state

(The aforementioned A, B, C, D are described in the corresponding column of each table)
(3) Evaluation of the Wettability after Application of Strain;

Bending strain and tensile strain were applied to each sample. First, the bending strain was applied. Specifically, the bending strain was applied four numbers of times, in a method of winding the sample around a pipe having a diameter of 15 nm (corresponding to a film thickness/diameter=0.15/15=0.01→1% in strain equivalent). In the second application, the sample was turned back after the first bending was applied, so that a tensile strain applied surface (outer surface of the plate material) was replaced with a compression applied surface (inner surface of the plate material). Then, in the third application also, the sample was similarly turned back, and the bending was performed at the same position of the sample as that of the first bending. After the third bending, the sample was turned back, and the fourth bending was performed at the same position of the sample as that of the second bending. After the fourth bending, the tensile stress was applied, and after an elongation amount of the sample was about 10%, the sample was released from this tensile stress and the application of strain was completed. Thereafter, the test of the solder wettability of each sample was conducted based on similar technique and reference as those of the aforementioned (2), and the solder wettability of each sample was evaluated.

(4) Evaluation of the Solder Bonding Strength after a Hydrogen Pressurization Test;

In order to examine a hydrogen embrittlement characteristic of each sample, solder-coated each sample was sealed in a hydrogen (H) gas atmosphere environment of 1 MPa·80° C. for 24 hours, and thereafter the bonding strength of each sample was evaluated based on the technique and the reference similar to those of the aforementioned (2).

### (5) Measurement of Oxygen Intensity Ratio X;

The oxygen content concentration in the interface (about 5 nm in thickness) between the adhesive layer 2 and the bonding layer 3 was measured by a spectroscopic analytical method. However, the interface (about 5 nm in thickness) between the metal substrate 1 and the adhesive layer 2, and the outermost surface (about 5 nm in thickness) of the bonding layer 3 are excluded from the measurement. Specifically, an X-ray photoelectron spectroscopy (XPS) was used to perform argon etching with 2 nm resolution, and obtain a peak value of the oxygen intensity ratio X defined in the following formula in the vicinity of the interface between the adhesive layer 2 and the bonding layer 3.

Oxygen intensity ratio X=oxygen intensity/{intensity of oxygen (O)+titanium (Ti) constituting the adhesive layer 2+intensity of copper (Cu)+intensity of nickel (Ni) and zinc (Zn)}

Then, when the value of the oxygen intensity ratio X satisfies X≦0.02 as a result of the oxygen content concentration measured by the photoelectron spectroscopy, this value is set to B as the value assumed to be suitable for the process condition of the first example of the present invention, and in other case, this value is set to D as the value out of the process condition of the first example of the present invention.

(The aforementioned B, D are described in the corresponding column of each table)

### (6) Evaluation of the Internal Residual Stress of the Adhesive Layer;

The internal residual stress after forming the adhesive layer 2 is generally varied widely from the tensile stress to the compression stress, in accordance with various process conditions such as material of the adhesive layer 2, film thickness, gas pressure during film formation, and oxygen concentration in a gas component.

The evaluation of the internal residual stress in the film of the formed adhesive layer 2 was performed by a cantilever method. The cantilever method (reference document is attached: journal of Vacuum Society of Japan J.VAC.Soc.JPN vol. 50, No 6.2007, P432) is a method of applying film forming process to a sheet having an already known mechanical characteristic, then fixing one end thereof and opening the other end thereof (to be free), and obtaining the internal stress of the film from a deformation direction and a deformation amount of the sheet. Here, whether the stress inside of the film was the compression stress or the tensile stress was judged and evaluated. The internal residual stress in the formed adhesive layer 2 mainly depends on a gas pressure and a film thickness during film formation. Therefore, an experiment of evaluating whether the stress of this film was the compression stress or the tensile stress was performed by previously setting the gas pressure and the film thickness under the same condition as that of preparing the sample, and based on this data, whether the internal residual stress of the adhesive layer 2 in each sample prepared under various different process conditions was the compression stress, tensile stress, or almost zero stress, was judged (evaluated).

Table 1 shows evaluation results of the internal residual stress in the adhesive layer 2 formed of the sputtering film composed of typical multiple kinds of titanium (Ti) prepared under different process conditions, in accordance with the aforementioned judgment methods. Based on the evaluation results shown in this table 1, whether the internal residual stress of the adhesive layer 2 in each sample was any one of the types of the tensile stress, zero stress, or the compression stress was judged. A case shown in the second line of table 1 is given as an example as follows. When the gas in the film formation atmosphere in the sputtering step was set as argon (Ar) gas of 0.3 Pa, it was so judged that the internal residual stress in the adhesive layer 2 by sputtering was zero in a case that the film thickness was 15 nm, 20 nm, 60 nm, and the internal residual stress was the compression stress in a case that the film thickness was 120 nm and 300 nm.

Here, in table 1, symbol “+” shows the tensile stress, and symbol “−” shows the compression stress, and “zero” shows the zero stress. Note that the same thing can be said for all tables hereinafter.

### (Experiment Result and Evaluation Result Using Each Sample)

(1) In a Case that the Metal Substrate is Aluminum (Al);

Table 2 arranges and shows the evaluation results of samples 101 to 107 as group 1, in the surface-treated metal substrate having the lamination structure of the adhesive layer 2 and the bonding layer 3 on the surface of the metal substrate 1 as shown in FIG. 1, wherein the internal residual stress of the adhesive layer 2 is the tensile stress. Here, the sample number of each sample is given, for the convenience of identifying each sample, and it is a matter of course that some kind of meaning such as a preferential order is not given to its arrangement order and the number itself. However, an intended purpose in each experiment is focused, and each sample prepared and evaluated for the same purpose is collected in one group, and the number of this group is given to a head number of the sample numbers. For example, in a case of each sample of the group 1 (samples of sample numbers 101 to 107; called samples 101 to 107 hereinafter), this is the group 1, and therefore the number of the third digit of this sample number is 1, and as the number after second digit or after, the number showing its arrangement order is given, like 01, 02, 03 . . . . Namely, for example if the sample number is 103, this means that the sample is the third one of the group 1 (the same thing can be said for the table 3 and thereafter).

Note that in all tables including table 2, “sput.” means “sputtering process, “ex.” means “example”, and “com.ex.” means “comparative example”.

According to the results shown in this table 2, when the internal residual stress of the adhesive layer 2 was the tensile stress, it was confirmed that the solder bonding strength (expressed by D) was insufficient, irrespective of the film thickness of the adhesive layer 2. Also, even when the adhesive layer 2 was not provided (sample 101), the bonding strength (expressed by D) was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of other setting.

Table 3 shows the evaluation results of samples 201 to 205 as group 2 in the surface-treated metal substrate, with the adhesive layer 2 and the bonding layer 3 formed on the surface of the metal substrate 1 shown in FIG. 1, wherein the film thickness of the bonding layer 3 is to 20 nm or more uniformly and the internal residual stress of the adhesive layer 2 is set to zero uniformly, and the film thickness of the adhesive layer 2 is variously changed.

From the results shown in this table 3, it was confirmed that an initial solder bonding strength was insufficient when the film thickness of the adhesive layer 2 was thin like 5 nm, and when it was thick like 250 nm. Further, it was confirmed that the wettability after application of strain had a tendency of decrease, with film thickness 200 nm taken as a boundary point, when the film thickness of the adhesive layer 2 was increased. Moreover, it was confirmed that the bonding strength after hydrogen test was apt to be decreased, as the film thickness of the adhesive layer 2 was increased.

Table 4 shows the evaluation results in the surface-treated metal substrate, with the adhesive layer 2 and the bonding layer 3 formed on the surface of the metal substrate 1 as shown in FIG. 1, when the internal residual stress of the adhesive layer is set to zero, and the film thickness of the adhesive layer 2 is set to 20 nm (group 3), 60 nm (group 4), 200 nm (group 5), and the film thickness of the bonding layer 3 is variously changed (10 nm, 15 nm, 60 nm, 120 nm, 200 nm) in a range from 10 nm to 200 nm.

From the results shown in this table 4, it was confirmed that when the bonding layer 3 was under 15 nm, the solder bonding strength was insufficient even if the film thickness of the adhesive layer 2 was variously changed in a range from 20 nm to 200 nm, and when the film thickness of the bonding layer 3 was 15 nm or more, excellent solder bonding strength and solder wettability could be achieved.

Further, according to the results of the samples of the group 4 and the group 5 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Table 5 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 20 nm (group 6), 60 nm (group 7), 200 nm and 300 nm (group 8), and the film thickness of the bonding layer 3 was variously changed (10 nm, 15 nm, 60 nm, 120 nm, 200 nm) in the range from 10 nm to 200 nm.

From the results shown in this table 5, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

Moreover, according to the results of the samples of the group 7 and the group 8 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Further, in a case of sample 806 of the group 8 in particular, the initial solder bonding strength was decreased, which was assumed to be caused by extremely thick film thickness 300 nm of the adhesive layer 2, compared with other case of the film thickness. This also shows that the film thickness of the adhesive layer 2 was desirably set to 200 nm or less.

Table 6 shows the evaluation results in the surface-treated metal substrate, with the adhesive layer 2 and the bonding layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 9), made of tin (Sn) sputtering film (group 10), made of copper-60 wt % nickel (Cu-60 wt % Ni) sputtering film (group 11), and made of copper-20 wt % nickel (Cu-20 wt % Ni) sputtering film (group 12).

From the results shown in this table 6, it was confirmed that regarding all performance items excluding the solder bonding strength after hydrogen test, further improvement of its performance could be achieved, by setting the film thickness of the adhesive layer 2 in the range from 20 nm or more and 200 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 7 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 13), made of copper-5 wt % nickel (Cu-5 wt % Ni) sputtering film (group 14), made of copper-5 wt % nickel-10 wt % zinc (Cu-5 wt % Ni-10 wt % Zn) sputtering film (group 15), made of copper-10 wt % nickel-20 wt % zinc (Cu-10 wt % Ni-20 wt % Zn) sputtering film (group 16), and made of copper-20 wt % zinc (Cu-20 wt % Zn) sputtering film (group 17), as comparative examples.

From the results shown in this table 7, it was confirmed that regarding all performance items excluding the solder bonding strength after hydrogen test, further improvement of its performance could be achieved, by setting the film thickness of the adhesive layer 2 made of pure copper (Cu) in the range from 20 nm or more and 200 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 8 shows the evaluation results in the surface-treated metal substrate, with the adhesive layer 2 and the bonding layer 3 formed on the surface of the metal substrate 1 as shown in FIG. 2, when the bonding layer 3 is made of copper-40 wt % nickel (Cu-40 wt % Ni) uniformly and when the protective layer 4 is not provided and is made of copper-40 wt % zinc (Cu-40 wt % Zn) sputtering film (group 18), and made of copper-20 wt % zinc (Zn) (Cu-20 wt % Zn) sputtering film (group 19), as comparative examples (samples 1801 and 1802).

From the results shown in this table 8, it was confirmed that regarding all performance items excluding the solder bonding strength after hydrogen test, further improvement of its performance could be achieved, by setting the film thickness of the adhesive layer 2 in the range from 20 nm or more and 200 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 9 shows the evaluation results in the surface-treated metal substrate, with the adhesive layer 2 and the bonding layer 3 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 20), and made of copper-5 wt % zinc-10 wt % nickel (Cu-5 wt % Zn-10 wt % Ni) sputtering film (group 21), made of copper-10 wt % zinc-10 wt % nickel (Cu-10 wt % Zn-10 wt % Ni) sputtering film (group 22), and the bonding layer 3 is made of copper-10 wt % zinc (Cu-10 wt % Zn) sputtering film without nickel, and when the protective layer 4 is not provided (sample 2301) and is made of nickel (Ni) sputtering film (group 23) as comparative examples.

From the results shown in this table 9, it was confirmed that each kind of performance was sufficient, although some of them are slightly inferior to other structure and material setting explained based on the aforementioned tables 2 to 8, excluding the solder wettability after application of strain, by using the material containing zinc (Zn) as a forming material of the bonding layer 3 and the protective layer 4. Further, the material cost can be reduced more than that of the aforementioned each case.

Also, particularly from the results of samples 2301 and 2302, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 2301), and the solder bonding strength was insufficient yet, even when the protective layer 4 was provided (in a case of the sample 2302).

When the result of the sample of the group 23 and the results of the samples of the samples of the groups 20, 21, 22 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 10 shows the evaluation results in the surface-treated metal substrate, with the adhesive layer 2 and the bonding layer 3 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when an oxygen concentration in the argon (Ar) gas used as atmosphere gas during sputtering film formation of these sputtering films is set to 0.05% and set to 0.005% (in either case, the oxygen intensity ratio X in a finished sample exceeds 0.02 (0.02<X)).

From the result shown in this table 10, it was confirmed that in a case of the metal substrate 1 made of pure aluminum (Al), when the concentration of the oxygen contained in an inert atmosphere gas during sputtering film formation was set to 0.001% or more and the oxygen intensity ratio X in the finished sample was set beyond 0.02, the initial solder bonding strength was insufficient, irrespective of the other structure and the setting of each kind of process condition.

(2) In a Case that the Metal Substrate is Stainless Steel (SUS);

Table 11 shows the evaluation results of samples 2501 to 2507 as group 25 in the surface-treated metal substrate, with the adhesive layer 2 and the bonding layer 3 formed on the surface of the metal substrate 1 as shown in FIG. 1, wherein the internal residual stress of the adhesive layer 2 is the tensile stress.

According to the result shown in this table 11, it was confirmed that when the internal residual stress of the adhesive layer 2 was the tensile stress, the bonding strength was insufficient (expressed by D), irrespective of the film thickness of the adhesive layer 2. Also, in a case of not providing the adhesive layer 2 (sample 2501), it was confirmed that the bonding strength was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of the other setting including the material of the metal substrate 1.

Table 12 shows the evaluation results in the surface-treated metal substrate, with the adhesive layer 2 and the bonding layer 3 formed on the surface of the metal substrate 1 as shown in FIG. 1, when the film thickness of the bonding layer 3 is set to 20 nm or more uniformly and the internal residual stress of the adhesive layer 2 is set to zero uniformly, and the film thickness of the adhesive layer 2 is variously changed.

From the result shown in this table 12, it was confirmed that the initial solder bonding strength was insufficient, when the film thickness of the adhesive layer 2 was thin like 5 nm, and when the film thickness of the adhesive layer 2 was thick like 250 nm. Further, it was confirmed that the wettability after application of strain had a tendency of decrease, with film thickness 200 nm taken as a boundary point, when the film thickness of the adhesive layer 2 was increased. Moreover, it was confirmed that the bonding strength after hydrogen test had a decrease tendency, as the film thickness of the adhesive layer 2 was increased.

Table 13 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to zero, and the film thickness of the adhesive layer 2 is set to 20 nm (group 27), 60 nm (group 28), 200 nm (group 29), and the film thickness of the bonding layer 3 is variously changed (10 nm, 15 nm, 60 nm, 120 nm, 200 nm) in a range from 10 nm to 200 nm.

From the result shown in this table 13, it was confirmed that when the bonding layer 3 was under 15 nm, the solder bonding strength was insufficient even when the film thickness of the adhesive layer 2 was changed in the range from 20 nm to 200 nm, and when the film thickness of the bonding layer 3 was 15 nm or more, excellent solder bonding strength and solder wettability could be achieved.

Further, according to the results of the group 28 and the group 29 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Table 14 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 20 nm (group 30), 60 nm (group 31), 200 nm and 300 nm (group 32), and the film thickness of the bonding layer 3 is variously changed (10 nm, 15 nm, 60 nm, 120 nm, 200 nm) in the range from 10 nm to 200 nm.

From the result sown in this table 14, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

Moreover, according to the results of the samples of the group 31 and the group 32 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Further, in a case of sample 3206 of the group 32 according to the comparative example in particular, the initial solder bonding strength was decreased, which was assumed to be caused by extremely thick film thickness 300 nm of the adhesive layer 2, compared with other case of the film thickness. This also shows that the film thickness of the adhesive layer 2 was desirably set to 200 nm or less.

Table 15 shows the evaluation results in the surface-treated metal substrate, with the adhesive layer 2, the bonding layer 4, and the protective layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 33), made of tin (Sn) sputtering film (group 34), made of copper-60 wt % nickel (Cu-60 wt % Ni) sputtering film (group 35), and made of copper-20 wt % nickel (Cu-20 wt % Ni) sputtering film (group 36).

From the results shown in this table 15, it was confirmed that regarding all performance items excluding the solder bonding strength after hydrogen test, further improvement of its performance could be achieved, by setting the film thickness of the adhesive layer 2 in the range from 20 nm or more and 200 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 16 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 37), made of copper-5 wt % nickel (Cu-5 wt % Ni) sputtering film (group 38), made of copper-5 wt % nickel-10 wt % zinc (Cu-5 wt % Ni-10 wt % Zn) sputtering film (group 39), made of copper-10 wt % nickel-20 wt % zinc (Cu-10 wt % Ni-20 wt % Zn) sputtering film (group 40), and made of copper-20 wt % zinc (Cu-20 wt % Zn) sputtering film (group 41), as comparative examples.

From the results shown in this table 16, it was confirmed that regarding all performance items excluding the solder bonding strength after hydrogen test, further improvement of its performance could be achieved, by setting the film thickness of the adhesive layer 2 made of pure copper (Cu) in the range from 20 nm or more and 200 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 17 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-40 wt % nickel (Cu-40 wt % Ni) uniformly and when the protective layer 4 is not provided (samples 4201 and 4202) and is made of copper-40 wt % zinc (Cu-40 wt % Zn) sputtering film (group 42), and made of copper-20 wt % zinc (Zn) (Cu-20 wt % Zn) sputtering film (group 43), as comparative examples.

From the results shown in this table 17, it was confirmed that regarding all performance items excluding the solder bonding strength after hydrogen test, further improvement of its performance could be achieved, by setting the film thickness of the adhesive layer 2 in the range from 20 nm or more and 200 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based metal alloy containing zinc (Zn) at a lower material cost than that of copper-nickel (Cu—Ni)-based metal as the material of the protective layer 4, the overall manufacturing cost including the material cost can be reduced, without decrease of the performance.

Table 18 shows the evaluation results in the surface-treated metal substrate, with the adhesive layer 2, the bonding layer 3, and the protective layer 4 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 44), and made of copper-5 wt % zinc-10 wt % nickel (Cu-5 wt % Zn-10 wt % Ni) sputtering film (group 45), and made of copper-10 wt % zinc-10 wt % nickel (Cu-10 wt % Zn-10 wt % Ni) sputtering film (group 46), and the bonding layer 3 is made of copper-10 wt % zinc (Cu-10 wt % Zn) sputtering film without nickel, and when the protective layer 4 is not provided and is made of nickel (Ni) sputtering film (group 47), as comparative examples.

From the results shown in this table 18, it was confirmed that each kind of performance was sufficient, although some of them are slightly inferior to other structure and material setting explained based on the aforementioned tables 11 to 17, by using the material containing zinc (Zn) as a forming material of the bonding layer 3 and the protective layer 4. Further, the material cost can be reduced more than that of the aforementioned each case.

Also, particularly from the results of samples 4701 and 4702, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 4701), and the solder bonding strength was insufficient yet, even when the protective layer 4 was provided (in a case of the sample 4702).

When the result of the sample of the group 47 and the results of the samples of the groups 44, 45, 46 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 19 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when the oxygen concentration in the argon (Ar) gas used as atmosphere gas during sputtering film formation of these sputtering films is set to 0.05% and set to 0.005% (in either case, the oxygen intensity ratio X in a finished sample exceeds 0.02 (0.02<X)).

From the result shown in this table 19, it was confirmed that when the concentration of the oxygen contained in an inert atmosphere gas during sputtering film formation was set to 0.001% or more and the oxygen intensity ratio X in the finished sample was set beyond 0.02, the initial solder bonding strength was insufficient, irrespective of the other structure and the setting of each kind of process condition.

(3) In a Case that the Metal Substrate is Titanium (Ti);

Table 20 shows the evaluation results as group 49 in the surface-treated metal substrate, with the adhesive layer 2 and the bonding layer 3 formed on the surface of the metal substrate 1 as shown in FIG. 1, when the internal residual stress of the adhesive layer 2 is the tensile stress.

Here, when the metal substrate 1 is a titanium (Ti) material, an influence of hydrogen on the adhesive layer 2 made of this titanium (Ti) coexists with an influence of hydrogen on the metal substrate 1 made of titanium (Ti) similarly. Therefore, it is actually difficult or impossible to exactly measure/evaluate the influence of hydrogen on the simple adhesive layer 2 only. Therefore, when the metal substrate 1 is titanium (Ti), the solder bonding strength after hydrogen test was not measured and evaluated.

According to the result shown in this table 20, it was confirmed that when the internal residual stress of the adhesive layer 2 was the tensile stress, the bonding strength was insufficient (expressed by D), irrespective of the film thickness of the adhesive layer 2. Also, in a case of not providing the adhesive layer 2 (sample 4901), it was confirmed that the bonding strength was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of the other setting including the material of the metal substrate 1.

Table 21 shows the evaluation results in the surface-treated metal substrate, with the adhesive layer 2 and the bonding layer 3 formed on the surface of the metal substrate 1 as shown in FIG. 1, when the film thickness of the bonding layer 3 is set to 20 nm or more uniformly and the internal residual stress of the adhesive layer 2 is set to zero uniformly, and the film thickness of the adhesive layer 2 is variously changed.

From the result shown in this table 21, it was confirmed that the initial solder bonding strength was insufficient, when the film thickness of the adhesive layer 2 was thin like 5 nm, and when the film thickness of the adhesive layer 2 was thick like 250 nm. Further, it was confirmed that the wettability after application of strain had a tendency of decrease, with film thickness 200 nm taken as a boundary point, when the film thickness of the adhesive layer 2 was increased.

Table 22 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to zero, and the film thickness of the adhesive layer 2 is set to 20 nm (group 51), 60 nm (group 52), 200 nm (group 53), and the film thickness of the bonding layer 3 is variously changed (10 nm, 15 nm, 60 nm, 120 nm, 200 nm) in a range from 10 nm to 200 nm.

From the result shown in this table 22, it was confirmed that when the bonding layer 3 was under 15 nm, the solder bonding strength was insufficient even when the film thickness of the adhesive layer 2 was changed in the range from 20 nm to 200 nm, and when the film thickness of the bonding layer 3 was 15 nm or more, excellent solder bonding strength and solder wettability could be achieved.

Table 23 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 20 nm (group 54), 60 nm (group 55), 200 nm and 300 nm (group 56), and the film thickness of the bonding layer 3 is variously changed (10 nm, 15 nm, 60 nm, 120 nm, 200 nm) in the range from 10 nm to 200 nm.

From the result sown in this table 23, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

In a case of the sample 5606 according to the comparative example of group 56 in particular, the decrease of the initial solder bonding strength was confirmed, which was assumed to be caused by excessively thick film thickness compared with other case of the film thickness. This also shows that the film thickness of the adhesive layer 2 is desirably set to 200 nm or less.

Table 24 shows the evaluation results in the surface-treated metal substrate, with the adhesive layer 2, the bonding layer 4, and the protective layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 57), made of tin (Sn) sputtering film (group 58), made of copper-60 wt % nickel (Cu-60 wt % Ni) sputtering film (group 59), and made of copper-20 wt % nickel (Cu-20 wt % Ni) sputtering film (group 60).

From the results shown in this table 24, it was confirmed that regarding all performance items excluding the solder bonding strength after hydrogen test, further improvement of its performance could be achieved, by setting the film thickness of the adhesive layer 2 in the range from 20 nm or more and 200 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 25 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 61), made of copper-5 wt % nickel (Cu-5 wt % Ni) sputtering film (group 62), made of copper-5 wt % nickel-10 wt % zinc (Cu-5 wt % Ni-10 wt % Zn) sputtering film (group 63), made of copper-10 wt % nickel-20 wt % zinc (Cu-10 wt % Ni-20 wt % Zn) sputtering film (group 64), and made of copper-20 wt % zinc (Cu-20 wt % Zn) sputtering film (group 65), as comparative examples.

From the results shown in this table 25, it was confirmed that regarding all performance items excluding the solder bonding strength after hydrogen test, further improvement of its performance could be achieved, by setting the film thickness of the adhesive layer 2 made of pure copper (Cu) in the range from 20 nm or more and 200 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 26 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-40 wt % nickel (Cu-40 wt % Ni) uniformly and when the protective layer 4 is not provided (samples 6601 and 6602) and is made of copper-40 wt % zinc (Cu-40 wt % Zn) sputtering film (group 66), and made of copper-20 wt % zinc (Zn) (Cu-20 wt % Zn) sputtering film (group 67), as comparative examples.

From the results shown in this table 26, it was confirmed that regarding all performance items (however, the solder bonding strength after hydrogen test is excluded because of impossibility to evaluate), further improvement of its performance could be achieved, by setting the film thickness of the adhesive layer 2 in the range from 20 nm or more and 200 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 27 shows the evaluation results in the surface-treated metal substrate, with the adhesive layer 2, the bonding layer 3, and the protective layer 4 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 68), and made of copper-5 wt % zinc-10 wt % nickel (Cu-5 wt % Zn-10 wt % Ni) sputtering film (group 69), and made of copper-10 wt % zinc-10 wt % nickel (Cu-10 wt % Zn-10 wt % Ni) sputtering film (group 70), and the bonding layer 3 is made of copper-10 wt % zinc (Cu-10 wt % Zn) sputtering film without nickel, and when the protective layer 4 is not provided and is made of nickel (Ni) sputtering film (group 71), as comparative examples.

From the results shown in this table 27, it was confirmed that each kind of performance was sufficient, although some of them are slightly inferior to other structure and material setting explained based on the aforementioned tables 20 to 26, by using the material containing zinc (Zn) as the forming material of the bonding layer 3 and the protective layer 4. Further, the material cost can be reduced more than that of the aforementioned each case.

Also, particularly from the results of samples 7101 and 7102, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 7101), and the solder bonding strength was insufficient yet even when the protective layer 4 was provided (in a case of the sample 7102).

When the result of the sample of the group 71 and the results of the samples of the groups 68, 69, 70 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 28 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when the oxygen concentration in the argon (Ar) gas used as atmosphere gas during sputtering film formation of these sputtering films is set to 0.05% and set to 0.005% (in either case, the oxygen intensity ratio X in a finished sample exceeds 0.02 (0.02<X)).

From the result shown in this table 28, it was confirmed that when the concentration of the oxygen contained in an inert atmosphere gas during sputtering film formation was set to 0.001% or more and the oxygen intensity ratio X in the finished sample was set beyond 0.02, the initial solder bonding strength was insufficient, irrespective of the other structure and the setting of each kind of process condition.

### (4) In a Case of Setting a Solder Layer Made of a Plating Film Instead of the Protective Layer;

The solder layer 5 was formed by an electroless plating method, after the surface-treated metal substrate having the structure shown in FIG. 1 was fabricated.

Table 29 shows the evaluation results of each kind of performance of the sample of the surface-treated metal substrate formed by electroless plating the solder layer 5.

In sample 7301 and sample 7302, the metal substrate 1 made of pure aluminum (Al) was used, with the bonding layer 3 set to contain copper-10 wt % nickel (Cu-10 wt % Ni), and the solder layer 5 was formed thereon by the electroless plating method. The film thickness of this solder layer 5 was set to 1 μm (sample 7301) and 5 μm (sample 7302).

In sample 7303 and sample 7304, a stainless steel-based (SUS-based) plate material was used as the metal substrate 1, instead of pure aluminum (Al).

In sample 7401 and sample 7402, the metal substrate 1 made of pure aluminum (Al) was used, and the solder layer 5 made of nickel (Ni) was formed thereon by the electroless plating method. The film thickness of the solder layer 5 was set to 0.3 μm (sample 7401) and 5 μm (sample 74302).

In sample 7403 and sample 7404, the stainless steel-based (SUS-based) plate material was used as the metal substrate 1, instead of pure aluminum (Al).

From the result shown in table 29, it was confirmed that the solder layer 5 by the electroless plating method could be formed, instead of the protective layer 4 made of the sputtering film. By forming the solder layer 5 by such a plating method, a thick solder layer 5 with film thickness set as the unit of μm could be formed, with good throughput. Therefore, further improvement of the solder bonding strength could be achieved, without inviting a higher manufacturing cost. Further, in addition, tin-silver (SN—Ag), tin-zinc (Sn-zinc), and zinc (Zn), etc, can also be used as plating materials.

From the results as described above, a main essential matter is extracted as follows.

The film thickness of the adhesive layer 2 is desirably set to 20 nm or more and 200 nm or less. When it is thinner than 20 nm, there is a high possibility that the solder wettability is insufficient. Reversely, when it is thicker than 200 nm, there is a high possibility that an adverse influence by hydrogen becomes stronger.

The film thickness of the bonding layer 3 is desirably set to 15 nm or more. When it is thinner than 15 nm, there is a high possibility that both of the solder wettability and solder bonding strength are insufficient. Also, when it is thicker than 200 nm, the bonding layer 3 has a tendency of being fragile to application of strain.

It can be considered that even if the film thickness of the protective layer 4 is more increased than 5 μm, there is no substantial demerit in an aspect of performance as the protective layer 4 itself, other than a higher manufacturing cost including the material cost.

When nickel (Ni) is used as the material of the protective layer 4, although there is a possibility that the manufacturing cost and the material cost are increased, the protective layer 4 made of nickel (Ni) can be used without problem in the aspect of its performance.

Also, when copper-60 wt % nickel (Cu-60 wt % Ni) is used, there is no problem in the aspect of performance, and there is a merit that it is slightly more inexpensive than nickel (Ni) simple body.

Also, when copper-20 wt % nickel (Cu-20 wt % Ni) is used, there is a merit that it is more inexpensive than the nickel (Ni) simple body.

Also, when copper-5 wt % nickel (Cu-5 wt % Ni) is used and tin (Sn) is used, there is a merit that it is greatly more inexpensive than the nickel (Ni) simple body, without problem in the aspect of performance.

Also, when copper-5 wt % nickel-10 wt % Zn(Cu-5 wt % Ni-10 wt % Zn) is used, and copper-10 wt % nickel-20 wt % Zn(Cu-10 wt % Ni-20 wt % Zn) is used, there is a merit that a zinc (Zn) component functions as a sacrificial protection material, and other than this merit, there is also a merit that it contributes to strengthening the solder wettability.

Also, when copper-20 wt % zinc (Cu-20 wt % Zn) is used, there is a merit that the zinc (Zn) component functions as the sacrificial protection material, and contributes to reducing the manufacturing cost including the material cost. However, there is a possibility that the solder wettability is decreased in some cases.

Also, there is a merit in the copper-10 wt % nickel-40 wt % zinc (Cu-10 wt % Ni-40 wt % Zn), such that a large volume of zinc (Zn) components can be added, when the bonding layer 3 is requested to have a sufficient function as the sacrificial protection material.

In the surface-treated metal substrate according to the first embodiment and the first example of the present invention, the adhesive layer 2 is made of titanium (Ti). However, titanium (Ti) is a metal having an intermediate hardness between niobium (Nb) and chromium (Cr), and a relatively inexpensive material. This is a merit of using titanium (Ti) in the adhesive layer 2. However, generally titanium (Ti) has great hydrogen absorbency and when strain is applied, the titanium adhesive layer 2 cannot be used unless the film thickness is decreased. Namely, when not used in a hydrogen environment and an environment of press molding, etc, the titanium adhesive layer 2 has an advantageous characteristic mainly in the point of the manufacturing cost including the material cost.

Regarding the oxygen concentration in an atmosphere of forming the adhesive layer 2, it is desirable to intentionally reduce the oxygen concentration like 0.001% or less. For example, when the oxygen concentration is beyond 0.001%, the oxygen intensity ratio X of the finished adhesive layer 2 is also beyond 0.02, and there is a high possibility that the solder wettability and the solder bonding strength are decreased.

Then, by performing sputtering film formation in the film formation atmosphere with low oxygen concentration, it is desirable to set the oxygen intensity ratio X of the finished adhesive layer 2 to 0.02 or less by sputtering, when the metal substrate 1 is pure aluminum (Al) or stainless steel (SUS), or titanium (Ti).

When this oxygen intensity ratio X is beyond 0.02, there is a high possibility that the initial solder bonding strength is insufficient, irrespective of the other structure and the setting of the film thickness and each kind of process condition, etc.

However, here, it is confirmed by the inventors of the present invention by the following experiment and consideration therefore, that when the metal substrate 1 is an alloy containing magnesium (Mg) such as A5052, being a kind of an aluminum alloy, the oxygen intensity ratio X of the finished adhesive layer 2 is desirably set to 0.04 or less by sputtering.

Namely, the sample was prepared in the same setting as the setting in which the aluminum alloy (A5052) containing magnesium (Mg) was used as the material of the metal substrate 1 instead of pure aluminum (Al), and regarding all other structures and conditions of the experiment, pure aluminum (Al) was used as the material of the metal substrate 1. Then, by using this sample, the experiment was performed regarding a case that the oxygen intensity ratio X was set to 0.04 or less, and a case that the oxygen intensity ratio X was set to beyond 0.04, and its result was examined. However, the solder bonding intensity after hydrogen-treatment was omitted. Table 30, table 31, and table 32 arrange, sum-up, and show the results. Note that in these tables 30, 31, 32, in order to make it easy to correspond to the experiment using the metal substrate 1 made of pure aluminum (Al), and the same sample number and group number are given to the samples experimented in the same setting as the setting in a case of using the metal substrate 1 made of pure aluminum (Al), as the sample number and the group number in a case of using the metal substrate 1 made of the aluminum alloy (A5052) containing magnesium (Mg) as described below.

From experiment results as shown in the table 30, table 31, and table 32, it was found that when the aluminum alloy (A5052) containing magnesium (Mg) was used in the metal substrate 1, each kind of performance of the finished samples of the examples and the finished samples of the comparative examples shows the same result as the result in a case of using pure aluminum in the metal substrate 1. However, particularly regarding the oxygen intensity ratio X in the adhesive layer 2, it was confirmed that both of the solder wettability and initial solder bonding property could be made excellent, in the same way as the case of using pure aluminum (Al) in the metal substrate 1, by setting it to 0.04 or less instead of setting it to 0.02 or less in a case of pure aluminum (Al). In contrast, when the oxygen intensity ratio X is set to beyond 0.04, it was confirmed that the initial solder boding strength was insufficient, irrespective of the other structure and the setting of the film thickness and each kind of process condition, etc, in the same way as the case of setting the oxygen intensity ratio X to beyond 0.02 in a case of using pure aluminum (Al) in the metal substrate 1.

Therefore, from such a result, it was found that the oxygen intensity ratio X of the finished adhesive layer 2 was set to 0.04 or less by sputtering, when the metal substrate 1 was made of an alloy containing magnesium (Mg) such as A5052, being a kind of the aluminum alloy.

### Second Example

Various surface-treated metal substrates as explained in the second embodiment were fabricated, with each kind of specification changed, and they were set as the samples of the second example. Further, the surface-treated metal substrate by a different specification and a manufacturing method from those of the second embodiment of the present invention was also separately fabricated, for comparison with the samples of the second example, and this surface-treated metal substrate was set as the sample of the comparative example. Then, by using these samples, the solder wettability and the bonding strength were respectively evaluated in each sample.

(Preparation of the Sample)

Three kinds of aluminum (Al)-based metal, stainless steel-based metal, and titanium (Ti)-based metal substrates 1 were prepared, and the surface-treated metal substrate, with the adhesive layer 2 and the bonding layer 3 formed thereon by the manufacturing method and the structure described in the second embodiment was fabricated for each of the metal substrates 1, and each performance was evaluated.

A1050, being pure aluminum (Al) was given as a typical one of the aluminum (Al)-based metal. Also, as its variation, A5052 containing Mg was also prepared to conduct a similar experiment (this A5052 will be described later).

SUS301 was selected as the stainless steel-based material, and one kind titanium material was selected as the titanium-based metal. A plate-like material having thickness of 0.15 mm was prepared for each kind. No acid pickling treatment was applied to the surfaces of these metal base materials, and sputtering film formation was performed thereafter, in a state that the passivation film remained on the outermost surface.

A sputtering film formation process was performed by using a DC magnetron sputtering apparatus (Type: SH-350 by ULVAC, Inc.). Argon (Ar) gas with pressure of 0.3 Pa or more and 9 Pa or less was set as an atmosphere (film formation atmosphere; similar as follows) when each film was formed. DC electric power (applied energy) applied to a target material was suitably adjusted according to the kind of metal. Thickness control of each film was performed for each kind of metal, by adjusting a film formation time based on a previously measured average film forming rate. The adhesive layer 2, the bonding layer 3, and further the protective layer 4 and the solder layer 5 in some cases, were formed on the surface of the metal substrate 1 in this order, and such a series of film forming step was sequentially performed in the same chamber, so that oxygen (or air, etc, like an indoor atmosphere) was not mixed therein, even when the kind of the metal was changed. Purity of the argon (Ar) gas during film formation was set to the purity of 99.999% or more, and each film forming step was executed while continuously flowing a constant amount of flow rate, while maintaining the purity. The oxygen concentration in the film formation atmosphere at that time was assumed to be 0.001% or less.

Two kinds of gases of argon (Ar)+oxygen mixed gas, and pure argon (Ar) were prepared as the film formation atmosphere used when the sample of the comparative example was fabricated. An oxygen content in the film formation atmosphere was adjusted by adjusting a flow rate ratio.

### (An Experiment Method and an Evaluation Method of the Sample)

### (1) Evaluation of the Solder Wettability

Tin-0.7 wt % copper (Sn-0.7 wt % Cu) alloy, being Pb-free solder, was used as the solder material, and by a meniscograph method, the wettability test device (Type: manufacture No. 2015) by TAMURA Corporation was used, and a sample piece with width of 10 mm cut out from each sample was immersed into flux (Type H-728 of HOZAN), 2 mm of which was then immersed into a bath tub maintained to a temperature of 220° C. at an immersion rate of 2 mm/seconds. Then, a time (zero cross time) required from the aforementioned immersion of the sample piece until obtaining a so-called solder coating state, was measured. Then, based on this time, the solder wettability of each sample was evaluated based on a reference shown below. This evaluation method shows that the shorter the time is, the more excellent the solder wettability is.

A: under 5 seconds

B: 5 seconds or more, and under 7 seconds

C: 7 seconds or more, and under 10 seconds

D: 10 seconds or more

(The aforementioned A, B, C, D are described in the corresponding column of each table)
(2) Evaluation of the Initial Solder Bonding Strength (Initial Evaluation Immediately after Film Formation);

Regarding each sample piece with solder coating applied to the surface by the method described in the aforementioned (1), bending was repeatedly performed with a bending diameter of 10 mm, and the number of times of bending until a solder coating film was peeled off from the surface was counted, and thereby the bonding strength was counted. In this evaluation method, the bending was repeatedly performed until five times, to evaluate the bonding strength based on the reference described below.

A: Not peeled-off even in 5 times bending

B: Peeled-off in 3 to 4 times bending

C: Not peeled-off until first bending but peeled-off in second bending

D: Peeled-off before bending and cannot be evaluated due to a bonding failure state

(The aforementioned A, B, C, D are described in the corresponding column of each table)
(3) Evaluation of the Wettability after Application of Strain;

Bending strain and tensile strain were applied to each sample. First, the bending strain was applied. Specifically, the bending strain was applied four numbers of times, in a method of winding the sample around a pipe having a diameter of 15 nm (corresponding to a film thickness/diameter=0.15/15=0.01→1% in strain equivalent). In the second application, the sample was turned back after the first bending was applied, so that a tensile strain applied surface (outer surface of the plate material) was replaced with a compression strain applied surface (inner surface of the plate material). Then, in the third application also, the sample was similarly turned back, and the bending was performed at the same position of the sample as that of the first bending. After the third bending, the sample was turned back, and the fourth bending was performed at the same position of the sample as that of the second bending. After the fourth bending, the tensile stress was applied, and after an elongation amount of the sample was about 10%, the sample was released from this tensile stress and the application of strain was completed. Thereafter, the test of the solder wettability of each sample was conducted based on similar technique and reference as those of the aforementioned (2), and the solder wettabiltiy of each sample was evaluated.

(4) Evaluation of the Solder Bonding Strength after a Hydrogen Pressurization Test;

In order to examine a hydrogen embrittlement characteristic of each sample, solder-coated each sample was sealed in a hydrogen (H) gas atmosphere environment of 1 MPa·80° C. for 24 hours, and thereafter the bonding strength of each sample was evaluated based on the technique and the reference similar to those of the aforementioned (2).

### (5) Measurement of Oxygen Intensity Ratio X;

The oxygen content concentration of the material in the interface (about 5 nm in thickness) between the adhesive layer 2 and the bonding layer 3 was measured as the oxygen intensity ratio X by a spectroscopic analytical method. However, the interface (about 5 nm in thickness) between the metal substrate 1 and the adhesive layer 2, and the outermost surface (about 5 nm in thickness) of the bonding layer 3 were excluded from the measurement. Specifically, an X-ray photoelectron spectroscopy (XPS) was used to perform argon etching with 2 nm resolution, and obtain a peak value of the oxygen intensity ratio X defined in the following formula, in the vicinity of the interface between the adhesive layer 2 and the bonding layer 3.

Oxygen intensity ratio X=oxygen intensity/{intensity of oxygen (O)+intensity of niobium (Nb) constituting the adhesive layer 2+intensity of copper (Cu)+intensity of nickel (Ni) and zinc (Zn)}

Then, when the value of the oxygen intensity ratio X satisfies X≦0.02 as a result of the oxygen content concentration measured by the photoelectron spectroscopy, this value was set to B as the value assumed to be suitable for the process condition of the second example of the present invention, and in other case, this value was set to D as the value out of the process condition of the second example of the present invention.

(The aforementioned B, D are described in the corresponding column of each table)

### (6) Evaluation of the Internal Residual Stress of the Adhesive Layer;

The internal residual stress after forming the adhesive layer 2 is generally varied widely from the tensile stress to the compression stress, in accordance with various process conditions such as material of the adhesive layer 2, film thickness, gas pressure during film formation, and oxygen concentration in a gas component.

The evaluation of the internal residual stress in the film of the formed adhesive layer 2 was performed by a cantilever method. The cantilever method (reference document is attached: journal of Vacuum Society of Japan J.VAC.Soc.JPN vol. 50, No 6.2007, P432) is a method of applying film forming process to a sheet having an already known mechanical characteristic, then fixing one end thereof and opening the other end thereof (to be free), and obtaining the internal stress of the film from a deformation direction and a deformation amount of the sheet. Here, whether the stress inside of the film was the compression stress or the tensile stress was judged and evaluated. The internal residual stress in the formed adhesive layer 2 mainly depends on a gas pressure and a film thickness during film formation. Therefore, an experiment of evaluating whether the stress of this film was the compression stress or the tensile stress was performed by previously setting the gas pressure and the film thickness under the same condition as that of preparing the sample, and based on this data, whether the internal residual stress of the adhesive layer 2 in each sample prepared under various different process conditions was the compression stress, tensile stress, or almost zero stress, was judged (evaluated).

Table 33 shows the evaluation results of the internal residual stress in the adhesive layer 2 formed of the sputtering film composed of niobium (Nb) of each sample, regarding typical multiple kinds of samples prepared under different process conditions, in accordance with the aforementioned judgment methods. Based on the evaluation results shown in this table 33, whether the internal residual stress of the adhesive layer 2 in each sample was any one of the types of the tensile stress, zero stress, or the compression stress was judged. A case shown in the second line of table 33 is given as an example as follows. When the gas in the film formation atmosphere in the sputtering step was set as argon (Ar) gas of 1.1 Pa, it was so judged that the internal residual stress in the adhesive layer 2 by sputtering was zero in a case that the film thickness was 15 nm, 20 nm, 60 nm, and the internal residual stress was the compression stress in a case that the film thickness was 120 nm, 300 nm, and 500 nm.

### (Experiment Result and Evaluation Result Using Each Sample)

(1) In a Case that the Metal Substrate is Aluminum (Al);

Table 34 arranges and shows the evaluation results of samples 101 to 107 as a group 1, in the surface-treated metal substrate having the lamination structure of the adhesive layer 2 and the bonding layer 3 on the surface of the metal substrate 1 as shown in FIG. 1, wherein the internal residual stress of the adhesive layer 2 is the tensile stress. Here, the sample number of each sample is given, for the convenience of identifying each sample, and it is a matter of course that some kind of meaning such as a preferential order is not given to its arrangement order and the number itself. However, an intended purpose in each experiment is focused, and each sample prepared and evaluated for the same purpose is collected in one group, and the number of this group is given to a head number of the sample numbers. For example, in a case of each sample of the group 1 (samples of sample numbers 101 to 107; called samples 101 to 107 hereinafter), this is the group 1, and therefore the number of the third digit of this sample number is 1, and as the number after second digit or after, the number showing its arrangement order is given, like 01, 02, 03 . . . . Namely, for example if the sample number is 103, this means that the sample is the third one of the group 1 (the same thing can be said for the table 35 and thereafter).

According to the results shown in this table 34, when the internal residual stress of the adhesive layer 2 was the tensile stress, it was confirmed that the solder bonding strength (expressed by D) was insufficient, irrespective of the film thickness of the adhesive layer 2. Also, even when the adhesive layer 2 was not provided (sample 101), the bonding strength (expressed by D) was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of other setting.

Table 35 shows the evaluation results of samples 201 to 205 as group 2 in the surface-treated metal substrate, with the adhesive layer 2 and the bonding layer 3 formed on the surface of the metal substrate 1 shown in FIG. 1, wherein the film thickness of the bonding layer 3 is made uniform so as to be 20 nm or more and the internal residual stress of the adhesive layer 2 is made uniform to be zero, and the film thickness of the adhesive layer 2 is variously changed.

From the results shown in this table 35, it was confirmed that the initial solder bonding strength was insufficient when the film thickness of the adhesive layer 2 was thin like 5 nm, and when it was thick like 250 nm. Further, it was confirmed that the wettability after application of strain had a tendency of decrease, with film thickness 200 nm taken as a boundary point, when the film thickness of the adhesive layer 2 was increased. Moreover, it was confirmed that the bonding strength after hydrogen test had a decrease tendency, as the film thickness of the adhesive layer 2 was increased.

Table 36 shows the evaluation results in the surface-treated metal substrate, with the adhesive layer 2 and the bonding layer 3 formed on the surface of the metal substrate 1 as shown in FIG. 1, when the internal residual stress of the adhesive layer is set to zero, and the film thickness of the adhesive layer 2 is set to 10 nm (group 3), 60 nm (group 4), 200 nm (group 5), and the film thickness of the bonding layer 3 is variously changed (10 nm, 15 nm, 60 nm, 120 nm, 200 nm) in a range from 10 nm to 200 nm.

From the results shown in this table 36, it was confirmed that when the bonding layer 3 was under 15 nm, the solder bonding strength was insufficient even if the film thickness of the adhesive layer 2 was variously changed in a range from 10 nm to 200 nm, and when the film thickness of the bonding layer 3 was 15 nm or more, excellent solder bonding strength and solder wettability could be achieved.

Further, according to the results of the samples of the group 4 and the group 5 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Table 37 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 10 nm (group 6), 60 nm (group 7), 200 nm and 300 nm (group 8), and the film thickness of the bonding layer 3 is variously changed (10 nm, 15 nm, 60 nm, 120 nm, 200 nm) in the range from 10 nm to 200 nm.

From the results shown in this table 37, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

Moreover, according to the results of the samples of the group 7 and the group 8 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Further, in a case of sample 806 of the group 8 in particular, the initial solder bonding strength was decreased, which was assumed to be caused by extremely thick film thickness 300 nm of the adhesive layer 2, compared with other case of the film thickness. This also shows that an excessively thick film thickness of the adhesive layer 2 is not desirable even if the film thickness of the bonding layer 3 is appropriate, and as a suitable film thickness of the adhesive layer 2, 200 nm or less is selected.

Table 38 shows the evaluation results in the surface-treated metal substrate, with the adhesive layer 2 and the bonding layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 9), made of tin (Sn) sputtering film (group 10), made of copper-60 wt % nickel (Cu-60 wt % Ni) sputtering film (group 11), and made of copper-20 wt % nickel (Cu-20 wt % Ni) sputtering film (group 12).

From the results shown in this table 38, it was confirmed that regarding all performance items excluding the solder bonding strength after hydrogen test, further improvement of its performance could be achieved, by setting the film thickness of the adhesive layer 2 in the range from 10 nm or more and 200 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 39 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 13), made of copper-5 wt % nickel (Cu-5 wt % Ni) sputtering film (group 14), made of copper-5 wt % nickel-10 wt % zinc (Cu-5 wt % Ni-10 wt % Zn) sputtering film (group 15), made of copper-10 wt % nickel-20 wt % zinc (Cu-10 wt % Ni-20 wt % Zn) sputtering film (group 16), and made of copper-20 wt % zinc (Cu-20 wt % Zn) sputtering film (group 17), as comparative examples.

From the results shown in this table 39, it was confirmed that regarding all performance items excluding the solder bonding strength after hydrogen test, further improvement of its performance could be achieved, by setting the film thickness of the adhesive layer 2 made of pure copper (Cu) in the range from 10 nm or more and 200 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 40 shows the evaluation results in the surface-treated metal substrate, with the adhesive layer 2 and the bonding layer 3 formed on the surface of the metal substrate 1 as shown in FIG. 2, when the bonding layer 3 is made of copper-40 wt % nickel (Cu-40 wt % Ni) uniformly and when the protective layer 4 is not provided (samples 1801 and 1802) and is made of copper-40 wt % zinc (Cu-40 wt % Zn) sputtering film (group 18) and made of copper-20 wt % zinc (Zn) (Cu-20 wt % Zn) sputtering film (group 19), as comparative examples.

From the results shown in this table 40, it was confirmed that regarding substantially all performance items excluding the solder bonding strength after hydrogen test, further improvement of its performance could be achieved, by setting the film thickness of the adhesive layer 2 in the range from 10 nm or more and 200 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 41 shows the evaluation results in the surface-treated metal substrate, with the adhesive layer 2 and the bonding layer 3 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 20), and made of copper-5 wt % zinc-10 wt % nickel (Cu-5 wt % Zn-10 wt % Ni) sputtering film (group 21), made of copper-10 wt % zinc-10 wt % nickel (Cu-10 wt % Zn-10 wt % Ni) sputtering film (group 22), and the bonding layer 3 is made of copper-10 wt % zinc (Cu-10 wt % Zn) sputtering film without nickel, and when the protective layer 4 is not provided (sample 2301) and is made of nickel (Ni) sputtering film (group 23), as comparative examples.

From the results shown in this table 41, it was confirmed that each kind of performance was substantially excellent as a whole, although some of them are slightly inferior to other structure and material setting explained based on the aforementioned tables 34 to 40, by using the material containing zinc (Zn) as a forming material of the bonding layer 3 and the protective layer 4. Further, the material cost can be reduced more than that of the aforementioned each case.

Also, particularly from the results of samples 2301 and 2302, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 2301), and the solder bonding strength was insufficient yet, even when the protective layer 4 was provided (in a case of the sample 2302).

When the results of the sample of the group 23 and the results of the samples of the groups 20, 21, 22 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 42 shows the evaluation results in the surface-treated metal substrate, with the adhesive layer 2 and the bonding layer 3 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when an oxygen concentration in the argon (Ar) gas used as atmosphere gas during sputtering film formation of these sputtering films is set to 0.05% and set to 0.005% (in either case, the oxygen intensity ratio X in a finished sample exceeds 0.02 (0.02<X)).

From the result shown in this table 42, it was confirmed that in a case of the metal substrate 1 made of pure aluminum (Al), when the concentration of the oxygen contained in an inert atmosphere gas during sputtering film formation was set to beyond 0.001% and the oxygen intensity ratio X in the finished sample was set to beyond 0.02, the initial solder bonding strength was insufficient, irrespective of the other structure and the setting of each kind of process condition.

(2) In a Case that the Metal Substrate is Stainless Steel (SUS);

Table 43 shows the evaluation results of samples 2501 to 2507 as group 25 in the surface-treated metal substrate, with the adhesive layer 2 and the bonding layer 3 formed on the surface of the metal substrate 1 as shown in FIG. 1, wherein the internal residual stress of the adhesive layer 2 is the tensile stress.

According to the result shown in this table 43, it was confirmed that when the internal residual stress of the adhesive layer 2 was the tensile stress, the bonding strength was insufficient (expressed by D), irrespective of the film thickness of the adhesive layer 2. Also, in a case of not providing the adhesive layer 2 (sample 2501), it was confirmed that the bonding strength was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of the other setting including the material of the metal substrate 1.

Table 44 shows the evaluation results in the surface-treated metal substrate, with the adhesive layer 2 and the bonding layer 3 formed on the surface of the metal substrate 1 as shown in FIG. 1, when the film thickness of the bonding layer 3 is set to 20 nm or more uniformly and the internal residual stress of the adhesive layer 2 is set to zero uniformly, and the film thickness of the adhesive layer 2 is variously changed.

From the result shown in this table 44, it was confirmed that the initial solder bonding strength was insufficient, when the film thickness of the adhesive layer 2 was thin like 5 nm, and when the film thickness of the adhesive layer 2 was thick like 250 nm. Further, it was confirmed that the wettability after application of strain had a tendency of decrease, with film thickness 200 nm taken as a boundary point, when the film thickness of the adhesive layer 2 was increased. Moreover, it was confirmed that the bonding strength after hydrogen test had a decrease tendency, as the film thickness of the adhesive layer 2 was increased.

Table 45 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to zero, and the film thickness of the adhesive layer 2 is set to 10 nm (group 27), 60 nm (group 28), 200 nm (group 29), and the film thickness of the bonding layer 3 is variously changed (10 nm, 15 nm, 60 nm, 120 nm, 200 nm) in a range from 10 nm to 200 nm.

From the result shown in this table 45, it was confirmed that when the bonding layer 3 was under 15 nm, the solder bonding strength was insufficient even when the film thickness of the adhesive layer 2 was changed in the range from 10 nm to 200 nm, and when the film thickness of the bonding layer 3 was 15 nm or more, excellent solder bonding strength and solder wettability could be achieved.

Further, according to the results of the group 28 and the group 29 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Table 46 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 10 nm (group 30), 60 nm (group 31), 200 nm and 300 nm (group 32), and the film thickness of the bonding layer 3 is variously changed (10 nm, 15 nm, 60 nm, 120 nm, 200 nm) in the range from 10 nm to 200 nm.

From the result sown in this table 46, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

Moreover, according to the results of the samples of the group 31 and the group 32 in particular, the decrease of the solder bonding strength after hydrogen test was confirmed, which was assumed to be caused by excessively thick film thickness of an entire body of the adhesive layer 2 and the bonding layer 3. This shows that when it is requested to overcome hydrogen embrittlement, the film thickness of the entire body is desirably set not to be excessively thick.

Further, in a case of sample 3206 of the group 32 according to the comparative example in particular, the initial solder bonding strength was decreased, which was assumed to be caused by extremely thick film thickness 300 nm of the adhesive layer 2, compared with other case of the film thickness. This also shows that the film thickness of the adhesive layer 2 was desirably set to 200 nm or less.

Table 47 shows the evaluation results in the surface-treated metal substrate, with the adhesive layer 2, the bonding layer 4, and the protective layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 33), made of tin (Sn) sputtering film (group 34), made of copper-60 wt % nickel (Cu-60 wt % Ni) sputtering film (group 35), and made of copper-20 wt % nickel (Cu-20 wt % Ni) sputtering film (group 36).

From the results shown in this table 47, it was confirmed that regarding all performance items excluding the solder bonding strength after hydrogen test, further improvement of its performance could be achieved, by setting the film thickness of the adhesive layer 2 in the range from 10 nm or more and 200 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 48 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 37), made of copper-5 wt % nickel (Cu-5 wt % Ni) sputtering film (group 38), made of copper-5 wt % nickel-10 wt % zinc (Cu-5 wt % Ni-10 wt % Zn) sputtering film (group 39), made of copper-10 wt % nickel-20 wt % zinc (Cu-10 wt % Ni-20 wt % Zn) sputtering film (group 40), and made of copper-20 wt % zinc (Cu-20 wt % Zn) sputtering film (group 41), as comparative examples.

From the results shown in this table 48, it was confirmed that regarding all performance items excluding the solder bonding strength after hydrogen test, further improvement of its performance could be achieved, by setting the film thickness of the adhesive layer 2 made of pure copper (Cu) in the range from 10 nm or more and 200 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 49 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-40 wt % nickel (Cu-40 wt % Ni) uniformly and when the protective layer 4 is not provided (samples 4201 and 4202) and is made of copper-40 wt % zinc (Cu-40 wt % Zn) sputtering film (group 42), and made of copper-20 wt % zinc (Zn) (Cu-20 wt % Zn) sputtering film (group 43), as comparative examples.

From the results shown in this table 49, it was confirmed that regarding all performance items excluding the solder bonding strength after hydrogen test, further improvement of its performance could be achieved, by setting the film thickness of the adhesive layer 2 in the range from 10 nm or more and 200 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 50 shows the evaluation results in the surface-treated metal substrate, with the adhesive layer 2, the bonding layer 3, and the protective layer 4 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 44), and made of copper-5 wt % zinc-10 wt % nickel (Cu-5 wt % Zn-10 wt % Ni) sputtering film (group 45), and made of copper-10 wt % zinc-10 wt % nickel (Cu-10 wt % Zn-10 wt % Ni) sputtering film (group 46), and the bonding layer 3 is made of copper-10 wt % zinc (Cu-10 wt % Zn) sputtering film without nickel, and when the protective layer 4 is not provided and is made of nickel (Ni) sputtering film (group 47), as comparative examples.

From the results shown in this table 82, it was confirmed that each kind of performance was sufficient, although some of them are slightly inferior to other structure and material setting explained based on the aforementioned tables 75 to 82, by using the material containing zinc (Zn) as a forming material of the bonding layer 3 and the protective layer 4. Further, the material cost can be reduced more than that of the aforementioned each case.

Also, particularly from the results of samples 4701 and 4702, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 4701), and the solder bonding strength was insufficient yet even when the protective layer 4 was provided (in a case of the sample 4702).

When the result of the sample of the group 47 and the results of the samples of the groups 44, 45, 46 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 51 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when the oxygen concentration in the argon (Ar) gas used as atmosphere gas during sputtering film formation of these sputtering films is set to 0.05% and set to 0.005% (in either case, the oxygen intensity ratio X in a finished sample exceeds 0.02 (0.02<X)).

From the result shown in this table 51, it was confirmed that when the concentration of the oxygen contained in an inert atmosphere gas during sputtering film formation was set to beyond 0.001% and the oxygen intensity ratio X in the finished sample was set to beyond 0.02, the initial solder bonding strength was insufficient, irrespective of the other structure and the setting of each kind of process condition.

(3) In a Case that the Metal Substrate is Titanium (Ti);

Table 52 shows the evaluation results as group 49 in the surface-treated metal substrate, with the adhesive layer 2 and the bonding layer 3 formed on the surface of the metal substrate 1 as shown in FIG. 1, when the internal residual stress of the adhesive layer 2 is the tensile stress.

Here, when the metal substrate 1 is a titanium (Ti) material, an influence of hydrogen on the adhesive layer 2 made of this titanium (Ti) coexists with an influence of hydrogen on the metal substrate 1 made of titanium (Ti) similarly. Therefore, it is actually difficult or impossible to exactly measure/evaluate the influence of hydrogen on the simple adhesive layer 2 only. Therefore, when the metal substrate 1 is titanium (Ti), the solder bonding strength after hydrogen test was not measured and evaluated.

According to the result shown in this table 52, it was confirmed that when the internal residual stress of the adhesive layer 2 was the tensile stress, the bonding strength was insufficient, irrespective of the film thickness of the adhesive layer 2. Also, in a case of not providing the adhesive layer 2 (sample 4901), it was confirmed that the bonding strength was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of the other setting including the material of the metal substrate 1.

Table 53 shows the evaluation results in the surface-treated metal substrate, with the adhesive layer 2 and the bonding layer 3 formed on the surface of the metal substrate 1 as shown in FIG. 1, when the film thickness of the bonding layer 3 is set to 20 nm or more uniformly and the internal residual stress of the adhesive layer 2 is set to zero uniformly, and the film thickness of the adhesive layer 2 is variously changed.

From the result shown in this table 53, it was confirmed that the initial solder bonding strength was insufficient, when the film thickness of the adhesive layer 2 was thin like 5 nm, and when the film thickness of the adhesive layer 2 was thick like 250 nm. Further, it was confirmed that the wettability after application of strain had a tendency of decrease, with film thickness 200 nm taken as a boundary point, when the film thickness of the adhesive layer 2 was increased.

Table 54 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to zero, and the film thickness of the adhesive layer 2 is set to 10 nm (group 51), 60 nm (group 52), 200 nm (group 53), and the film thickness of the bonding layer 3 is variously changed (10 nm, 15 nm, 60 nm, 120 nm, 200 nm) in a range from 10 nm to 200 nm.

From the result shown in this table 54, it was confirmed that when the bonding layer 3 was under 15 nm, the solder bonding strength was insufficient even when the film thickness of the adhesive layer 2 was changed in the range from 10 nm to 200 nm, and when the film thickness of the bonding layer 3 was 15 nm or more, excellent solder bonding strength and solder wettability could be achieved.

Table 55 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 10 nm (group 54), 60 nm (group 55), 200 nm and 300 nm (group 56), and the film thickness of the bonding layer 3 is variously changed (10 nm, 15 nm, 60 nm, 120 nm, 200 nm) in the range from 10 nm to 200 nm.

From the result sown in this table 55, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

In a case of the sample 5606 of group 56 according to the comparative example in particular, the decrease of the initial solder bonding strength was confirmed, which was assumed to be caused by excessively thick film thickness compared with other case of the film thickness. This also shows that the film thickness of the adhesive layer 2 is desirably set to 200 nm or less.

Table 56 shows the evaluation results in the surface-treated metal substrate, with the adhesive layer 2, the bonding layer 4, and the protective layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 57), made of tin (Sn) sputtering film (group 58), made of copper-60 wt % nickel (Cu-60 wt % Ni) sputtering film (group 59), and made of copper-20 wt % nickel (Cu-20 wt % Ni) sputtering film (group 60).

From the results shown in this table 56, it was confirmed that regarding all performance items excluding the solder bonding strength after hydrogen test, further improvement of its performance could be achieved, by setting the film thickness of the adhesive layer 2 in the range from 20 nm or more and 200 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 57 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 61), made of copper-5 wt % nickel (Cu-5 wt % Ni) sputtering film (group 62), made of copper-5 wt % nickel-10 wt % zinc (Cu-5 wt % Ni-10 wt % Zn) sputtering film (group 63), made of copper-10 wt % nickel-20 wt % zinc (Cu-10 wt % Ni-20 wt % Zn) sputtering film (group 64), and made of copper-20 wt % zinc (Cu-20 wt % Zn) sputtering film (group 65), as comparative examples.

From the results shown in this table 57, it was confirmed that regarding all performance items excluding the solder bonding strength after hydrogen test, further improvement of its performance could be achieved, by setting the film thickness of the adhesive layer 2 made of pure copper (Cu) in the range from 10 nm or more and 200 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 58 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-40 wt % nickel (Cu-40 wt % Ni) uniformly and when the protective layer 4 is not provided (samples 6601 and 6602) and is made of copper-40 wt % zinc (Cu-40 wt % Zn) sputtering film (group 66), and made of copper-20 wt % zinc (Zn) (Cu-20 wt % Zn) sputtering film (group 67), as comparative examples.

From the results shown in this table 58, it was confirmed that regarding all performance items (however, the solder bonding strength after hydrogen test is excluded because of impossibility to evaluate), further improvement of its performance could be achieved, by setting the film thickness of the adhesive layer 2 in the range from 10 nm or more and 200 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 59 shows the evaluation results in the surface-treated metal substrate, with the adhesive layer 2, the bonding layer 3, and the protective layer 4 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 68), and made of copper-5 wt % zinc-10 wt % nickel (Cu-5 wt % Zn-10 wt % Ni) sputtering film (group 69), and made of copper-10 wt % zinc-10 wt % nickel (Cu-10 wt % Zn-10 wt % Ni) sputtering film (group 70), and the bonding layer 3 is made of copper-10 wt % zinc (Cu-10 wt % Zn) sputtering film without nickel, and when the protective layer 4 is not provided and is made of nickel (Ni) sputtering film (group 71), as comparative examples.

From the results shown in this table 59, it was confirmed that each kind of performance was sufficient, although some of them are slightly inferior to other structure and material setting explained based on the aforementioned tables 52 to 58, by using the material containing zinc (Zn) as the forming material of the bonding layer 3 and the protective layer 4. Further, the material cost can be reduced more than that of the aforementioned each case.

Also, particularly from the results of samples 7101 and 7102, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 7101), and the solder bonding strength was insufficient yet even when the protective layer 4 was provided (in a case of the sample 7102).

When the result of the sample of the group 71 and the results of the samples of the groups 68, 69, 70 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 60 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when the oxygen concentration in the argon (Ar) gas used as atmosphere gas during sputtering film formation of these sputtering films is set to 0.05% and set to 0.005% (in either case, the oxygen intensity ratio X in a finished sample exceeds 0.02 (0.02<X)).

From the result shown in this table 60, it was confirmed that when the concentration of the oxygen contained in an inert atmosphere gas during sputtering film formation was set to 0.001% or more and the oxygen intensity ratio X in the finished sample was set beyond 0.02, the initial solder bonding strength was insufficient, irrespective of the other structure and the setting of each kind of process condition.

### (4) In a Case of Setting a Solder Layer Made of a Plating Film Instead of the Protective Layer;

The solder layer 5 was formed by an electroless plating method, after the surface-treated metal substrate having the structure shown in FIG. 1 was fabricated.

Table 61 shows the evaluation results of each kind of performance of the sample of the surface-treated metal substrate formed by electroless plating the solder layer 5.

In the sample of group 73, the metal substrate 1 was made of pure aluminum (Al) or stainless steel (SUS), or titanium (Ti), with the bonding layer 3 set to contain copper-10 wt % nickel (Cu-10 wt % Ni), and the solder layer 5 was formed thereon by the electroless plating method. The film thickness of this solder layer 5 was set to 1 μm or 5 μm.

In the sample of group 74, the metal substrate 1 was made of pure aluminum (Al) or stainless steel (SUS), or titanium (Ti), with the bonding layer 3 set to contain copper-10 wt % nickel (Cu-10 wt % Ni), and the solder layer 5 was formed thereon by the electroless plating method. The film thickness of the solder layer 5 was set to 1 μm or 5 μm.

In sample of group 75, the metal substrate 1 was made of an aluminum alloy (A5052), and the adhesive layer 3 was made of copper-10 wt % nickel (Cu-10 wt % Ni), and the solder layer 5 made of tin-9 wt % zinc (Sn-9 wt % Zn) was formed thereon by the electroless plating method. The film thickness of the solder layer 5 was set to 5 μm. In the sample of group 76, the metal substrate 1 made of the aluminum alloy (Al) or stainless steel (SUS) or titanium (Ti) was used, and pure copper (Cu) was used in the bonding layer 3, and the solder layer 5 made of nickel (Ni) was formed thereon by the electroless plating method. The film thickness of the solder layer 5 was set to 0.3 μm or 5 μm.

In the sample of group 77, the metal substrate 1 made of the aluminum alloy (Al) or stainless steel (SUS) or titanium (Ti) was used, and the bonding layer 3 was made of copper-10 wt % nickel-20 wt % zinc (Cu-10 wt % Ni-20 wt % Zn), and the solder layer 5 made of nickel (Ni) was formed thereon by the electroless plating method. The film thickness of the solder layer 5 was set to 0.3 μm or 5 μm.

In the sample of group 78, an aluminum alloy (A5052) was used in the metal substrate 1, and copper-10 wt % nickel (Cu-10 wt % Ni) was used in the bonding layer 3, and the solder layer 5 made of nickel (Ni) was formed thereon by the electroless plating method. The film thickness of the solder layer 5 was set to 0.3 μm or 5 μm.

The film thickness of the adhesive layer 2 was set to 20 nm in any one of the samples. Further, the film thickness of the bonding layer 3 was set to 60 nm in any one of the samples. Moreover, the internal residual stress of the adhesive layer 2 was set to the compression stress in all samples.

From the result shown in table 61, it was confirmed that the solder layer 5 by the electroless plating method could be formed, instead of the protective layer 4 made of the sputtering film, and by providing the solder layer 5 thus formed, it was confirmed that each kind of performance as the surface-treated metal substrate could be made excellent. Further, by forming the solder layer 5 by such a plating method, a thick solder layer 5 with film thickness set as the unit of μm could be formed, with good throughput. Therefore, further improvement of the solder bonding strength could be achieved, without inviting a higher manufacturing cost. Further, in addition, tin-silver (SN—Ag) and pure zinc (Zn), etc, can also be used as plating materials.

From the results as described above, a main essential matter is extracted and shows as follows.

The film thickness of the adhesive layer 2 is desirably set to 10 nm or more and 200 nm or less. When it is thinner than 10 nm, there is a high possibility that the solder wettability is insufficient. Reversely, when it is thicker than 200 nm, there is a high possibility that an adverse influence by hydrogen becomes stronger.

The film thickness of the bonding layer 3 is desirably set to 15 nm or more. When it is thinner than 15 nm, there is a high possibility that both of the solder wettability and solder bonding strength are insufficient. Also, when it is thicker than 200 nm, the bonding layer 3 has a tendency of being fragile to application of strain.

Further, copper-10 wt % nickel (Cu-10 wt % Ni) can be given as a typical material of the bonding layer 3, and particularly by adding nickel (Ni), the solder wettability is improved. However, even if pure copper (Cu) is selected without nickel, the excellent solder wettability and solder bonding strength can be obtained. Further, copper-40 wt % nickel (Cu-40 wt % Ni) is an upper limit of the content of nickel (Ni).

Further, by selecting copper-5 wt % zinc (Cu-5 wt % Zn), the solder wettability can be secured. Also, by selecting three elements composition of copper-5 wt % nickel-10 wt % Zn(Cu-5 wt % Ni-10 wt % Zn), both of the sacrificial protection effect by adding zinc (Zn), and the effect of improving the solder wettability by adding nickel (Ni) can be achieved.

Even if the film thickness of the protective layer 4 and the solder layer 5 are made thicker than 5 μm, it can be considered that there is no substantial demerit in the aspect of performance as the protective layer 4 itself, other than higher manufacturing cost including the material cost.

When nickel (Ni) simple body is used as the material of the protective layer 4, there is a possibility of higher manufacturing cost and material cost. However, the nickel protective layer 4 can be used without problem in the aspect of its performance.

Also, when copper-60 wt % nickel (Cu-60 wt % Ni) is used, there is no problem in the aspect of performance, and there is a merit that it is slightly more inexpensive than nickel (Ni) simple body.

Also, when copper-20 wt % nickel (Cu-20 wt % Ni) is used, there is a merit that it is more inexpensive than the nickel (Ni) simple body.

Also, when copper-5 wt % nickel (Cu-5 wt % Ni) is used and tin (Sn) is used, there is a merit that it is greatly more inexpensive than the nickel (Ni) simple body, without problem in the aspect of performance.

Also, when copper-5 wt % nickel-10 wt % Zn(Cu-5 wt % Ni-10 wt % Zn) is used, and copper-10 wt % nickel-20 wt % Zn(Cu-10 wt % Ni-20 wt % Zn) is used, there is a merit that a zinc (Zn) component functions as a sacrificial protection material, and other than this merit, there is also a merit that it contributes to strengthening the solder wettability.

Also, when copper-20 wt % zinc (Cu-20 wt % Zn) is used, there is a merit that the zinc (Zn) component functions as the sacrificial protection material, and contributes to reducing the manufacturing cost including the material cost. However, there is a possibility that the solder wettability is decreased in some cases.

Also, there is a merit in the copper-10 wt % nickel-40 wt % zinc (Cu-10 wt % Ni-40 wt % Zn), such that a large volume of zinc (Zn) components can be added, when the bonding layer 3 is requested to have a sufficient function as the sacrificial protection material.

In the surface-treated metal substrate according to the second embodiment and the second example of the present invention, the adhesive layer 2 is made of niobium (Nb). However, niobium (Nb) is a metal softer than titanium (Ti) and chromium (Cr). Accordingly, there are typical merits in forming the adhesive layer 2 using niobium (Nb) as follows. Namely, there is a least possibility of decrease of the solder wettability and the solder bonding strength even if treatment associated with application of strain is applied after sputtering film formation, with less abrasion of a press die used in a process such as a press molding process and a cutting process, when these processes are applied.

However, when a stainless steel (SUS)-based metal or titanium (Ti)-based metal substrate 1 is used, the metal substrate 1 itself is hard, and therefore the aforementioned characteristic of niobium (Nb) is apt to be obscure. Therefore, it can be assumed that the merit of using niobium (Nb) in the adhesive layer 2 can be evidently exhibited when the metal substrate 1 is made of a relatively softer material such as aluminum (Al)-based metal. However, regarding niobium (Nb), the material cost is likely to be increased more than the material cost of titanium (Ti) and chromium (Cr). Also, the adverse influence by hydrogen is likely to be increased more than a case of chromium (Cr).

Regarding the oxygen concentration in an atmosphere of forming the adhesive layer 2, it is desirable to intentionally reduce the oxygen concentration like 0.001% or less. For example, when the oxygen concentration is beyond 0.001%, the oxygen intensity ratio X of the finished adhesive layer 2 is also beyond 0.02, and there is a high possibility that the solder wettability and the solder bonding strength are decreased.

Then, by performing sputtering film formation in the film formation atmosphere with low oxygen concentration, it is desirable to set the oxygen intensity ratio X of the finished adhesive layer 2 to 0.02 or less by sputtering, when the metal substrate 1 is pure aluminum (Al) or stainless steel (SUS), or titanium (Ti).

When this oxygen intensity ratio X is beyond 0.02, there is a high possibility that the initial solder bonding strength is insufficient, irrespective of the other structure and the setting of the film thickness and each kind of process condition, etc.

However, here, it is confirmed by the inventors of the present invention by the following experiment and consideration therefore, that when the metal substrate 1 is an alloy containing magnesium (Mg) such as A5052, being a kind of an aluminum alloy, the oxygen intensity ratio X of the finished adhesive layer 2 is desirably set to 0.04 or less by sputtering.

Namely, the sample was prepared in the same setting as the setting in which the aluminum alloy (A5052) containing magnesium (Mg) was used as the material of the metal substrate 1 instead of pure aluminum (Al), and regarding all other structures and conditions of the experiment, pure aluminum (Al) was used as the material of the metal substrate 1. Then, by using this sample, the experiment was performed regarding a case that the oxygen intensity ratio X was set to 0.04 or less, and a case that the oxygen intensity ratio X was set to beyond 0.04, and its result was examined. However, the solder bonding intensity after hydrogen-treatment was omitted. Table 62, table 63, and table 64 arrange, sum-up, and show the results. Note that in these tables 62, 63, 64, in order to make it easy to correspond to the experiment using the metal substrate 1 made of pure aluminum (Al), the same sample number and group number are given to the samples experimented in the same setting as the setting in a case of using the metal substrate 1 made of pure aluminum (Al), as the sample number and the group number in a case of using the metal substrate 1 made of the aluminum alloy (A5052) containing magnesium (Mg) as described below.

From experiment results as shown in the table 62, table 63, and table 64, it was found that when the aluminum alloy (A5052) containing magnesium (Mg) was used in the metal substrate 1, each kind of performance of the finished samples of the examples and the finished samples of the comparative examples shows the same result as the result in a case of using pure aluminum in the metal substrate 1. However, particularly regarding the oxygen intensity ratio X in the adhesive layer 2, it was confirmed that both of the solder wettability and initial solder bonding property could be made excellent, in the same way as the case of using pure aluminum (Al) in the metal substrate 1, by setting it to 0.04 or less instead of setting it to 0.02 or less in a case of pure aluminum (Al). In contrast, when the oxygen intensity ratio X is set to beyond 0.04, it was confirmed that the initial solder boding strength was insufficient, irrespective of the other structure and the setting of the film thickness and each kind of process condition, etc, in the same way as the case of setting the oxygen intensity ratio X to beyond 0.02 in a case of using pure aluminum (Al) in the metal substrate 1.

Therefore, from such a result, it was found that the oxygen intensity ratio X of the finished adhesive layer 2 was set to 0.04 or less by sputtering, when the metal substrate 1 was made of an alloy containing magnesium (Mg) such as A5052, being a kind of the aluminum alloy.

### Third Example

Various surface-treated metal substrates as explained in the third embodiment were fabricated, with each kind of specification changed, and they were set as the samples of the third example. Further, the surface-treated metal substrate by a different specification and a manufacturing method from those of the third embodiment of the present invention was also separately fabricated, for comparison with the samples of the third example, and this surface-treated metal substrate was set as the sample of the comparative example. Then, by using these samples, the solder wettability and the bonding strength were respectively evaluated in each sample.

### (Preparation of the Sample)

Two kinds of aluminum (Al)-based metal and stainless steel-based metal substrates 1 were prepared, and the surface-treated metal substrate, with the adhesive layer 2 and the bonding layer 3 formed thereon by the manufacturing method and the structure described in the third embodiment was fabricated for each of the metal substrates 1, and each performance was evaluated.

A1050, being pure aluminum (Al) was given as a typical one of the aluminum (Al)-based metal. Also, as its variation, A5052 containing Mg was also prepared to conduct a similar experiment (this A5052 will be described later).

SUS301 was selected as the stainless steel-based material, and a plate-shaped material having a thickness of 0.15 mm was prepared, for each kind. No acid pickling treatment was applied to the surfaces of these metal base materials, and sputtering film formation was performed thereafter, in a state that the passivation film remained on the outermost surface.

A sputtering film formation process was performed by using a DC magnetron sputtering apparatus (Type: SH-350 by ULVAC, Inc.). Argon (Ar) gas with pressure of 0.3 Pa or more and 9 Pa or less was set as an atmosphere (film formation atmosphere; similar as follows) when each film was formed. DC electric power (applied energy) applied to a target material was suitably adjusted according to the kind of metal. Thickness control of each film was performed for each kind of metal, by adjusting a film formation time based on a previously measured average film forming rate. The adhesive layer 2, the bonding layer 3, and further the protective layer 4 and the solder layer 5 in some cases, were formed on the surface of the metal substrate 1 in this order, and such a series of film forming step was sequentially performed in the same chamber, so that oxygen (or air, etc, like an indoor atmosphere) was not mixed therein, even when the kind of the metal was changed. Purity of the argon (Ar) gas during film formation was set to the purity of 99.999% or more, and each film forming step was executed while continuously flowing a constant amount of flow rate, while maintaining the purity. The oxygen concentration in the film formation atmosphere at that time was assumed to be 0.001% or less.

Two kinds of gases of argon (Ar)+oxygen mixed gas, and pure argon (Ar) were prepared as the film formation atmosphere used when the sample of the comparative example was fabricated. An oxygen content in the film formation atmosphere was adjusted by adjusting a flow rate ratio.

### (An Experiment Method and an Evaluation Method of the Sample)

### (1) Evaluation of the Solder Wettability

Tin-0.7 wt % copper (Sn-0.7 wt % Cu) alloy, being Pb-free solder, was used as the solder material, and by a meniscograph method, the wettability test device (Type: manufacture No. 2015) by TAMURA Corporation was used, and a sample piece with width of 10 mm cut out from each sample was immersed into flux (Type H-728 of HOZAN), 2 mm of which was then immersed into a bath tub maintained to a temperature of 220° C. at an immersion rate of 2 mm/seconds. Then, a time (zero cross time) required from the aforementioned immersion of the sample piece until obtaining a so-called solder coating state, was measured. Then, based on this time, the solder wettability of each sample was evaluated based on a reference shown below. This evaluation method shows that the shorter the time is, the more excellent the solder wettability is.

A: under 5 seconds

B: 5 seconds or more, and under 7 seconds

C: 7 seconds or more, and under 10 seconds

D: 10 seconds or more

(The aforementioned A, B, C, D are described in the corresponding column of each table)
(2) Evaluation of the Initial Solder Bonding Strength (Initial Evaluation Immediately after Film Formation);

Regarding each sample piece with solder coating applied to the surface by the method described in the aforementioned (1), bending was repeatedly performed with a bending diameter of 10 mm, and the number of times of bending until a solder coating film was peeled off from the surface was counted, and thereby the bonding strength was counted. In this evaluation method, the bending was repeatedly performed until five times, to evaluate the bonding strength based on the reference described below.

A: Not peeled-off even in 5 times bending

B: Peeled-off in 3 to 4 times bending

C: Not peeled-off until first bending but peeled-off in second bending

D: Peeled-off before bending and cannot be evaluated due to a bonding failure state

(The aforementioned A, B, C, D are described in the corresponding column of each table)
(3) Evaluation of the Wettability after Application of Strain;

Bending strain and tensile strain were applied to each sample. First, the bending strain was applied. Specifically, the bending strain was applied four numbers of times, in a method of winding the sample around a pipe having a diameter of 15 nm (corresponding to a film thickness/diameter=0.15/15=0.01→1% in strain equivalent). In the second application, the sample was turned back after the first bending was applied, so that a tensile strain applied surface (outer surface of the plate material) was replaced with a compression strain applied surface (inner surface of the plate material). Then, in the third application also, the sample was similarly turned back, and the bending was performed at the same position of the sample as that of the first bending. After the third bending, the sample was turned back, and the fourth bending was performed at the same position of the sample as that of the second bending. After the fourth bending, the tensile stress was applied, and after an elongation amount of the sample was about 10%, the sample was released from this tensile stress and the application of strain was completed. Thereafter, the test of the solder wettability of each sample was conducted based on similar technique and reference as those of the aforementioned (2), and the solder wettabiltiy of each sample was evaluated.

(4) Evaluation of the Solder Bonding Strength after a Hydrogen Pressurization Test;

In order to examine a hydrogen embrittlement characteristic of each sample, solder-coated each sample was sealed in a hydrogen (H) gas atmosphere environment of 1 MPa·80° C. for 24 hours, and thereafter the bonding strength of each sample was evaluated based on the technique and the reference similar to those of the aforementioned (2).

### (5) Measurement of Oxygen Intensity Ratio X;

The oxygen content concentration of the material in the interface (about 5 nm in thickness) between the adhesive layer 2 and the bonding layer 3 was measured as the oxygen intensity ratio X by a spectroscopic analytical method. However, the interface (about 5 nm in thickness) between the metal substrate 1 and the adhesive layer 2, and the outermost surface (about 5 nm in thickness) of the bonding layer 3 were excluded from the measurement. Specifically, an X-ray photoelectron spectroscopy (XPS) was used to perform argon etching with 2 nm resolution, and obtain a peak value of the oxygen intensity ratio X defined in the following formula, in the vicinity of the interface between the adhesive layer 2 and the bonding layer 3.

Oxygen intensity ratio X=oxygen intensity/{intensity of oxygen (O)+intensity of chromium (Cr) constituting the adhesive layer 2+intensity of copper (Cu)+intensity of nickel (Ni) and zinc (Zn)}

Then, when the value of the oxygen intensity ratio X satisfies X≦0.02 as a result of the oxygen content concentration measured by the photoelectron spectroscopy, this value was set to B as the value assumed to be suitable for the process condition of the third example of the present invention, and in other case, this value was set to D as the value out of the process condition of the third example of the present invention.

(The aforementioned B, D are described in the corresponding column of each table)

### (6) Evaluation of the Internal Residual Stress of the Adhesive Layer;

The internal residual stress after forming the adhesive layer 2 is generally varied widely from the tensile stress to the compression stress, in accordance with various process conditions such as material of the adhesive layer 2, film thickness, gas pressure during film formation, and oxygen concentration in a gas component.

The evaluation of the internal residual stress in the film of the formed adhesive layer 2 was performed by a cantilever method. The cantilever method (reference document is attached: journal of Vacuum Society of Japan J.VAC.Soc.JPN vol. 50, No 6.2007, P432) is a method of applying film forming process to a sheet having an already known mechanical characteristic, then fixing one end thereof and opening the other end thereof (to be free), and obtaining the internal stress of the film from a deformation direction and a deformation amount of the sheet. Here, whether the stress inside of the film was the compression stress or the tensile stress was judged and evaluated. The internal residual stress in the formed adhesive layer 2 mainly depends on a gas pressure and a film thickness during film formation. Therefore, an experiment of evaluating whether the stress of this film was the compression stress or the tensile stress was performed by previously setting the gas pressure and the film thickness under the same condition as that of preparing the sample, and based on this data, whether the internal residual stress of the adhesive layer 2 in each sample prepared under various different process conditions was the compression stress, tensile stress, or almost zero stress, was judged (evaluated).

Table 65 shows the evaluation results of the internal residual stress in the adhesive layer 2 of each sample, regarding typical multiple kinds of samples prepared under different process conditions, in accordance with the aforementioned judgment methods. Based on the evaluation results shown in this table 65, whether the internal residual stress of the adhesive layer 2 in each sample was any one of the types of the tensile stress, zero stress, or the compression stress was judged. A case shown in the second line of table 65 is given as an example as follows. When the gas in the film formation atmosphere in the sputtering step was set as argon (Ar) gas of 1.2 Pa, it was so judged that the internal residual stress in the adhesive layer 2 by sputtering was zero in a case that the film thickness was 15 nm, 20 nm, 60 nm, and the internal residual stress was the compression stress in a case that the film thickness was 120 nm, 300 nm, and 500 nm.

(Experiment Result and Evaluation Result Using Each Sample)

(1) In a Case that the Metal Substrate is Aluminum (Al);
Table 66 shows the evaluation results of samples 101 to 107 as a group 1, in the surface-treated metal substrate, with the adhesive layer 2 and the bonding layer 3 formed on the surface of the metal substrate 1 as shown in FIG. 1, wherein the internal residual stress of the adhesive layer 2 is the tensile stress. Here, the sample number of each sample is given, for the convenience of identifying each sample, and it is a matter of course that some kind of meaning such as a preferential order is not given to its arrangement order and the number itself. However, an intended purpose in each experiment is focused, and each sample prepared and evaluated for the same purpose is collected in one group, and the number of this group is given to a head number of the sample numbers. For example, in a case of each sample of the group 1 (samples of sample numbers 101 to 107; called samples 101 to 107 hereinafter), this is the group 1, and therefore the number of the third digit of this sample number is 1, and as the number after second digit or after, the number showing its arrangement order is given, like 01, 02, 03 . . . . Namely, for example if the sample number is 103, this means that the sample is the third one of the group 1 (the same thing can be said for the table 67 and thereafter).

According to the results shown in this table 66, when the internal residual stress of the adhesive layer 2 was the tensile stress, it was confirmed that the solder bonding strength (expressed by D) was insufficient, irrespective of the film thickness of the adhesive layer 2. Also, even when the adhesive layer 2 was not provided (sample 101), the bonding strength (expressed by D) was insufficient.

From this result, in a case of the surface-treated metal substrate, with the adhesive layer 2 and the bonding layer 3 formed on the surface of the metal substrate 1 as shown in FIG. 1, it was confirmed that when the internal residual stress of the adhesive layer 2 was the tensile stress, the solder bonding strength was insufficient, irrespective of other setting such as setting the thickness of the adhesive layer 2 to 10 nm or more.

Table 67 shows the evaluation results of samples 201 to 205 as group 2 in the surface-treated metal substrate, with the adhesive layer 2 and the bonding layer 3 formed on the surface of the metal substrate 1 shown in FIG. 1, wherein the film thickness of the bonding layer 3 is made uniform so as to be 20 nm or more and the internal residual stress of the adhesive layer 2 is made uniform to be zero, and the film thickness of the adhesive layer 2 is variously changed.

From the results shown in this table 67, it was confirmed that the initial solder bonding strength was insufficient when the film thickness of the adhesive layer 2 was thin like 5 nm, and when it was thick like 250 nm. Further, it was confirmed that the wettability after application of strain had a tendency of decrease, with film thickness 200 nm taken as a boundary point, when the film thickness of the adhesive layer 2 was increased. Moreover, it was confirmed that the bonding strength after hydrogen test had a decrease tendency, as the film thickness of the adhesive layer 2 was increased.

Table 68 shows the evaluation results in the surface-treated metal substrate, with the adhesive layer 2 and the bonding layer 3 formed on the surface of the metal substrate 1 as shown in FIG. 1, when the internal residual stress of the adhesive layer is set to zero, and the film thickness of the adhesive layer 2 is set to 10 nm (group 3), 120 nm (group 4), 500 nm (group 5), and the film thickness of the bonding layer 3 is variously changed (10 nm, 15 nm, 60 nm, 120 nm, 500 nm) in a range from 10 nm to 500 nm.

From the results shown in this table 68, it was confirmed that when the bonding layer 3 was under 15 nm, the solder bonding strength was insufficient even if the film thickness of the adhesive layer 2 was variously changed in a range from 10 nm to 500 nm, and when the film thickness of the bonding layer 3 was 15 nm or more, excellent solder bonding strength and solder wettability could be achieved.

Further, according to the results of the samples of the group 4 and the group 5 in particular, the decrease of the solder bonding strength after hydrogen test was not generated, provided that the film thickness of the adhesive layer 2 was 500 nm or less.

Table 69 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 10 nm (group 6), 120 nm (group 7), and 500 nm, and the film thickness of the bonding layer 3 is variously changed (10 nm, 15 nm, 60 nm, 120 nm, 200 nm) in the range from 10 nm to 200 nm.

From the results shown in this table 69, it was confirmed that the solder wettability and the solder bonding strength were C or more (to B, A) when the internal residual stress of the adhesive layer 2 was set to the compression stress, and the film thickness of the bonding layer 3 was set to 15 nm or more. Further, it was also confirmed that the wettability after application of strain was excellent.

Further, it was confirmed that the solder wettability was excellent when the thickness of the adhesive layer 2 was within the range from 10 to 500 nm. Moreover, the initial bonding strength was also substantially excellent, when the thickness of the adhesive layer 2 was set in this range.

Further, it was confirmed that the solder bonding strength after hydrogen test was not substantially changed from that of initial time.

Table 70 shows the evaluation results in the surface-treated metal substrate, with the adhesive layer 2 and the bonding layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 9), made of tin (Sn) sputtering film (group 10), made of copper-60 wt % nickel (Cu-60 wt % Ni) sputtering film (group 11), and made of copper-20 wt % nickel (Cu-20 wt % Ni) sputtering film (group 12).

From the results shown in this table 70, it was confirmed that regarding all performance items, further improvement of its performance could be achieved, by setting the film thickness of the adhesive layer 2 in the range from 10 nm or more and 500 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 71 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 13), made of copper-5 wt % nickel (Cu-5 wt % Ni) sputtering film (group 14), made of copper-5 wt % nickel-10 wt % zinc (Cu-5 wt % Ni-10 wt % Zn) sputtering film (group 15), made of copper-10 wt % nickel-20 wt % zinc (Cu-10 wt % Ni-20 wt % Zn) sputtering film (group 16), and made of copper-20 wt % zinc (Cu-20 wt % Zn) sputtering film (group 17), as comparative examples.

From the results shown in this table 71, it was confirmed that regarding all performance items, further improvement of its performance could be achieved, by setting the film thickness of the adhesive layer 2 made of pure copper (Cu) in the range from 10 nm or more and 500 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 72 shows the evaluation results in the surface-treated metal substrate, with the adhesive layer 2 and the bonding layer 3 formed on the surface of the metal substrate 1 as shown in FIG. 2, when the bonding layer 3 is made of copper-40 wt % nickel (Cu-40 wt % Ni) uniformly and when the protective layer 4 is not provided (samples 1801 and 1802) and is made of copper-40 wt % zinc (Cu-40 wt % Zn) sputtering film (group 18), and made of copper-20 wt % zinc (Zn) (Cu-20 wt % Zn) sputtering film (group 19), as comparative examples.

From the results shown in this table 72, it was confirmed that regarding substantially all performance items, further improvement of its performance could be achieved, by setting the film thickness of the adhesive layer 2 in the range from 10 nm or more and 500 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 73 shows the evaluation results in the surface-treated metal substrate, with the adhesive layer 2 and the bonding layer 3 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 20), and made of copper-5 wt % zinc-10 wt % nickel (Cu-5 wt % Zn-10 wt % Ni) sputtering film (group 21), made of copper-10 wt % zinc-10 wt % nickel (Cu-10 wt % Zn-10 wt % Ni) sputtering film (group 22), and the bonding layer 3 is made of copper-10 wt % zinc (Cu-10 wt % Zn) sputtering film without nickel, and when the protective layer 4 is not provided (sample 2301) and is made of nickel (Ni) sputtering film (group 23), as comparative examples.

From the results shown in this table 73, it was confirmed that each kind of performance was substantially excellent as a whole, although some of them are slightly inferior to other structure and material setting explained based on the aforementioned tables 66 to 72, by using the material containing zinc (Zn) as a forming material of the bonding layer 3 and the protective layer 4. Further, the material cost can be reduced more than that of the aforementioned each case.

Also, particularly from the results of samples 2301 and 2302, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 2301), and the solder bonding strength was insufficient yet, even when the protective layer 4 was provided (in a case of the sample 2302).

When the results of the sample of the group 23 and the results of the samples of the groups 20, 21, 22 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 74 shows the evaluation results in the surface-treated metal substrate, with the adhesive layer 2 and the bonding layer 3 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and when an oxygen concentration in the argon (Ar) gas used as atmosphere gas during sputtering film formation of these sputtering films is set to 0.05%, being beyond 0.001%, and set to 0.005% (in either case, the oxygen intensity ratio X in a finished sample exceeds 0.02 (0.02<X)).

From the result shown in this table 74, it was confirmed that in a case of the metal substrate 1 made of pure aluminum (Al), when the concentration of the oxygen contained in an inert atmosphere gas during sputtering film formation was set to beyond 0.001% and the oxygen intensity ratio X in the finished sample was set to beyond 0.02, the initial solder bonding strength was insufficient, irrespective of the other structure and the setting of each kind of process condition.

(2) In a Case that the Metal Substrate is Stainless Steel (SUS);

Table 75 shows the evaluation results of samples 2501 to 2507 as group 25 in the surface-treated metal substrate, with the adhesive layer 2 and the bonding layer 3 formed on the surface of the metal substrate 1 as shown in FIG. 1, wherein the internal residual stress of the adhesive layer 2 is the tensile stress.

According to the result shown in this table 75, it was confirmed that when the internal residual stress of the adhesive layer 2 was the tensile stress, the bonding strength was insufficient (expressed by D), irrespective of the film thickness of the adhesive layer 2. Also, in a case of not providing the adhesive layer 2 (sample 2501), it was confirmed that the bonding strength was insufficient.

From this result, in a case of the surface-treated metal substrate, with the adhesive layer 2 and the bonding layer 3 formed on the surface of the metal substrate 1 as shown in FIG. 1, it was confirmed that when the adhesive layer 2 does not exist at all or when the internal residual stress of the adhesive layer 2 was the tensile stress, the solder bonding strength was insufficient, irrespective of the other setting including the material of the metal substrate 1.

Table 76 shows the evaluation results in the surface-treated metal substrate, with the adhesive layer 2 and the bonding layer 3 formed on the surface of the metal substrate 1 as shown in FIG. 1, when the film thickness of the bonding layer 3 is set to 20 nm or more uniformly and the internal residual stress of the adhesive layer 2 is set to zero uniformly, and the film thickness of the adhesive layer 2 is variously changed.

From the result shown in this table 76, it was confirmed that the initial solder bonding strength was insufficient, when the film thickness of the adhesive layer 2 was thin like 5 nm, and when the film thickness of the adhesive layer 2 was thick like 550 nm. Further, it was confirmed that the wettability after application of strain had a tendency of decrease, with film thickness 500 nm taken as a boundary point, when the film thickness of the adhesive layer 2 was increased. Moreover, it was confirmed that the bonding strength after hydrogen test had a decrease tendency, as the film thickness of the adhesive layer 2 was increased.

Table 77 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to zero, and the film thickness of the adhesive layer 2 is set to 10 nm (group 27), 120 nm (group 28), 500 nm (group 29), and the film thickness of the bonding layer 3 is variously changed (10 nm, 15 nm, 60 nm, 120 nm, 200 nm) in a range from 10 nm to 200 nm.

From the result shown in this table 77, it was confirmed that when the bonding layer 3 was under 15 nm, the solder bonding strength was insufficient even when the film thickness of the adhesive layer 2 was changed in the range from 10 nm to 500 nm, and when the film thickness of the bonding layer 3 was 15 nm or more, excellent solder bonding strength and solder wettability could be achieved. However, according to the results of the group 29, wherein the film thickness of the bonding layer 3 was set to 500 nm, the wettability after application of strain was greatly decreased.

Further, the solder bonding strength after hydrogen test was not decreased, and it was confirmed that the initial solder bonding strength was substantially maintained.

Table 78 shows the evaluation results in the surface-treated metal substrate, with the adhesive layer 2 and the bonding layer 3 formed on the surface of the metal substrate 1 as shown in FIG. 1, when the internal residual stress of the adhesive layer 2 is set to the compression stress uniformly, and the film thickness of the adhesive layer 2 is set to 10 nm (group 30), 120 nm (group 31), 500 nm (group 32), and the film thickness of the bonding layer 3 is variously changed (10 nm, 15 nm, 60 nm, 120 nm, 200 nm) in the range from 10 nm to 200 nm.

From the result sown in this table 78, it was confirmed that the solder wettability and the solder bonding strength were C or more (to B, A) when the internal residual stress of the adhesive layer 2 was set to the compression stress, and the film thickness of the bonding layer 3 was set to 15 nm or more.

The solder bonding strength after hydrogen test was not decreased.

Moreover, according to the results of the samples of the group 32 according to the comparative example in particular, the decrease of the wettability after application of strain was confirmed, which was assumed to be caused by excessively thick film thickness of the adhesive layer 2. This shows that it can be considered desirable to set the film thickness of the adhesive layer 2 to 500 nm or less.

Table 79 shows the evaluation results in the surface-treated metal substrate, with the adhesive layer 2, the bonding layer 4, and the protective layer 4 formed on the surface of the metal substrate 1 as shown in FIG. 2, when the bonding layer 3 is made of copper-10 wt % nickel (Cu-10 wt % Ni) uniformly, and the protective layer 4 is made of nickel (Ni) sputtering film (group 33), made of tin (Sn) sputtering film (group 34), made of copper-60 wt % nickel (Cu-60 wt % Ni) sputtering film (group 35), and made of copper-20 wt % nickel (Cu-20 wt % Ni) sputtering film (group 36).

From the results shown in this table 79, it was confirmed that regarding all performance items, further improvement of its performance could be achieved, by setting the film thickness of the adhesive layer 2 in the range from 10 nm or more and 500 nm or less, setting the film thickness of the bonding layer 3 made of copper-10 wt % nickel (Cu-10 wt % Ni) to 15 nm or more, setting the internal residual stress of the adhesive layer 2 to zero or the compression stress, and providing the protective layer 4 having the aforementioned materials (composition).

Table 80 shows the evaluation results of each sample in the surface-treated metal substrate, with the adhesive layer 2, the bonding layer 3, and the protective layer 4 formed on the surface of the metal substrate 1 as shown in FIG. 2, when the bonding layer 3 is made of pure copper (Cu) uniformly and when the protective layer 4 is not provided and is made of copper-20 wt % nickel (Cu-20 wt % Ni) sputtering film (group 37), made of copper-5 wt % nickel (Cu-5 wt % Ni) sputtering film (group 38), made of copper-5 wt % nickel-10 wt % zinc (Cu-5 wt % Ni-10 wt % Zn) sputtering film (group 39), made of copper-10 wt % nickel-20 wt % zinc (Cu-10 wt % Ni-20 wt % Zn) sputtering film (group 40), and made of copper-20 wt % zinc (Cu-20 wt % Zn) sputtering film (group 41), as comparative examples.

From the results shown in this table 80, it was confirmed that regarding all performance items, further improvement of its performance could be achieved, by setting the film thickness of the adhesive layer 2 made of pure copper (Cu) in the range from 10 nm or more and 500 nm or less, setting the film thickness of the bonding layer 3 to 15 nm or more, setting the internal residual stress of the adhesive layer 2 to zero or the compression stress, and providing the protective layer 4 having the aforementioned materials (composition).

Further, by using pure copper (Cu) at a lower cost than that of copper-nickel (Cu—Ni)-based metal as the material of the bonding layer 3, an overall manufacturing cost including the material cost can be reduced, without decrease of the performance.

Table 81 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-40 wt % nickel (Cu-40 wt % Ni) uniformly and when the protective layer 4 is not provided (samples 4201 and 4202) and is made of copper-40 wt % zinc (Cu-40 wt % Zn) sputtering film (group 42), and made of copper-20 wt % zinc (Zn) (Cu-20 wt % Zn) sputtering film (group 43), as comparative examples.

From the results shown in this table 81, it was confirmed that regarding all performance items, further improvement of its performance could be achieved, by setting the film thickness of the adhesive layer 2 in the range from 10 nm or more and 500 nm or less, setting the film thickness of the bonding layer 3 made of the aforementioned materials to 15 nm or more, setting the internal residual stress of the adhesive layer 2 to zero or the compression stress, and providing the protective layer 4 having the aforementioned materials (composition).

Further, by setting the bonding layer 3 made of copper-40 wt % nickel (Cu-40 wt % Ni), further improvement of the solder wettability can be achieved, although the material cost is increased, compared with a case of using pure copper (Cu).

Moreover, by using a copper-zinc (Cu—Zn)-based alloy containing zinc (Zn) at a lower material cost than that of copper-nickel (Cu—Ni)-based metal as the material of the protective layer 4, the overall manufacturing cost including the material cost can be reduced, without decrease of the performance.

Table 82 shows the evaluation results in the surface-treated metal substrate, with the adhesive layer 2, the bonding layer 3, and the protective layer 4 formed on the surface of the metal substrate 1 as shown in FIG. 2, when the protective layer 4 is made of a copper-10 wt % nickel-40 wt % zinc (Cu-10 wt % Ni-40 wt % Zn) alloy and the bonding layer 3 is made of copper-5 wt % zinc (Cu-5 wt % Zn) sputtering film (group 44), and made of copper-5 wt % zinc-10 wt % nickel (Cu-5 wt % Zn-10 wt % Ni) sputtering film (group 45), and made of copper-10 wt % zinc-10 wt % nickel (Cu-10 wt % Zn-10 wt % Ni) sputtering film (group 46), and the bonding layer 3 is made of copper-10 wt % zinc (Cu-10 wt % Zn) sputtering film without nickel, and when the protective layer 4 is not provided and is made of nickel (Ni) sputtering film (group 47) as comparative examples.

From the results shown in this table 82, it was confirmed that each kind of performance was substantially excellent excluding the solder wettability after application of strain, although some of them are slightly inferior to other structure and material setting explained based on the aforementioned tables 75 to 82, by using the material containing zinc (Zn) as a forming material of the bonding layer 3 and the protective layer 4. Further, the material cost can be reduced more than that of the aforementioned each case.

Also, particularly from the results of samples 4701 and 4702, it was confirmed that when the bonding layer 3 was made of a material containing 10 wt % or more zinc (Zn) without nickel (Ni), although the solder wettability was substantially excellent, the solder bonding strength was insufficient when there was no protective layer 4 (in a case of the sample 4701), and the solder bonding strength was insufficient yet even when the protective layer 4 was provided (in a case of the sample 4702).

When the result of the sample of the group 47 and the results of the samples of the groups 44, 45, 46 were considered, it was found that by adding nickel (Ni) of about 10 wt % to the material of the bonding layer 3, the solder bonding strength could be improved more than a case of no nickel (Ni), and zinc (Zn) could be added up to about 10 wt %.

Table 83 shows the evaluation results in the surface-treated metal substrate, with the adhesive layer 2, the bonding layer 3, and the protective layer 4 formed on the surface of the metal substrate 1 as shown in FIG. 2, when the bonding layer 3 is made of copper-10 wt % nickel (Cu-10 wt % Ni), and the protective layer 4 is made of either one of the nickel (Ni) sputtering film or copper-40 wt % nickel (Cu-40 wt % Ni) sputtering film, and the oxygen concentration in the argon (Ar) gas used as atmosphere gas during sputtering film formation of these sputtering films is set to 0.05%, being beyond 0.01%, and set to 0.005% (in either case, the oxygen intensity ratio X in a finished sample exceeds 0.02 (0.02<X)).

From the result shown in this table 83, it was confirmed that when the concentration of the oxygen contained in an inert atmosphere gas during sputtering film formation was set to beyond 0.001% and the oxygen intensity ratio X in the finished sample was set to beyond 0.02, the initial solder bonding strength was insufficient, irrespective of the other structure and the setting of each kind of process condition.

### (3) In a Case of Setting a Solder Layer Made of a Plating Film Instead of the Protective Layer;

The solder layer 5 was formed by an electroless plating method, after the surface-treated metal substrate having the structure shown in FIG. 1 was fabricated.

Table 84 shows the evaluation results of each kind of performance of the sample of the surface-treated metal substrate formed by applying electroless plating to the solder layer 5.

Three kinds of pure aluminum (Al), stainless steel (SUS), and titanium (Ti) were prepared as the metal substrate 1.

Then, the adhesive layer 2 was formed on the surface of the metal substrate 1, and the bonding layer 3 was formed on this surface by sputtering, and the solder layer 5 was formed on the surface of the bonding layer 3 by the electroless plating method, instead of the protective layer 4 made of the aforementioned sputtering film. The results are shows and shown in table 84.

In the sample of group 49, the bonding layer 3 was made of copper-10 wt % nickel (Cu-10 wt % Ni), and the solder layer 5 was made of tin (Sn). The film thickness of the adhesive layer 2 was set to 20 nm, and the film thickness of the bonding layer 3 was set to 60 nm, and the film thickness of the solder layer 5 was set to 1 μm or 5 μm. The adhesive layer 2 has the compression stress.

In the sample of group 50, the bonding layer 3 was made of copper-10 wt % nickel-20 wt % zinc (Cu-10 wt % Ni-20 wt % Zn), and the solder layer 5 was made of tin (Sn). The film thickness of the adhesive layer 2 was set to 20 nm, the film thickness of the bonding layer 3 was set to 60 nm, and the film thickness of the solder layer 5 was set to 1 μm or 5 μm. The adhesive layer 2 has the compression stress.

In the sample of group 51, the bonding layer 3 was made of copper-40 wt % nickel (Cu-40 wt % Ni), and the solder layer 5 was made of tin (Sn). The film thickness of the adhesive layer 2 was set to 20 nm, the film thickness of the bonding layer 3 was set to 60 nm, and the film thickness of the solder layer 5 was set to 5 μm. The adhesive layer 2 has zero compression stress.

In the sample of group 52, the bonding layer 3 was made of copper-40 wt % nickel (Cu-40 wt % Ni), and the solder layer 5 was made of tin-9 wt % zinc (Sn-9 wt % Zn). The film thickness of the adhesive layer 2 was set to 20 nm, the film thickness of the bonding layer 3 was set to 60 nm, and the film thickness of the solder layer 5 was set to 5 μm. The adhesive layer 2 has zero compression stress.

In the sample of group 53, the bonding layer 3 was made of copper-40 wt % nickel (Cu-40 wt % Ni), and the solder layer 5 was made of tin-5 wt % bismuth (Sn-9 wt % Bi). The film thickness of the adhesive layer 2 was set to 20 nm, the film thickness of the bonding layer 3 was set to 60 nm, and the film thickness of the solder layer 5 was set to 5 μm. The adhesive layer 2 has zero compression stress.

In the sample of group 54, the bonding layer 3 was made of copper-40 wt % nickel (Cu-40 wt % Ni), and the solder layer 5 was made of tin-9 wt % silver (Sn-1 wt % Ag). The film thickness of the adhesive layer 2 was set to 20 nm, the film thickness of the bonding layer 3 was set to 60 nm, and the film thickness of the solder layer 5 was set to 5 μm. The adhesive layer 2 has zero compression stress.

In the sample of group 55, only one kind of aluminum alloy (A5052) was used in the metal substrate 1, and the bonding layer 3 was made of copper-10 wt % nickel (Cu-10 wt % Ni), and the solder layer 5 was made of tin-9 wt % zinc (Sn-9 wt % Zn). The film thickness of the adhesive layer 2 was set to 20 nm, the film thickness of the bonding layer 3 was set to 60 nm, and the film thickness of the solder layer 5 was set to 1 μm or 5 μm. The adhesive layer 2 has the compression stress.

In the sample of group 56, the bonding layer 3 was made of copper (Cu), and the solder layer 5 was made of nickel (Ni). The film thickness of the adhesive layer 2 was set to 20 nm, the film thickness of the bonding layer 3 was set to 60 nm, and the film thickness of the solder layer 5 was set to 0.3 μm or 5 μm. The adhesive layer 2 has the compression stress.

In the sample of group 57, the bonding layer 3 was made of copper-10 wt % nickel-20 wt % zinc (Cu-10 wt % Ni-20 wt % Zn), and the solder layer 5 was made of nickel (Ni). The film thickness of the adhesive layer 2 was set to 20 nm, the film thickness of the bonding layer 3 was set to 60 nm, and the film thickness of the solder layer 5 was set to 0.3 μm or 5 μm. The adhesive layer 2 has the compression stress.

In the sample of group 58, the bonding layer 3 was made of copper (Cu), and the solder layer 5 was made of zinc (Zn). The film thickness of the adhesive layer 2 was set to 20 nm or 60 nm, the film thickness of the bonding layer 3 was set to 15 nm or 60 nm, and the film thickness of the solder layer 5 was set to 0.3 μm or 5 μm. The adhesive layer 2 has the compression stress.

In the sample of group 59, the bonding layer 3 was made of copper-40 wt % nickel (Cu-40 wt % Ni), and the solder layer 5 was made of copper (Cu). The film thickness of the adhesive layer 2 was set to 20 nm, the film thickness of the bonding layer 3 was set to 60 nm, and the film thickness of the solder layer 5 was set to 0.3 μm. The adhesive layer 2 has zero compression stress.

In the sample of group 60, only one kind of aluminum alloy (A5052) was used in the metal substrate 1, and the bonding layer 3 was made of copper-10 wt % nickel (Cu-10 wt % Ni), and the solder layer 5 was made of nickel (Ni). The film thickness of the adhesive layer 2 was set to 20 nm, the film thickness of the bonding layer 3 was set to 60 nm, and the film thickness of the solder layer 5 was set to 0.3 μm or 5 μm. The adhesive layer 2 has the compression stress.

From the experiment results by these samples, it was confirmed that the solder wettability and the initial bonding strength could be further stably excellent by forming the solder layer 5 by a plating method such as electroless plating. Further, it was confirmed that the solder wettability after application of strain could also be excellent.

Namely, by forming the solder layer 5 by the plating method such as the electroless plating, the solder layer 5 having extremely thick film thickness of μm unit can be formed as the protective film, with good through put. Therefore, further improvement of the solder bonding strength can be achieved without inviting a higher manufacturing cost. Moreover, the wettability and the initial bonding strength and the wettability after application of strain can be made excellent.

Here, as the forming materials of the solder layer 5, other than the aforementioned ones, tin-silver (Sn—Ag), tin-zinc (Sn-zinc), zinc (Zn), etc, can also be used as plating materials.

From the results as described above, a main essential matter is extracted as follows.

The film thickness of the adhesive layer 2 is desirably set to 10 nm or more and 500 nm or less. When it is thinner than 10 nm, there is a high possibility that the solder wettability is insufficient. Reversely, when it is thicker than 500 nm, there is a high possibility that an adverse influence by hydrogen becomes stronger. However, even if it is thicker than 500 nm, the adverse influence by hydrogen (hydrogen embrittlement) is not problematic.

The film thickness of the bonding layer 3 is desirably set to 15 nm or more. When it is thinner than 15 nm, there is a high possibility that both of the solder wettability and solder bonding strength are insufficient. Also, when it is thicker than 200 nm, the bonding layer 3 has a tendency of being fragile to application of strain.

Copper-10 wt % nickel (Cu-10 wt % Ni) can be given as a most typical material of the adhesive layer 3. However, by adding nickel (Ni) in particular, the solder wettability is apt to be improved. However, even if pure copper (Cu) is selected without nickel (Ni), excellent solder wettabiltiy and solder bonding strength can be obtained. Further, copper-40 wt % nickel (Cu-40 wt % Ni) is the upper limit of a degree of containing nickel (Ni).

In addition, by selecting copper-5 wt % zinc (Cu-5 wt % Zn), the solder wettability can be secured. Also, by selecting three elements composition of copper-5 wt % nickel-10 wt % Zn (Cu-5 wt % Ni-10 wt % Zn), both of the sacrificial protection effect by adding zinc (Zn) and an effect of improving the solder wettability by adding nickel (Ni) can be achieved.

It can be considered that even if the film thickness of the protective layer 4 and the film thickness of the solder layer 4 are more increased than 5 μm, there is no substantial demerit in the aspect of performance as the protective layer 4 itself, other than a higher manufacturing cost including the material cost.

When nickel (Ni) as a simple body is used as the material of the protective layer 4, although there is a possibility that the manufacturing cost and the material cost are increased, the protective layer 4 made of nickel (Ni) can be used without problem in the aspect of its performance.

Also, when copper-60 wt % nickel (Cu-60 wt % Ni) is used, there is no problem in the aspect of performance, and there is a merit that it is slightly more inexpensive than nickel (Ni) simple body.

When copper-20 wt % nickel (Cu-20 wt % Ni) is used, there is no problem in the aspect of performance, and there is a merit that it is more inexpensive than the nickel (Ni) simple body.

When copper-5 wt % nickel (Cu-5 wt % Ni) is used, and when tin (Sn) is used, there is no problem in the aspect of performance, and there is a merit that it is greatly more inexpensive than the nickel (Ni) simple body.

When copper-5 wt % nickel-10 wt % Zn(Cu-5 wt % Ni-10 wt % Zn) is used, and when copper-10 wt % nickel-20 wt % Zn(Cu-10 wt % Ni-20 wt % Zn) is used, there is a merit that a zinc (Zn) component functions as a sacrificial protection material, and other than this merit, there is also a merit that the zinc (Zn) component contributes to strengthening the solder wettability.

When copper-20 wt % zinc (Cu-20 wt % Zn) is used, there is a merit that the zinc (Zn) component functions as the sacrificial protection material, and also there is a merit that he zinc (Zn) component can contribute to reducing the manufacturing cost including the material cost. However, there is a possibility that the solder wettability is decreased in some cases.

Further, there is a merit that in copper-10 wt % nickel-40 wt % zinc (Cu-10 wt % Ni-4-wt % Zn), a large volume of zinc (Zn) components can be added when the bonding layer 3 is requested to have a sufficient function as the sacrificial protection material.

In the surface-treated metal substrate according to the third embodiment and the third example of the present invention, the adhesive layer 2 is made of chromium (Cr), and a first merit of using chromium (Cr) in the adhesive layer 2 is a point that no adverse influence due to a so-called hydrogen embrittlement is generated under a hydrogen environment.

Further, when a significant application of strain is not performed, there is no problem if the film thickness of the adhesive layer 2 is 500 nm or less. However, when the application of strain is performed such as applying mechanical process by a press molding method, there is a high possibility that this adhesive layer 2 cannot be used, unless the film thickness is made thin such as under 500 nm and desirably 120 nm or less, and there is also a possibility that the abrasion, etc, of the press die is encouraged.

Further, chromium (Cr) is inexpensive among the aforementioned metal materials in terms of material cost, and therefore has a most advantageous characteristic in the point of reducing the manufacturing cost mainly including the material cost.

Regarding the oxygen concentration in the film formation atmosphere of the adhesive layer 2, it is desirable to intentionally reduce the oxygen concentration like 0.001% or less. If the oxygen concentration is beyond 0.0015 for example, the oxygen intensity ratio X of the finished adhesive layer 2 is beyond 0.02, and there is a high possibility that the solder wettability and the solder bonding strength are decreased.

Then, by forming the adhesive layer 2 by sputtering in the film formation atmosphere with low oxygen concentration, when the metal substrate 1 is pure aluminum (Al), or stainless steel (SUS), or titanium (Ti), the oxygen intensity ratio X of the finished adhesive layer 2 formed by sputtering is desirably set to 0.02 or less.

This is because when this oxygen intensity ratio X is beyond 0.02, there is a high possibility that the initial solder bonding strength is insufficient, irrespective of the other structure and the setting of each kind of process condition.

However, here, when the metal substrate 1 is made of an alloy containing magnesium (Mg) such as A5052, being one kind of the aluminum alloy, the oxygen intensity ratio X of the finished adhesive layer 2 formed by sputtering is desirably set to 0.04 or less.

Namely, the aluminum alloy (A5052) containing magnesium (Mg) was used in the metal substrate 1 instead of pure aluminum (Al), and regarding other structure and experiment conditions, the same setting was set as the setting in which pure aluminum (Al) was used in the metal substrate 1, to thereby prepare the sample. Then, by using this sample, experiment was conducted for a case that the oxygen intensity ratio X was set to 0.04 or less, and a case that it was set to beyond 0.04, and its results were examined. However, the solder bonding strength after hydrogen treatment was omitted. Its results were arranged and shown in table 85, table 86, and table 87.

From the experiment results shown in table 85, table 86, and table 87, when the metal substrate 1 was made of the aluminum alloy (A5052) containing magnesium (Mg), it was confirmed that the solder wettability and the initial solder bonding property could be made excellent, similarly to the case that the oxygen intensity ratio X was set to 0.02 or less when the metal substrate 1 was made of pure aluminum (Al), by setting the oxygen intensity ratio X to 0.04 or less in the finished adhesive layer 2. Further, in contrast, if the oxygen intensity ratio X was set to beyond 0.04, also similarly to the case that the metal substrate 1 is made of pure aluminum (Al), it was confirmed that the initial solder bonding strength was insufficient, irrespective of the other structure and the setting of each kind of process condition.

From this result, it was confirmed that the oxygen intensity ratio X of the finished adhesive layer 2 formed by sputtering was desirably set to 0.04 or less, when the metal substrate 1 was made of the alloy containing magnesium (Mg) such as A5052, being a kind of the aluminum alloy.

The present application is based on Japanese patent application No. 2008-306398, filed on Dec. 1, 2008, Japanese patent application No. 2008-306399, filed on Dec. 1, 2008, and Japanese patent application No. 2008-306400, filed on Dec. 1, 2008, the entire contents of which are hereby incorporated by reference.

What is claimed is:

1. A surface-treated metal substrate, comprising:
an adhesive layer formed of a sputtering film directly adhered to a passivation film of a metal substrate, with this adhesive layer having an internal residual stress of a compression stress or a zero stress; and
a bonding layer formed of a sputtering film mainly composed of any one of copper (Cu), a mixture state of copper and nickel (Cu—Ni), a mixture state of copper and zinc (Cu—Zn), and a mixture state of copper, nickel, and zinc (Cu—Ni—Zn),
on the surface of the metal substrate having the passivation film on an outermost, in an order from a surface side of the metal substrate.

2. The surface-treated metal substrate according to claim 1, wherein the adhesive layer is mainly composed of titanium (Ti).

3. The surface-treated metal substrate according to claim 2, wherein the adhesive layer is mainly composed of niobium (Nb).

4. The surface-treated metal substrate according to claim 1, wherein the adhesive layer is mainly composed of chromium (Cr).

5. The surface-treated metal substrate according to claim 1, wherein oxygen intensity ratio X is set to X≦0.02, which is measured by a spectroscopic analytical method by XPS or Auger analysis with 2 nm resolution, and defined by intensity of oxygen (O)/(intensity of oxygen (O)+intensity of a main component element constituting the adhesive layer+intensity of a component element of the bonding layer)=X, in the vicinity of an interface between the adhesive layer and the bonding layer.

6. The surface-treated metal substrate according to claim 1, wherein the metal substrate is made of a material intentionally added with magnesium (Mg), and the oxygen intensity ratio X is set to X≦0.04, which is measured by a spectroscopic analytical method by XPS or Auger analysis with 2 nm resolution, and defined by intensity of oxygen (O)/(intensity of oxygen (O)+intensity of a main component element constituting the adhesive layer+intensity of a component element of the bonding layer)=X, in the vicinity of an interface between the adhesive layer and the bonding layer.

7. The surface-treated metal substrate according to claim 2, wherein an average thickness of the adhesive layer is 20 nm to 200 nm.

8. The surface-treated metal substrate according to claim 3, wherein an average thickness of the adhesive layer is 10 nm to 200 nm.

9. The surface-treated metal substrate according to claim 4, wherein an average thickness of the adhesive layer is 10 nm to 500 nm.

10. The surface-treated metal substrate according to claim 1, wherein an average thickness of the bonding layer is 15 nm or more.

11. The surface-treated metal substrate according to claim 1, wherein a protective layer is provided on the bonding layer, for suppressing a generation of an oxide film on the outermost surface of the bonding layer.

12. The surface-treated metal substrate according to claim 11, wherein the protective layer is formed of a sputtering film mainly composed of at least anyone of nickel (Ni), tin (Sn), and a mixture state of copper and nickel (Cu—Ni), a mixture state of copper, nickel, and zinc (Cu—Ni—Zn), and a mixture state of copper and zinc (Cu—Zn).

13. The surface-treated metal substrate according to claim 11, wherein the protective layer is made of a plating film mainly composed of copper (Cu) or nickel (Ni) or zinc (Zn).

14. The surface-treated metal substrate according to claim 1, wherein a solder layer is further provided on the bonding layer, which is formed by a tin plating or a tin alloy plating having a composition for the purpose of use for solder.

15. The surface-treated metal substrate according to claim 11, wherein a solder layer is further provided on the protective layer, which is formed by a tin plating or a tin alloy plating having a composition for the purpose of use for solder.

16. A manufacturing method of a surface-treated metal substrate, comprising the steps of:
forming by sputtering an adhesive layer directly adhered to a passivation film of the metal substrate, with an internal residual stress of this adhesive layer set as a compression stress or a zero stress, and
forming on the adhesive layer by sputtering a bonding layer mainly composed of any one of copper (Cu), a mixture state of copper and nickel (Cu—Ni), a mixture state of copper and zinc (Cu—Zn), and a mixture state of copper, nickel, and zinc (Cu—Ni—Zn),
wherein in the step of forming the adhesive layer and the step of forming the bonding layer, film formation by sputtering is performed sequentially in the same chamber maintaining a film formation atmosphere of inactive gas from which oxygen is intentionally removed even when materials of the formed layers are switched.

17. The manufacturing method of the surface-treated metal substrate according to claim 16, wherein the adhesive layer is mainly composed of any one of titanium (Ti), niobium (Nb), and chromium (Cr).

18. The manufacturing method of the surface-treated metal substrate according to claim 16, wherein a concentration of the oxygen is set to 0.001% or less, and a pressure of a film formation atmosphere is set to 1.5 Pa or less in this film formation atmosphere in the chamber, by using argon (Ar) gas as an inert gas of the film formation atmosphere.
